(19) United States
(12) Patent Application Publication
(10) Pub. No.: US 2021/0343876 A1
(43) Pub. Date: Nov. 4, 2021

(54) CRYSTAL STRUCTURE COMPOUND, OXIDE SINTERED BODY, SPUTTERING TARGET, CRYSTALLINE OXIDE THIN FILM, AMORPHOUS OXIDE THIN FILM, THIN FILM TRANSISTOR AND ELECTRONIC EQUIPMENT

(71) Applicant: IDEMITSU KOSAN CO.,LTD., Tokyo (JP)

(72) Inventors: Kazuyoshi INOUE, Sodegaura-shi (JP); Masatoshi SHIBATA, Sodegaura-shi (JP); Emi KAWASHIMA, Sodegaura-shi (JP); Kenichi SASAKI, Sodegaura-shi (JP); Atsushi YAO, Sodegaura-shi (JP)

(73) Assignee: IDEMITSU KOSAN CO.,LTD., Tokyo (JP)

(21) Appl. No.: 17/264,650

(22) PCT Filed: Aug. 1, 2019
(86) PCT No.: PCT/JP2019/030134

§ 371 Date: Jan. 29, 2021

(30) Foreign Application Priority Data
Aug. 1, 2018 (JP) 2018-145479

(51) Int. Cl. H01L 29/786; C23C 14/34; C01G 15/00

(52) U.S. Cl. CPC H01L 29/78693; C23C 14/3407; C04B 2235/3286; C01P 2002/02; C01P 2002/72; C01G 15/00

(57) ABSTRACT

A crystalline structure compound A is represented by a composition formula (2) and has having diffraction peaks respectively in below-defined ranges (A) to (K) of an incidence angle observed by X-ray diffraction measurement.

(InₓGa_{y}Al_{z})₂O₃ (2)

In the formula (2), 0.47≤x≤0.53, 0.17≤y≤0.43, 0.07≤z≤0.33, and x+y+z=1.

31° to 34° (A), 36° to 39° (B), 30° to 32° (C), 51° to 53° (D), 53° to 56° (E), 62° to 66° (F), 9° to 11° (G), 19° to 21° (H), 42° to 45° (I), 8° to 10° (J), and 17° to 19° (K).

### TECHNICAL FIELD

The present invention relates to a crystalline structure compound, an oxide sintered body, a sputtering target, an amorphous oxide thin film, an amorphous oxide thin film, a thin-film transistor, and an electronic device.

### BACKGROUND

An amorphous oxide semiconductor usable for a thin-film transistor has a higher carrier mobility and a larger optical band gap than general-purpose amorphous silicon (amorphous silicon is sometimes abbreviated as a-Si) and can be formed into a film at a low temperature. For this reason, the amorphous oxide semiconductor is expected to be applied to a next generation display requiring a large size, high resolution and high speed drive, and a resin substrate having a low heat resistance.

A sputtering method, through which a sputtering target is sputtered, is preferably used for formation of the above oxide semiconductor (film). This is because a thin film formed by the sputtering method exhibits an excellent component composition in a film plane direction (in a film plane) and an excellent in-plane uniformity such a film thickness as compared with a thin film formed through an ion plating method, vacuum deposition method, or electron beam vapor deposition, and has the same component composition as that of the sputtering target.

Although Cited Literature 1 exemplarily describes a ceramic body including a GaAlO₃ compound, Patent Literature 1 is silent on an oxide semiconductor.

Patent Literature 2 describes a thin-film transistor having a crystalline oxide semiconductor film containing indium oxide and a trivalent positive metal oxide.

Patent Literature 3 describes an oxide sintered body in which gallium is solid-dissolved in indium oxide at an atomic ratio of Ga/(Ga+In) ranging from 0.001 to 0.12, and one or more oxides selected from yttrium oxide, scandium oxide, aluminum oxide and boron oxide are added.

Patent Literature 4 describes an oxide sintered body having an atomic ratio of Ga/(Ga+In) ranging from 0.10 to 0.15.

Patent Literature 5 describes an oxide sintered body of indium oxide containing gallium oxide and aluminum oxide. In this oxide sintered body, a content (atomic ratio) of a gallium element to all metal elements ranges from 0.01 to 0.08 and a content (atomic ratio) of an aluminum element to all metal elements ranges from 0.0001 to 0.03. Example 2 shows that In₂O₃ (Bixbyite) is observed when calcination is performed at a Ga added amount of 5.7 at %, an Al added amount of 2.6 at %, and a temperature of 1600 degrees C. for 13 hours.

Patent Literature 6 describes an oxide sintered body containing indium oxide doped with Ga, and a tetravalent positive metal at a ratio of more than 100 atom ppm and 700 atom ppm or less of the sum of Ga and indium, in which the atomic ratio Ga/(Ga+In) in the indium oxide doped with Ga ranges from 0.001 to 0.15, and a crystal structure of the oxide sintered body consists essentially of the Bixbyite structure of indium oxide.

Patent Literature 7 describes an oxide sintered body containing gallium solid-dissolved in indium oxide at an atomic ratio Ga/(Ga+In) ranging from 0.001 to 0.08, the contents of indium and gallium to all of the metal atoms being 80 atomic % or more. The oxide sintered body has Bixbyite structure of In₂O₃ and is added with one or more oxides selected from yttrium oxide, scandium oxide, aluminum oxide, and boron oxide. According to Patent Literature 7, the Bixbyite structure of In₂O₃ is confirmed in a sintered body obtained at a sintering temperature of 1400 degrees C. when a Ga added amount is 7.2 at % and an Al added amount is 2.6 at %.

Patent Literature 8 describes an oxide sintered body containing indium oxide, gallium oxide, and aluminum oxide, in which a content of gallium represented by Ga/(In+Ga) (atomic ratio) is in a range from 0.15 to 0.49; a content of aluminum represented by Al/(In+Ga+Al) (atomic ratio) is 0.0001 or more and less than 0.25; and the oxide sintered body includes an In₂O₃ phase of a Bixbyite structure, and a generated phase other than the In₂O₃ phase including a GaInO₃ phase of a β-Ga₂O₃ structure, or a GaInO₃ phase of a β-Ga₂O₃ structure and a (Ga,In)₂O₃ phase. Patent Literature 8 also describes that, in a case where a mixture of Ga (20 at % in an added amount) and Al (1 at % in the added amount) and a mixture of Ga (25 at % in an added amount) and Al (5 at % in the added amount) are each calcined at a temperature of 1400 degrees C. for 20 hours, it has been confirmed from an XRD chart that the In₂O₃ phase and the GaInO₃ phase are deposited.

### CITATION LIST

### Patent Literatures

| | |
|---|---|
| Patent Literature 1 | JP 2004-008924 A |
| Patent Literature 2 | International Publication No. WO 2010/032431 |
| Patent Literature 3 | International Publication No. WO 2010/032422 |
| Patent Literature 4 | JP 2011-146571 A |
| Patent Literature 5 | JP 2012-211065 A |
| Patent Literature 6 | JP 2013-067855 A |
| Patent Literature 7 | JP 2014-098211 A |
| Patent Literature 8 | International Publication No. WO 2016/084636 |

### SUMMARY OF THE INVENTION

### Problems to be Solved by the Invention

There exists a strong demand for a higher-quality TFT, and for a material exhibiting a small change in properties (a high process durability) before and after process such as CVD and also achieving a high carrier mobility.

An object of the invention is to provide: a crystalline structure compound that can achieve a stable sputtering and also can achieve a high process durability and a high mobility in TFT having a thin film obtained by sputtering; an oxide sintered body containing the crystalline structure compound; and a sputtering target containing the oxide sintered body.

Another object of the invention is to provide a thin-film transistor having a high process durability and a high mobility, and an electronic device having the thin-film transistor.

Still another object of the invention is to provide a crystalline oxide thin film and an amorphous oxide thin film which are used for the thin-film transistor.

### Means for Solving the Problems

According to aspects of the invention, a crystalline structure compound, an oxide sintered body, a sputtering target, a crystalline oxide thin film, an amorphous oxide thin film, a thin-film transistor, and an electronic device are provided.

[1] A crystalline structure compound A is represented by a composition formula (1) and has diffraction peaks respectively in below-defined ranges (A) to (K) of an incidence angle (2θ) observed by X-ray (Cu—K α ray) diffraction measurement.

(InₓGa_{y}Al_{z})₂O₃ (1)

In composition formula (1),

0.47≤x≤0.53,

0.17≤y≤0.33,

0.17≤z≤0.33, and

x+y+z=1.

31° to 34° (A)

36° to 39° (B)

30° to 32° (C)

51° to 53° (D)

53° to 56° (E)

62° to 66° (F)

9° to 11° (G)

19° to 21° (H)

42° to 45° (I)

8° to 10° (J)

17° to 19° (K)

[2] A crystalline structure compound A is represented by a composition formula (2) and has diffraction peaks respectively in below-defined ranges (A) to (K) of an incidence angle (2θ) observed by X-ray (Cu—K α ray) diffraction measurement.

(InₓGa_{y}Al_{z})₂O₃ (2)

In the composition formula (2),

0.47≤x≤0.53,

0.17≤y≤0.43,

0.07≤z≤0.33, and

x+y+z=1.

31° to 34° (A)

36° to 39° (B)

30° to 32° (C)

51° to 53° (D)

53° to 56° (E)

62° to 66° (F)

9° to 11° (G)

19° to 21° (H)

42° to 45° (I)

8° to 10° (J)

17° to 19° (K)

[3] An oxide sintered body consists of a crystalline structure compound A represented by a composition formula (1) and having diffraction peaks respectively in below defined ranges (A) to (K) of an incidence angle (2θ) observed by X-ray (Cu—K α ray) diffraction measurement.

(InₓGa_{y}Al_{z})₂O₃ (1)

In composition formula (1),

0.47≤x≤0.53,

0.17≤y≤0.33,

0.17≤z≤0.33, and

x+y+z=1.

31° to 34° (A)

36° to 39° (B)

30° to 32° (C)

51° to 53° (D)

53° to 56° (E)

62° to 66° (F)

9° to 11° (G)

19° to 21° (H)

42° to 45° (I)

8° to 10° (J)

17° to 19° (K)

[4] An oxide sintered body consists of a crystalline structure compound A represented by a composition formula (2) and having diffraction peaks respectively in below defined ranges (A) to (K) of an incidence angle (2θ) observed by X-ray (Cu—K α ray) diffraction measurement.

(InₓGa_{y}Al_{z})₂O₃ (2)

In the composition formula (2),

0.47≤x≤0.53,

0.17≤y≤0.43,

0.07≤z≤0.33, and

x+y+z=1.

31° to 34° (A)

36° to 39° (B)

30° to 32° (C)

51° to 53° (D)

53° to 56° (E)

62° to 66° (F)

9° to 11° (G)

19° to 21° (H)

42° to 45° (I)

8° to 10° (J)

17° to 19° (K)

[5] An oxide sintered body includes a crystalline structure compound A represented by a composition formula (1) and having diffraction peaks respectively in below defined ranges (A) to (K) of an incidence angle (2θ) observed by X-ray (Cu—K α ray) diffraction measurement.

(InₓGa_{y}Al_{z})₂O₃ (1)

In composition formula (1),

0.47≤x≤0.53,

0.17≤y≤0.33,

0.17≤z≤0.33, and

x+y+z=1.

31° to 34° (A)

36° to 39° (B)

30° to 32° (C)

51° to 53° (D)

53° to 56° (E)

62° to 66° (F)

9° to 11° (G)

19° to 21° (H)

42° to 45° (I)

8° to 10° (J)

17° to 19° (K)

[6] An oxide sintered body includes a crystalline structure compound A represented by a composition formula (2) and having diffraction peaks respectively in below defined ranges (A) to (K) of an incidence angle (2θ) observed by X-ray (Cu—K α ray) diffraction measurement.

(InₓGa_{y}Al_{z})₂O₃ (2)

In the composition formula (2),

0.47≤x≤0.53,

0.17≤y≤0.43,

0.07≤z≤0.33, and

x+y+z=1.

31° to 34° (A)

36° to 39° (B)

30° to 32° (C)

51° to 53° (D)

53° to 56° (E)

62° to 66° (F)

9° to 11° (G)

19° to 21° (H)

42° to 45° (I)

8° to 10° (J)

17° to 19° (K)

[7] In the oxide sintered body according to the above [5] or [6], an indium element (In), a gallium element (Ga) and an aluminum element (Al) are present within a composition range surrounded by points (R1-1), (R2), (R3), (R4-1), (R5-1) and (R6-1) below represented by atomic % ratios in an In—Ga—Al ternary composition diagram.

In:Ga:Al=45:22:33 (R1)

In:Ga:Al=66:1:33 (R2)

In:Ga:Al=90:1:9 (R3)

In:Ga:Al=90:9:1 (R4)

In:Ga:Al=54:45:1 (R5)

In:Ga:Al=45:45:10 (R6)

[8] In the oxide sintered body according to the above [5] or [6], an indium element (In), a gallium element (Ga) and an aluminum element (Al) are present within a composition range surrounded by points (R1-1), (R2), (R3), (R4-1), (R5-1) and (R6-1) below represented by atomic % ratios in an In—Ga—Al ternary composition diagram.

In:Ga:Al=47:20:33 (R1-1)

In:Ga:Al=66:1:33 (R2)

In:Ga:Al=90:1:9 (R3)

In:Ga:Al=90:8.5:1.5 (R4-1)

In:Ga:Al=55.5:43:1.5 (R5-1)

In:Ga:Al=47:43:10 (R6-1)

[9] The oxide sintered body according to any one of the above [5] to [8] further includes: a Bixbyite crystalline compound represented by In₂O₃.
[10] In the oxide sintered body according to the above [9], at least one of the gallium element or the aluminum element is solid-dissolved in the Bixbyite crystalline compound represented by In₂O₃.
[11] In the oxide sintered body according to the above [9] or [10], crystal grains of the Bixbyite crystalline compound represented by In₂O₃ are dispersed in a phase formed of crystal grains of the crystalline structure compound A, and a ratio of an area of the crystalline structure compound A to an area of a view field, in the view field when the oxide sintered body is observed with an electron microscope, is in a range from 70% to 100%.
[12] In the oxide sintered body according to any one of the above [5] to [11], an indium element (In), a gallium element (Ga) and an aluminum element (Al) are present within a composition range surrounded by points (R1), (R2), (R7), (R8), and (R9) below represented by atomic % ratios in an In—Ga—Al ternary composition diagram.

In:Ga:Al=45:22:33 (R1)

In:Ga:Al=66:1:33 (R2)

In:Ga:Al=69:1:30 (R7)

In:Ga:Al=69:15:16 (R8)

In:Ga:Al=45:39:16 (R9)

[13] In the oxide sintered body according to the above [9] or [10], the oxide sintered body includes a phase in which crystal grains of the crystalline structure compound A are connected to each other and a phase in which crystal grains of the Bixbyite crystalline compound represented by In₂O₃ are connected to each other, and a ratio of an area of the crystalline structure compound A to an area of a view field, in the view field when the oxide sintered body is observed with an electron microscope, is more than 30% and less than 70%.
[14] In the oxide sintered body according to any one of the above [5], [6], [7], [8], [9], [10] and [13], an indium element (In), a gallium element (Ga) and an aluminum element (Al) are present within a composition range surrounded by points (R10), (R11), (R12), (R13), and (R14) below represented by atomic % ratios in an In—Ga—Al ternary composition diagram.

In:Ga:Al=72:12:16 (R10)

In:Ga:Al=78:12:10 (R11)

In:Ga:Al=78:21:1 (R12)

In:Ga:Al=77:22:1 (R13)

In:Ga:Al=62:22:16 (R14)

[15] In the oxide sintered body according to the above [5], [6], [7], [8], [9], [10] or [13], an indium element (In), a gallium element (Ga) and an aluminum element (Al) are present within a composition range surrounded by points (R11), (R12-10), (R1), (R13-1), and (R14) below represented by atomic % ratios in an In—Ga—Al ternary composition diagram.

In:Ga:Al=72:12:16 (R10)

In:Ga:Al=78:12:10 (R11)

In:Ga:Al=78:20.5:1.5 (R12-1)

In:Ga:Al=76.5:22:1.5 (R13-1)

In:Ga:Al=62:22:16 (R14)

[16] In the oxide sintered body according to the above [9] or [10], crystal grains of the crystalline structure compound A are dispersed in a phase formed of crystal grains of the Bixbyite crystalline compound represented by In₂O₃, and a ratio of an area of the crystalline structure compound A to an area of a view field, in the view field when the oxide sintered body is observed with an electron microscope, is more than 0% and 30% or less.
[17] In the oxide sintered body according to the above [5], [6], [7], [8], [9], [10] or [16], an indium element (In), a gallium element (Ga) and an aluminum element (Al) are present within a composition range surrounded by points (R3), (R4), (R12), (R15), and (R16) below represented by atomic % ratios in an In—Ga—Al ternary composition diagram.

In:Ga:Al=90:1:9 (R3)

In:Ga:Al=90:9:1 (R4)

In:Ga:Al=78:21:1 (R12)

In:Ga:Al=78:5:17 (R15)

In:Ga:Al=82:1:17 (R16)

[18] In the oxide sintered body according to the above [5], [6], [7], [8], [9], [10] or [16], an indium element (In), a gallium element (Ga) and an aluminum element (Al) are present within a composition range surrounded by points (R3), (R4-1), (R12-1), (R15), and (R16) below represented by atomic % ratios in an In—Ga—Al ternary composition diagram.

In:Ga:Al=90:1:9 (R3)

In:Ga:Al=90:8.5:1.5 (R4-1)

In:Ga:Al=78:20.5:1.5 (R12-1)

In:Ga:Al=78:5:17 (R15)

In:Ga:Al=82:1:17 (R16)

[19] The oxide sintered body according to any one of the above [9] to [18], a lattice constant of the Bixbyite crystalline compound represented by In₂O₃ is in a range from 10.05×10⁻¹⁰ m to 10.114×10⁻¹⁰ m.
[20] A sputtering target includes the oxide sintered body according to any one of the above [3] to [19].
[21] A crystalline oxide thin film includes an indium element (In), a gallium element (Ga), and an aluminum element (Al), in which the indium element, the gallium element, and the aluminum element are present within a composition range surrounded by points (R16), (R3), (R4), and (R17) below represented by atomic % ratios in an In—Ga—Al ternary composition diagram.

In:Ga:Al=82:1:17 (R16)

In:Ga:Al=90:1:9 (R3)

In:Ga:Al=90:9:1 (R4)

In:Ga:Al=82:17:1 (R17)

[22] A crystalline oxide thin film includes an indium element (In), a gallium element (Ga), and an aluminum element (Al), in which the indium element, the gallium element, and the aluminum element are present within a composition range surrounded by points (R16-1), (R3), (R4-1), and (R17-1) below represented by atomic % ratios in an In—Ga—Al ternary composition diagram.

In:Ga:Al=80:1:19 (R16-1)

In:Ga:Al=90:1:9 (R3)

In:Ga:Al=90:8.5:1.5 (R4-1)

In:Ga:Al=80:18.5:1.5 (R17-1)

[23] In the crystalline oxide thin film according to the above [21] or [22], the crystalline oxide thin film is a Bixbyite crystal represented by In₂O₃.
[24] In the crystalline oxide thin film according to the above [23], a lattice constant of the Bixbyite crystal represented by In₂O₃ is equal to or less than 10.05×10⁻¹⁰ m.
[25] A thin-film transistor includes the crystalline oxide thin film according to according to any one of the above [21] to [24].
[26] An amorphous oxide thin film includes an indium element (In), a gallium element (Ga), and an aluminum element (Al), in which the indium element, the gallium element, and the aluminum element are present within a composition range surrounded by points (R16), (R17) and (R18) below represented by atomic % ratios in an In—Ga—Al ternary composition diagram.

In:Ga:Al=82:1:17 (R16)

In:Ga:Al=82:17:1 (R17)

In:Ga:Al=66:17:17 (R18)

[27] An amorphous oxide thin film includes an indium element (In), a gallium element (Ga), and an aluminum element (Al), in which the indium element, the gallium element, and the aluminum element are present within a composition range surrounded by points (R16-1), (R17-1) and (R18-1) below represented by atomic % ratios in an In—Ga—Al ternary composition diagram.

In:Ga:Al=80:1:19 (R16-1)

In:Ga:Al=80:18.5:1.5 (R17-1)

In:Ga:Al=62.5:18.5:19 (R18-1)

[28] An amorphous oxide thin film has a composition represented by a composition formula (1) below.

(InₓGa_{y}Al_{z})₂O₃ (1)

In composition formula (1),

0.47≤x≤0.53,

0.17≤y≤0.33,

0.17≤z≤0.33, and

x+y+z=1.

[29] An amorphous oxide thin film has a composition represented by a composition formula (2) below.

(InₓGa_{y}Al_{z})₂O₃ (2)

In the composition formula (2),

0.47≤x≤0.53,

0.17≤y≤0.43,

0.07≤z≤0.33, and

x+y+z=1.

[30] A thin-film transistor includes the amorphous oxide thin film according to any one of the above [26] to [29].
[31] A thin-film transistor includes an oxide semiconductor thin-film containing an indium element (In), a gallium element (Ga) and an aluminum element (Al), in which the indium element (In), the gallium element (Ga) and the aluminum element (Al) are present within a composition range surrounded by points (R1), (R2), (R3), (R4), (R5) and (R6) below represented by atomic % ratios in an In—Ga—Al ternary composition diagram.

In:Ga:Al=45:22:33 (R1)

In:Ga:Al=66:1:33 (R2)

In:Ga:Al=90:1:9 (R3)

In:Ga:Al=90:9:1 (R4)

In:Ga:Al=54:45:1 (R5)

In:Ga:Al=45:45:10 (R6)

[31X] A thin-film transistor includes the crystalline oxide thin film according to any one of the above [21] to [24] and the amorphous oxide thin film according to any one of the above [26] to [29].
[32] A thin-film transistor includes: a gate insulating film; an active layer in contact with the gate insulating film; a source electrode; and a drain electrode, in which the active layer is the crystalline oxide thin film according to any one of the above [21] to [24], the amorphous oxide thin film according to any one of the above [26] to [29] is laminated on the active layer, and the amorphous oxide thin film is in contact with at least one of the source electrode or the drain electrode.
[33] An electronic device includes the thin-film transistor according to the above [25], [30], [31] or [32].

According to the above aspects of the invention, a crystalline structure compound that can achieve a stable sputtering and also can achieve a high process durability and a high mobility in TFT having a thin film obtained by sputtering; an oxide sintered body containing the crystalline structure compound; and a sputtering target containing the oxide sintered body can be provided.

According to the above aspects of the invention, a thin-film transistor having a high process durability and a high mobility, and an electronic device having the thin-film transistor can be provided.

According to the above aspects of the invention, a crystalline oxide thin film and an amorphous oxide thin film which are used in the thin-film transistor can be provided.

### BRIEF DESCRIPTION OF DRAWING(S)

FIG. 1 is an In—Ga—Al ternary composition diagram showing an example of a composition range of a sintered body according to an exemplary embodiment of the invention.

FIG. 2 is an In—Ga—Al ternary composition diagram showing an example of a composition range of a sintered body according to an exemplary embodiment of the invention.

FIG. 3 is an In—Ga—Al ternary composition diagram showing an example of a composition range of a sintered body according to an exemplary embodiment of the invention.

FIG. 4 is an In—Ga—Al ternary composition diagram showing an example of a composition range of a sintered body according to an exemplary embodiment of the invention.

FIG. 5 is an In—Ga—Al ternary composition diagram showing an example of a composition range of a sintered body according to an exemplary embodiment of the invention.

FIG. 6A is a perspective view showing a shape of a target according to an exemplary embodiment of the invention.

FIG. 6B is a perspective view showing another shape of the target according to the exemplary embodiment of the invention.

FIG. 6C is a perspective view showing still another shape of the target according to the exemplary embodiment of the invention.

FIG. 6D is a perspective view showing a further shape of the target according to the exemplary embodiment of the invention.

FIG. 7 is an In—Ga—Al ternary composition diagram showing an example of composition range of a sintered body according to an exemplary embodiment of the invention.

FIG. 8A is a vertical cross section showing an oxide semiconductor thin-film formed on a glass substrate.

FIG. 8B illustrates an SiO₂ film formed on the oxide semiconductor thin-film shown in FIG. 8A.

FIG. 9 is a vertical cross section showing a thin-film transistor according to an exemplary embodiment of the invention.

FIG. 10 is a vertical cross section showing a thin-film transistor according to an exemplary embodiment of the invention.

FIG. 11 is a vertical cross section showing a quantum-tunneling field-effect transistor according to an exemplary embodiment of the invention.

FIG. 12 is a vertical cross section showing a quantum-tunneling field-effect transistor according to another exemplary embodiment of the invention.

FIG. 13 is a TEM (Transmission Electron Microscope) photograph of a portion where a silicon oxide layer is formed between a p-type semiconductor layer and an n-type semiconductor layer in FIG. 12.

FIG. 14A is a vertical cross section showing a step in a production process of the quantum-tunneling field-effect transistor.

FIG. 14B is a vertical cross section showing another step in the production process of the quantum-tunneling field-effect transistor.

FIG. 14C is a vertical cross section showing still another step in the production process of the quantum-tunneling field-effect transistor.

FIG. 14D is a vertical cross section showing a further step in the production process of the quantum-tunneling field-effect transistor.

FIG. 14E is a vertical cross section showing a still further step in the production process of the quantum-tunneling field-effect transistor.

FIG. 15A is a top plan showing a display using a thin-film transistor according to an exemplary embodiment of the invention.

FIG. 15B illustrates a circuit of a pixel unit applicable to a pixel of a VA liquid crystal display.

FIG. 15C illustrates a circuit of a pixel unit in a display using an organic EL device.

FIG. 16 illustrates a circuit of a pixel unit of a solid-state image sensor using a thin-film transistor according to an exemplary embodiment of the invention.

FIG. 17 shows SEM observation image photographs of oxide sintered bodies of Examples 1 and 2.

FIG. 18 is an XRD chart of the oxide sintered body prepared in Example 1.

FIG. 19 is an XRD chart of the oxide sintered body prepared in Example 2.

FIG. 20 shows SEM observation image photographs of oxide sintered bodies of Examples 3 and 4.

FIG. 21 is an XRD chart of the oxide sintered body prepared in Example 3.

FIG. 22 is an XRD chart of an oxide sintered body prepared in Example 4.

FIG. 23 shows SEM observation image photographs of oxide sintered bodies of Examples 5 and 6.

FIG. 24 is an XRD chart of the oxide sintered body prepared in Example 5.

FIG. 25 is an XRD chart of the oxide sintered body prepared in Example 6.

FIG. 26 shows SEM observation image photographs of oxide sintered bodies of Examples 7, 8 and 9.

FIG. 27 shows SEM observation image photographs of oxide sintered bodies of Examples 10, 11 and 12.

FIG. 28 shows SEM observation image photographs of oxide sintered bodies of Examples 13 and 14.

FIG. 29 is an XRD chart of the oxide sintered body prepared in Example 7.

FIG. 30 is an XRD chart of the oxide sintered body prepared in Example 8.

FIG. 31 is an XRD chart of the oxide sintered body prepared in Example 9.

FIG. 32 is an XRD chart of the oxide sintered body prepared in Example 10.

FIG. 33 is an XRD chart of the oxide sintered body prepared in Example 11.

FIG. 34 is an XRD chart of the oxide sintered body prepared in Example 12.

FIG. 35 is an XRD chart of the oxide sintered body prepared in Example 13.

FIG. 36 is an XRD chart of the oxide sintered body prepared in Example 14.

FIG. 37 is an XRD chart of an oxide sintered body prepared in Comparative 1.

FIG. 38 is an In—Ga—Al ternary composition diagram showing an example of a composition range of a sintered body according to an exemplary embodiment of the invention.

FIG. 39 is an In—Ga—Al ternary composition diagram showing an example of a composition range of a sintered body according to an exemplary embodiment of the invention.

FIG. 40 is an In—Ga—Al ternary composition diagram showing an example of a composition range of a sintered body according to an exemplary embodiment of the invention.

FIG. 41 is an In—Ga—Al ternary composition diagram showing an example of a composition range of a sintered body according to an exemplary embodiment of the invention.

FIG. 42 is an In—Ga—Al ternary composition diagram showing an example of a composition range of a sintered body according to an exemplary embodiment of the invention.

FIG. 43 is an In—Ga—Al ternary composition diagram showing an example of a composition range of a crystalline structure compound or a sintered body according to an exemplary embodiment of the invention.

FIG. 44 is an In—Ga—Al ternary composition diagram showing an example of a composition range of a crystalline structure compound or a sintered body according to an exemplary embodiment of the invention.

FIG. 45 shows SEM observation image photographs of oxide sintered bodies of Examples 15 and 16.

FIG. 46 is an XRD chart of the oxide sintered body prepared in Example 15.

FIG. 47 is an XRD chart of the oxide sintered body prepared in Example 16.

FIG. 48 shows SEM observation image photographs of oxide sintered bodies of Examples 17 to 22.

FIG. 49 is an XRD chart of the oxide sintered body prepared in Example 17.

FIG. 50 is an XRD chart of the oxide sintered body prepared in Example 18.

FIG. 51 is an XRD chart of the oxide sintered body prepared in Example 19.

FIG. 52 is an XRD chart of the oxide sintered body prepared in Example 20.

FIG. 53 is an XRD chart of the oxide sintered body prepared in Example 21.

FIG. 54 is an XRD chart of the oxide sintered body prepared in Example 22.

FIG. 55 is an SEM observation image photograph of the oxide sintered body prepared in Comparative 2.

FIG. 56 is an XRD chart of the oxide sintered body prepared in Comparative 2.

FIG. 57 is an XRD chart of an amorphous oxide thin film prepared in Example D2.

### DESCRIPTION OF EMBODIMENT(S)

Exemplary embodiment(s) of the invention will be described below with reference to attached drawing(s). It should however be noted that it is easily understood by those skilled in the art that the exemplary embodiment(s) may be modified in various manners, as long as such modification and details are compatible with an object and the scope of the invention. Accordingly, the scope of the invention should by no means be interpreted to be restricted to the disclosure in the exemplary embodiment(s) below.

Further, in the drawing(s), a size, a layer thickness, or a region is sometimes exaggerated for clarification. Thus, the scale of the drawing(s) in the invention is not necessarily limited to the scale shown in the drawing. It should be noted that the drawing(s) schematically shows an ideal example, and illustrated shape(s) and/or value(s) are not limited to those shown in the drawing(s).

Further, ordinals such as “first,” “second,” and “third,” used in the specification are attached for avoiding confusion between components, and are not numerically limiting.

In the specification and the like, the term “electrically connected” encompasses a connection through “an object of some electric action.” The “object of some electric action” is not limited to specific object as long as such an object allows communication of electric signals between connected components. Examples of the “object of some electric action” include an electrode, a line, a switching element such as a transistor, a resistor, an inductor, a capacitor, and devices having other function(s).

In the specification and the like, the term “film” or “thin-film” is sometimes interchangeable with the term “layer.”

In the specification and the like, a source and a drain of a transistor are sometimes interchanged when, for instance, a transistor of different polarity is used or a direction of a current is changed during an operation of a circuit. Accordingly, the terms “source” and “drain” in the specification and the like are interchangeable.

Further, in an oxide sintered body and an oxide semiconductor thin-film in the specification and the like, the term “compound” and the term “crystalline phase” are sometimes interchangeable.

Herein, numerical ranges represented by “x to y” represents a range whose lower limit is the value (x) recited before “to” and whose upper limit is the value (y) recited after “to.”

### Crystalline Structure Compound

A crystalline structure compound A in an exemplary form according to an exemplary embodiment of the invention is represented by a composition formula (1) below and has diffraction peaks respectively in the below-defined ranges (A) to (K) of an incidence angle (2θ) observed by X-ray (Cu—K α ray) diffraction measurement.

(InₓGa_{y}Al_{z})₂O₃ (1)

In composition formula (1),

0.47≤x≤0.53,

0.17≤y≤0.33,

0.17≤z≤0.33, and

x+y+z=1.

31° to 34° (A)

36° to 39° (B)

30° to 32° (C)

51° to 53° (D)

53° to 56° (E)

62° to 66° (F)

9° to 11° (G)

19° to 21° (H)

42° to 45° (I)

8° s to 10° (J)

17° to 19° (K)

The crystalline structure compound A in another form according to the exemplary embodiment is represented by a composition formula (2) below and has diffraction peaks respectively in the above-defined ranges (A) to (K) of an incidence angle (2θ) observed by X-ray (Cu—K α ray) diffraction measurement.

(InₓGa_{y}Al_{z})₂O₃ (2)

In the composition formula (2),

0.47≤x≤0.53,

0.17≤y≤0.43,

0.07≤z≤0.33, and

x+y+z=1.

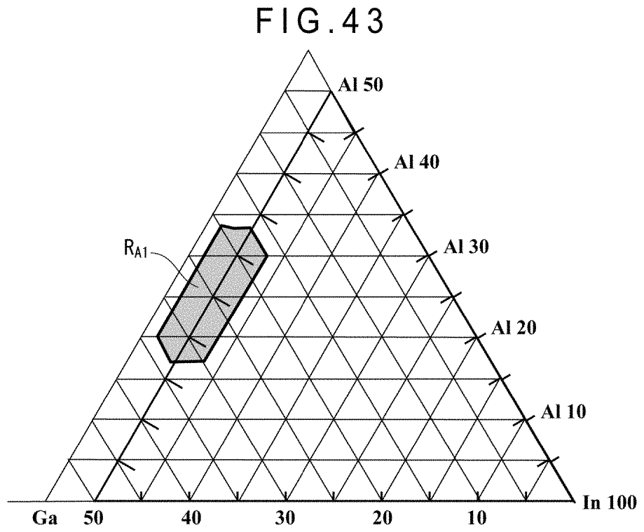

FIG. 43 shows an In—Ga—Al ternary composition diagram. FIG. 43 shows a composition range R_{A1} of the crystalline structure compound A represented by the composition formula (1).

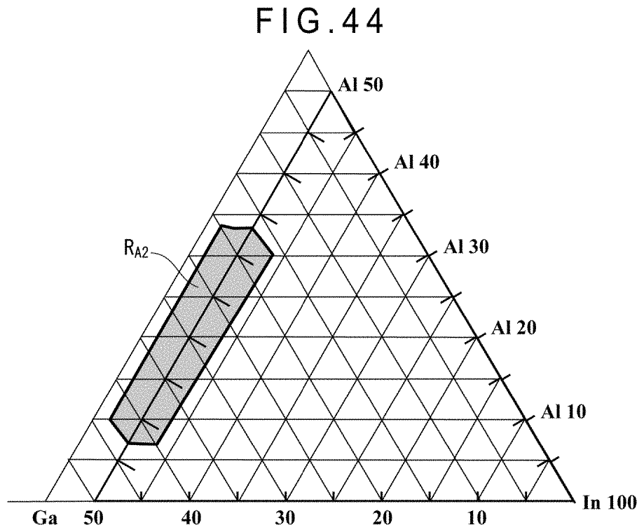

FIG. 44 shows an In—Ga—Al ternary composition diagram. FIG. 44 shows a composition range R_{A2} of the crystalline structure compound A represented by the composition formula (2).

Representative examples of a composition ratio of the crystalline structure compound A include In:Ga:Al being 5:4:1, In:Ga:Al being 5:3:2 or In:Ga:Al being 5:2:3.

It can be confirmed by X-ray diffraction (XRD) measurement that the crystalline structure compound A of the exemplary embodiment has diffraction peaks in the above-defined ranges (A) to (K) of the incidence angle (2θ). Criteria for determining that the crystalline structure compound A has a diffraction peak through the X-ray diffraction (XRD) measurement was as follows.

<Conditions of X-Ray Diffraction (XRD) Measurement>

Scanning Mode: 2θ/θ

Scanning Type: continuous scanning

X-ray intensity: 45 kV/200 mA

incidence slit: 1.000 mm

light-receiving slit 1: 1.000 mm

light-receiving slit 2: 1.000 mm

IS longitudinal length: 10.0 mm

step width: 0.02°

speed measurement time: 2.0°/min

An XRD pattern obtained using SmartLab (manufactured by Rigaku Corporation) under the above measurement conditions was subjected to “peak search and labelling” of JADE6, in which a threshold value a was set to 2.1, a cut-off peak intensity was set to 0.19%, a range for determining a background was set to 0.5, and a point number for averaging the background was set to 7, and a peak was detected. A peak position was defined through a gravity center method.

The crystalline structure compound A of the exemplary embodiment has diffraction peaks respectively in the above-defined ranges (A) to (K) of the incidence angle (2θ). For instance, the crystalline structure compound A has a diffraction peak at the incidence angle (2θ) smaller than 31° as the diffraction peak in the defined range (C) when the crystalline structure compound A has a diffraction peak at 31° as the peak in the defined range (A), and has a diffraction peak at the incidence angle (2θ) smaller than 9° as the diffraction peak in the defined range (J) when the crystalline structure compound A has a diffraction peak at 9° as the peak in the defined range (G).

A crystal having diffraction peaks in the respective defined ranges (A) to (K) was not compatible with a known compound through analysis by JADE6, so that it has been found that the compound A according to the exemplary embodiment is a compound with an unknown crystal structure.

The crystalline structure compound A in the arrangement according to the exemplary embodiment includes an indium element (In), gallium element (Ga), aluminum element (Al) and oxygen element (O), and represented by a composition formula (2) below.

(InₓGa_{y}Al_{z})₂O₃ (2)

In the composition formula (2),

0.47≤x≤0.53,

0.17≤y≤0.43,

0.07≤z≤0.33, and

x+y+z=1.

In the crystalline structure compound A of the exemplary embodiment, a preferable range of the composition formula (2) is:

0.48×0.52,

0.18≤y≤0.42,

0.08≤z≤0.32, and

x+y+z=1.

In the crystalline structure compound A of the exemplary embodiment, a more preferable range of the composition formula (2) is:

0.48×0.51,

0.19≤y≤0.41,

0.09≤z≤0.32, and

x+y+z=1.

An atomic ratio of the crystalline structure compound A of the exemplary embodiment can be measured with SEM-EDS (Scanning Electron Microscope-Energy Dispersed X-ray analyzer) or ICP-AES (Inductively Coupled Plasma-Atomic Emission Spectrometry).

The crystalline structure compound A of the exemplary embodiment has semiconductor properties.

According to the crystalline structure compound A of the exemplary embodiment, a stable sputtering can be achieved by using a sputtering target containing the crystalline structure compound A, and a high process durability and a high mobility can be achieved in TFT including a thin film produced through the sputtering.

### Production Method of Crystalline Structure Compound

The crystalline structure compound A of the exemplary embodiment is producible by a sintering reaction.

### Oxide Sintered Body

An oxide sintered body of the exemplary embodiment contains the crystalline structure compound A of the exemplary embodiment.

Herein, the oxide sintered body in an exemplary form according to the exemplary embodiment containing the crystalline structure compound A is exemplified by a first oxide sintered body and a second oxide sintered body below. However, the oxide sintered body of the invention is not limited to this form.

### First Oxide Sintered Body

An oxide sintered body in an exemplary form according to the exemplary embodiment (the oxide sintered body in this form is sometimes referred to as a first oxide sintered body) is represented by the composition formula (1) or (2) and consists of the crystalline structure compound A having the diffraction peaks respectively in the defined ranges (A) to (K) of the incidence angle (2θ) observed by the X-ray (Cu—K α ray) diffraction measurement.

The first oxide sintered body exhibits a sufficiently low resistivity and is preferably usable as the sputtering target. Accordingly, it is preferable to use the first oxide sintered body as the sputtering target.

FIG. 43 shows an In—Ga—Al ternary composition diagram. The composition range R_{A1} shown in FIG. 43 also corresponds to a composition range of the first oxide sintered body consisting of the crystalline structure compound A represented by the composition formula (1).

FIG. 44 shows an In—Ga—Al ternary composition diagram. The composition range R_{A2} shown in FIG. 44 also corresponds to a composition range of the first oxide sintered body consisting of the crystalline structure compound A represented by the composition formula (2).

When a material of the oxide sintered body is calcined at a high temperature of 1370 degrees C. or more, a crystalline structure compound A phase easily appears in the composition range R_{A1}. When the material of the oxide sintered body is calcined at a low temperature of 1360 or less, the crystalline structure compound A phase easily appears in the composition range R_{A2}. It is considered that the composition ranges where the crystalline structure compound A phase appears differ due to a difference in reactivity between indium oxide, gallium oxide and aluminum oxide.

A relative density of the first oxide sintered body is preferably 95% or more. The relative density of the first oxide sintered body is more preferably 96% or more, further preferably 97% or more.

At 95% or more of the relative density of the first oxide sintered body, a strength of the obtained target is increased, thereby preventing breakage of the target and occurrence of abnormal electrical discharge when a film is formed by a large power. Moreover, at 95% or more of the relative density of the first oxide sintered body, the film density of the obtained oxide film is not increased, thereby preventing deterioration in TFT properties and decrease in TFT stability.

The relative density is measurable according to the method described in Examples.

A bulk resistivity of the first oxide sintered body is preferably 15 mΩ·cm or less. If the bulk resistivity of the first oxide sintered body is 15 mΩ·cm or less, it means that the first oxide sintered body has a sufficiently low bulk resistivity. Accordingly, the first oxide sintered body can be more preferably used as the sputtering target. When the bulk resistivity of the first oxide sintered body is low, the resistivity of the obtained target is decreased to generate a stable plasma. Moreover, when the bulk resistivity of the first oxide sintered body is low, arc discharge (also called as fireball discharge) becomes unlikely to occur, thereby keeping a target surface from being melted or cracked.

The bulk resistivity is measurable according to the method described in Examples.

### Second Oxide Sintered Body

An oxide sintered body in another exemplary form according to the exemplary embodiment (the oxide sintered body in this form is sometimes referred to as the second oxide sintered body) is represented by the composition formula (1) or (2) and contains the crystalline structure compound A having the diffraction peaks respectively in the defined ranges (A) to (K) of the incidence angle (2θ) observed by the X-ray (Cu—K α ray) diffraction measurement.

In the second oxide sintered body in the above exemplary form, the indium element (In), gallium element (Ga) and aluminum element (Al) are preferably present within a composition range R_{A} surrounded by points (R1), (R2), (R3), (R4), (R5) and (R6) below represented by atomic % ratios in the In—Ga—Al ternary composition diagram.

In:Ga:Al=45:22:33 (R1)

In:Ga:Al=66:1:33 (R2)

In:Ga:Al=90:1:9 (R3)

In:Ga:Al=90:9: (R4)

In:Ga:Al=54:45:1 (R5)

In:Ga:Al=45:45:10 (R6)

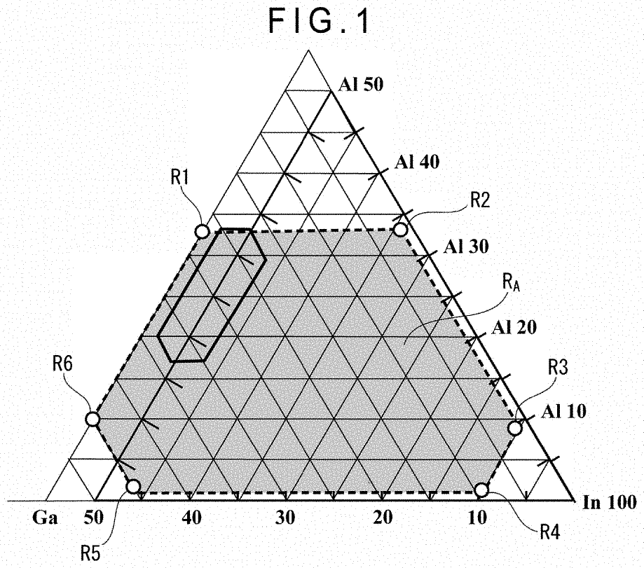

FIG. 1 shows an In—Ga—Al ternary composition diagram. FIG. 1 shows a composition range R_{A} surrounded by the above points (R1), (R2), (R3), (R4), (R5) and (R6).

The composition range R_{A} herein refers to a range in which vertices of a polygon, which indicate the above (R1), (R2), (R3), (R4), (R5) and (R6) represented by the composition ratios, are connected by a straight line in FIG. 1. Herein, the composition range Rx (X is A, B, C, D, E, F and the like) includes compositions at the vertices and points on the straight line connecting the vertices, in the polygon showing the composition range.

In the second oxide sintered body in the above exemplary form, the indium element (In), gallium element (Ga) and aluminum element (Al) are preferably present within a composition range R_{A}′ surrounded by points (R1-1), (R2), (R3), (R4-1), (R5-1) and (R6-1) below represented by atomic % ratios in the In—Ga—Al ternary composition diagram.

In:Ga:Al=47:20:33 (R1-1)

In:Ga:Al=66:1:33 (R2)

In:Ga:Al=90:1:9 (R3)

In:Ga:Al=90:8.5:1.5 (R4-1)

In:Ga:Al=55.5:43:1.5 (R5-1)

In:Ga:Al=47:43:10 (R6-1)

The atomic ratios of the oxide sintered body herein can be measured with a Inductively Coupled Plasma-Atomic Emission Spectrometry (ICP-AES).

The second oxide sintered body preferably contains a Bixbyite crystalline compound represented by In₂O₃.

The Bixbyite crystalline compound represented by In₂O₃ in the second oxide sintered body preferably contains at least one of a gallium element or an aluminum element. The Bixbyite crystalline compound represented by In₂O₃ and containing at least one of a gallium element or an aluminum element is, for instance, in a form of a solid solution such as substitution solid solution and interstitial solid solution.

In the second oxide sintered body, at least one of a gallium element or an aluminum element is preferably solid-dissolved in the Bixbyite crystalline compound represented by In₂O₃.

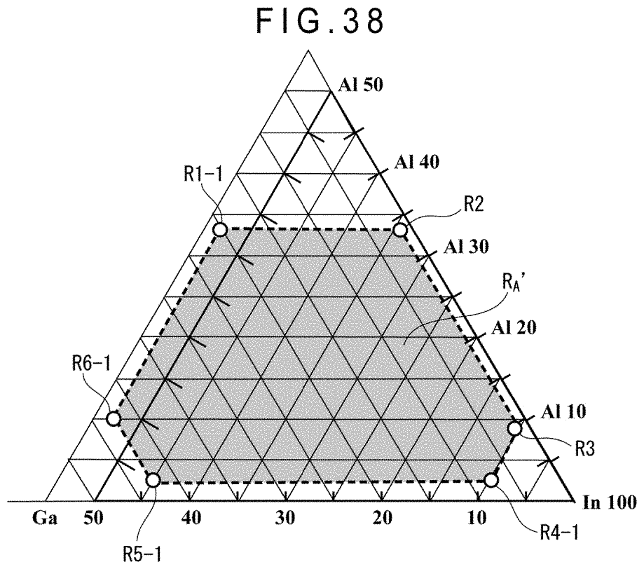

By the XRD measurement of the second oxide sintered body, the crystalline structure compound A is observed in a large region in an indium oxide-gallium oxide-aluminum oxide sintered body. The region is the composition range R_{A} surrounded by the above (R1), (R2), (R3), (R4), (R5) and (R6) in the In—Ga—Al ternary composition diagram of FIG. 1, or the composition range R_{A}′ surrounded by the above (R1-1), (R2), (R3), (R4-1), (R5-1) and (R6-1) in the In—Ga—Al ternary composition diagram of FIG. 38.

In the second oxide sintered body, the atomic % ratios of the indium element (In), gallium element (Ga) and aluminum element (Al) are also further preferably in ranges represented by formulae (2), (3) and (4A) below.

47≤In/(In+Ga+Al)≤90 (2)

2≤Ga/(In+Ga+Al)≤45 (3)

1.7≤Al/(In+Ga+Al)≤33 (4A)

In the formulae (2), (3) and (4A), In, Al and Ga represent the number of atoms of the indium element, aluminum element and gallium element, respectively, in the oxide sintered body.

In the second oxide sintered body, the atomic % ratios of the indium element (In), gallium element (Ga) and aluminum element (Al) are also further preferably in ranges represented by formulae (2) to (4) below.

47≤In/(In+Ga+Al)≤90 (2)

2≤Ga/(In+Ga+Al)≤45 (3)

2≤Al/(In+Ga+Al)≤33 (4)

In the formulae (2) to (4), In, Al and Ga represent the number of atoms of the indium element, aluminum element and gallium element, respectively, in the oxide sintered body.

The second oxide sintered body exhibits electrical conductive properties and semiconductor properties. Accordingly, the second oxide sintered body is usable for various applications such as a semiconductive material and an electrical conductive material.

When the In content is less than the range represented by at least one of the composition range R_{A} and R_{A}′, crystals of the crystalline structure compound A are not observed but a lot of impurities crystals are observed other than crystals of the crystalline structure compound A and crystals of the Bixbyite structure represented by In₂O₃, so that semiconductor properties, which are properties of the crystalline structure compound A, may sometimes be impaired, or, even if exhibited, the semiconductor properties may sometimes be close to insulation properties.

When the In content is more than the range represented by at least one of the composition range R_{A} or R_{A}′, the crystalline structure compound A is not expressed but only the Bixbyite crystalline compound phase represented by In₂O₃ is expressed. When this sintered body is used for an oxide semiconductor thin-film, a thin film having a large amount of the indium oxide composition is obtained, which requires a strong control of carriers of the thin film. A carrier control method of the thin film is exemplified by control of an oxygen partial pressure at the time of film formation, coexistence of highly oxidizing gas such as NO₂, and coexistence of H₂O gas having an effect of suppressing the generation of carriers. Moreover, the formed thin film needs to be subjected to processing such as an oxygen plasma processing, NO₂ plasma processing, or heat treatment in presence of oxidized gas such as oxygen or NO₂ gas.

When the Al content is less than the range represented by at least one of the composition range R_{A} or R_{A}′, the crystalline structure compound A is not observed but only InGaO₃ of a β-Ga₂O₃ and the like are observed. In this case, since InGaO₃ is poorly conductive, an insulator exists in the sintered body, which may cause abnormal electrical discharge or generate nodule and the like. When the Al content is more than the range represented by at least one of the composition range R_{A} or R_{A}′, since aluminum oxide per se is an insulator, abnormal electrical discharge may be caused, or nodule and the like may be generated. In addition, the entire oxide may be insulated, so that inconvenience may occur when the sintered body is used as a semiconductor material.

When the Ga content is less than the range represented by at least one of the composition range R_{A} or R_{A}′, since the contents of In and Al are relatively large, the Bixbyite crystalline compound phase represented by In₂O₃ as well as Al₂O₃ is likely to be observed. When Al₂O₃ is observed, it means that the sintered body contains the insulator since Al₂O₃ is an insulator. When the sintered body containing an insulator is used as a sputtering target, abnormal electrical discharge may occur, or arc discharge may cause breakage, cracks and the like in the target. When the Ga content is more than the range represented by at least one of the composition range R_{A} or R_{A}′, GaAlO₃, InGaO₃ of β-Ga₂O₃ or the like is observed. In this case, since GaAlO₃ is an insulator and InGaO₃ is poorly conductive, the sintered body may be insulated. Inconvenience may occur when the insulated sintered body is used as a semiconductor material.

In these composition ranges R_{A} and R_{A}′, the crystalline structure compound A phase, and the Bixbyite crystalline compound phase represented by In₂O₃ used as the material may be observed. However, Al₂O₃, Ga₂O₃, GaAlO₃ obtained by reacting Al₂O₃ and Ga₂O₃, InGaO₃ that is a reaction product of In₂O₃ and Ga₂O₃, and the like are not observed.

In this composition range R_{A}, when mixed powders of indium oxide, gallium oxide and aluminum oxide are calcined at a temperature of 1400 degrees C., in a range with a small aluminum-added amount in the composition range R_{A}, the Bixbyite crystalline compound phase represented by In₂O₃ used as the material, an InGaO₃ phase that is a reaction product of In₂O₃ and Ga₂O₃, or a gallium oxide phase in which at least one of indium element or an aluminum element is solid-dissolved may be observed. When these phases are observed, abnormal electrical discharge or the like may occur during sputtering. Therefore, the preferred composition range is the composition range R_{A}′.

The Bixbyite crystalline compound phase represented by In₂O₃ can contain at least one of a gallium element or an aluminum element. In each of crystal grains of the observed Bixbyite crystalline compound phase represented by In₂O₃, in an SEM photograph, contrast occurs in each of crystal grains of indium oxide since the content of the gallium element and the content of the aluminum element are different, or contrast occurs in each of crystal grains of indium oxide since observed crystal surfaces are different. However, the crystal grains of the observed Bixbyite crystalline compound phase represented by In₂O₃ are identical with the crystal grains of the Bixbyite crystalline compound represented by In₂O₃.

Total content (X_{Ga}+X_{Al}) of a content X_{Ga} of the gallium element contained in the indium oxide crystals and a content X_{Al} of the aluminum element contained in the indium oxide crystals is preferably approximately in a range from 0.5 at % to 10 at %. When the content X_{Ga} of the gallium element and the content X_{Al} of the aluminum element are each 0.5 at % or more, the gallium element and the aluminum element can be detected by the SEM-EDS measurement. When the content X_{Ga} of the gallium element is 10 at % or less and the content X_{Al} of the aluminum element is 3 at % or less, the gallium element and the aluminum element can be solid-dissolved in crystals of the Bixbyite crystalline compound represented by In₂O₃. By containing the gallium element and the aluminum element in the indium oxide crystals, lattice constants of the indium oxide crystals become smaller than lattice constants of pure indium oxide crystals. Accordingly, an atomic distance between indium oxide metal elements is decreased, whereby an electron-conducting path is likely to be formed and a highly electric conductive (low-resistance-value) sintered body is obtained.

There is such a correlation as leading to equilibrium among the crystalline structure compound A, the Bixbyite crystalline compound represented by In₂O₃, and the Bixbyite crystalline compound represented by In₂O₃ in which at least one of the gallium element or the aluminum element is solid-dissolved. In the oxide sintered body, it is preferable to form the crystalline structure compound A from the indium oxide, gallium oxide, and aluminum oxide, or to be present in a form of the Bixbyite crystalline compound represented by In₂O₃ in which at least one of the gallium element or the aluminum element is solid-dissolved. Since gallium oxide and aluminum oxide are insulative materials to cause abnormal electrical discharge and arc discharge, when at least one of gallium oxide or aluminum oxide is present alone in the oxide sintered body, inconvenience may occur in use as the sputtering target.

In the second oxide sintered body in the above exemplary form, the indium element (In), gallium element (Ga) and aluminum element (Al) are preferably present within a composition range R_{B} surrounded by points (R1), (R2), (R7), (R8) and (R9) below represented by atomic % ratios in the In—Ga—Al ternary composition diagram.

In:Ga:Al=45:22:33 (R1)

In:Ga:Al=66:1:33 (R2)

In:Ga:Al=69:1:30 (R7)

In:Ga:Al=69:15:16 (R8)

In:Ga:Al=45:39:16 (R9)

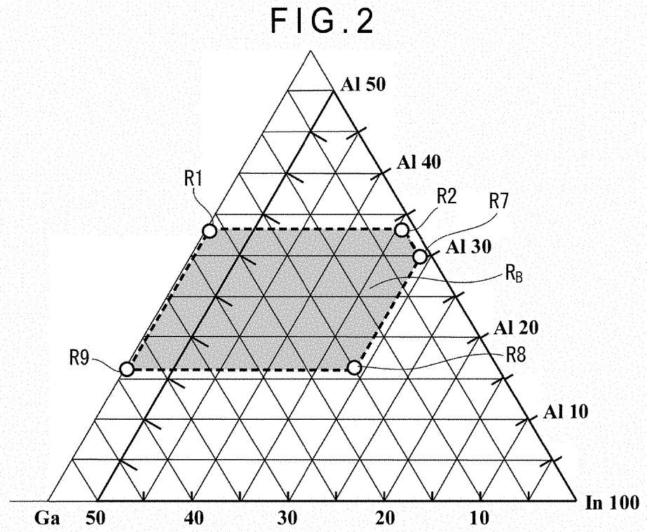

FIG. 2 shows an In—Ga—Al ternary composition diagram. FIG. 2 shows the composition range R_{B} surrounded by the above (R1), (R2), (R7), (R8) and (R9).

In an exemplary form of the second oxide sintered body, the atomic % ratios of the indium element (In), gallium element (Ga) and aluminum element (Al) are further preferably in ranges represented by formulae (5) to (7) below.

47≤In/(In+Ga+Al)≤65 (5)

5≤Ga/(In+Ga+Al)≤30 (6)

16≤Al/(In+Ga+Al)≤30 (7)

In the formulae (5) to (7), In, Al and Ga respectively represent the number of atoms of the indium element, aluminum element and gallium element in the oxide sintered body.

In an exemplary form of the second oxide sintered body, the indium element (In), gallium element (Ga) and aluminum element (Al) are preferably present within a composition range R_{C} surrounded by points (R10), (R11), (R12), (R13) and (R14) below represented by atomic % ratios in the In—Ga—Al ternary composition diagram.

In:Ga:Al=72:12:16 (R10)

In:Ga:Al=78:12:10 (R11)

In:Ga:Al=78:21:1 (R12)

In:Ga:Al=77:22:1 (R13)

In:Ga:Al=62:22:16 (R14)

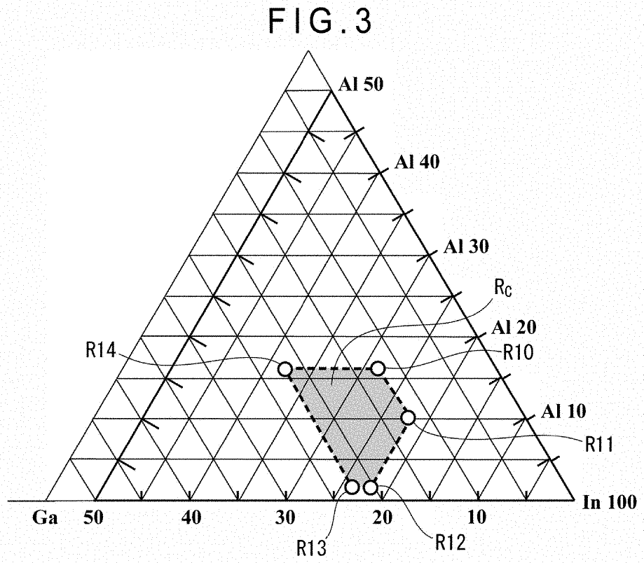

FIG. 3 shows an In—Ga—Al ternary composition diagram. FIG. 3 shows the composition range R_{C} surrounded by the above (R10), (R11), (R12), (R13) and (R14).

In the second oxide sintered body in the above exemplary form, the indium element (In), gallium element (Ga) and aluminum element (Al) are preferably present within a composition range R_{C}′ surrounded by points (R10), (R11), (R12-1), (R13-1) and (R14) below represented by atomic % ratios in the In—Ga—Al ternary composition diagram.

In:Ga:Al=72:12:16 (R10)

In:Ga:Al=78:12:10 (R11)

In:Ga:Al=78:20.5:1.5 (R12-1)

In:Ga:Al=76.5:22:1.5 (R13-1)

In:Ga:Al=62:22:16 (R14)

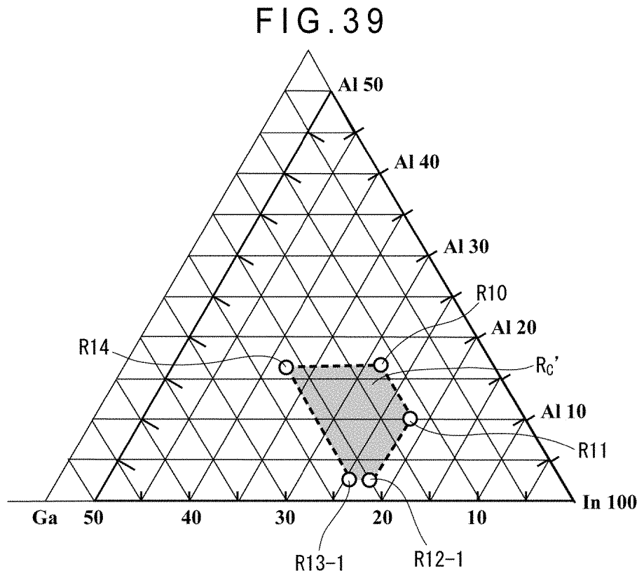

FIG. 39 shows an In—Ga—Al ternary composition diagram. FIG. 39 shows the composition range R_{C}′ surrounded by the above (R10), (R11), (R12-1), (R13-1) and (R14).

In this composition range R_{c}, when mixed powders of indium oxide, gallium oxide and aluminum oxide are calcined at a temperature of 1400 degrees C., in a range where an aluminum-added amount is small, of the composition range R_{c}, the Bixbyite crystalline compound phase represented by In₂O₃ used as the material, InGaO₃ that is a reaction product of In₂O₃ and Ga₂O₃, and a gallium oxide phase in which at least one of indium element or an aluminum element is solid-dissolved may be observed. In this case, a preferable composition range is the composition range R_{C}′.

In the exemplary form of the second oxide sintered body, the atomic % ratios of the indium element (In), gallium element (Ga) and aluminum element (Al) are further preferably in ranges represented by formulae (8) to (10) below.

62≤In/(In+Ga+Al)≤78 (8)

12≤Ga/(In+Ga+Al)≤15 (9)

1.7≤Al/(In+Ga+Al)≤16 (10)

In the formulae (8) to (10), In, Al and Ga represent the number of atoms of the indium element, aluminum element and gallium element, respectively, in the oxide sintered body.

In the above exemplary form of the second oxide sintered body, the indium element (In), gallium element (Ga) and aluminum element (Al) are preferably present within a composition range R_{D} surrounded by points (R3), (R4), (R12), (R15) and (R16) represented by atomic % ratios below in the In—Ga—Al ternary composition diagram.

In:Ga:Al=90:1:9 (R3)

In:Ga:Al=90:9:1 (R4)

In:Ga:Al=78:21:1 (R12)

In:Ga:Al=78:5:17 (R15)

In:Ga:Al=82:1:17 (R16)

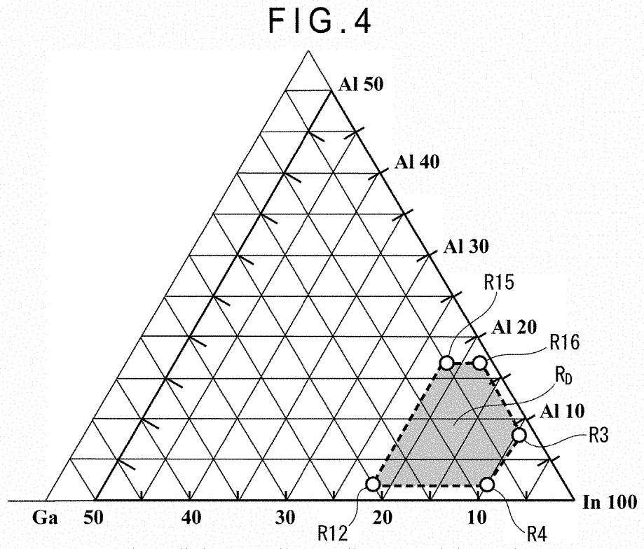

FIG. 4 shows an In—Ga—Al ternary composition diagram. FIG. 4 shows the composition range R_{D} surrounded by the above (R3), (R4), (R12), (R15) and (R16).

In the second oxide sintered body in the above exemplary form, the indium element (In), gallium element (Ga) and aluminum element (Al) are preferably present within a composition range R_{D}′ surrounded by points (R3), (R4-1), (R12-1), (R15) and (R16) below represented by atomic % ratios in the In—Ga—Al ternary composition diagram.

In:Ga:Al=90:1:9 (R3)

In:Ga:Al=90:8.5:1.5 (R4-1)

In:Ga:Al=78:20.5:1.5 (R12-1)

In:Ga:Al=78:5:17 (R15)

In:Ga:Al=82:1:17 (R16)

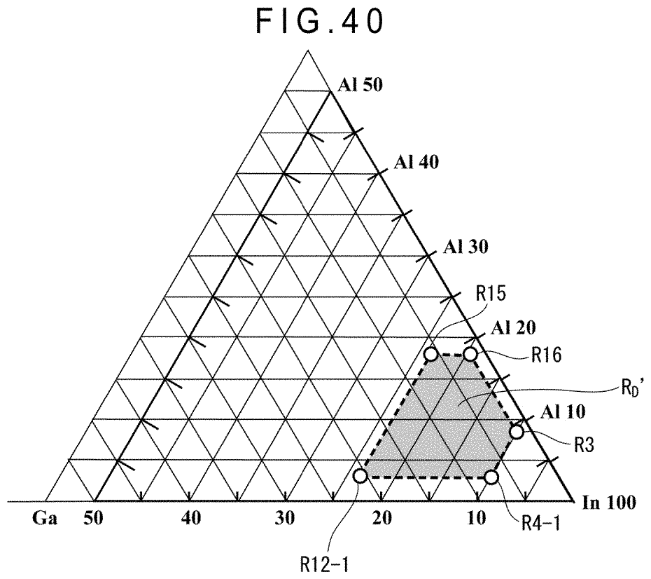

FIG. 40 shows an In—Ga—Al ternary composition diagram. FIG. 40 shows the composition range R_{D}′ surrounded by the above (R3), (R4-1), (R12-1), (R15) and (R16).

In this composition range R_{D}, when mixed powders of indium oxide, gallium oxide and aluminum oxide are calcined at a temperature of 1400 degrees C., in a range where an aluminum-added amount is small, of the composition range R_{D}, the Bixbyite crystalline compound phase represented by In₂O₃ used as the material, InGaO₃ that is a reaction product of In₂O₃ and Ga₂O₃, and a gallium oxide phase in which at least one of indium element or an aluminum element is solid-dissolved may be observed. In this case, a preferably composition range is the composition range R_{D}′.

In the exemplary form of the second oxide sintered body, the atomic % ratios of the indium element (In), gallium element (Ga) and aluminum element (Al) are further preferably in ranges represented by formulae (11) to (13) below.

78≤In/(In+Ga+Al)≤90 (11)

3≤Ga/(In+Ga+Al)≤15 (12)

1.7≤Al/(In+Ga+Al)≤15 (13)

In the formulae (11) to (13), In, Al and Ga respectively represent the number of atoms of the indium element, aluminum element and gallium element in the oxide sintered body.

In the second oxide sintered body in the above exemplary form, the indium element (In), gallium element (Ga) and aluminum element (Al) are preferably present within a composition range R_{E} surrounded by (R16), (R3), (R4) and (R17) below represented by atomic % ratios in the In—Ga—Al ternary composition diagram.

In:Ga:Al=82:1:17 (R16)

In:Ga:Al=90:1:9 (R3)

In:Ga:Al=90:9:1 (R4)

In:Ga:Al=82:17:1 (R17)

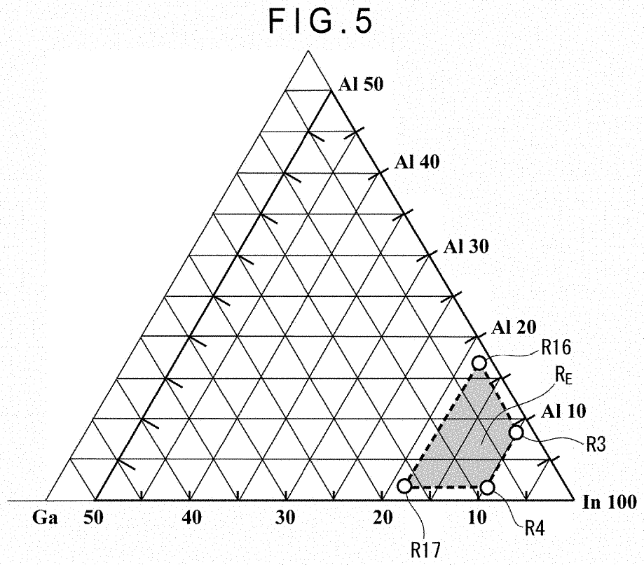

FIG. 5 shows an In—Ga—Al ternary composition diagram. FIG. 5 shows the composition range R_{E} surrounded by the above (R16), (R3), (R4) and (R17).

In the second oxide sintered body in the above exemplary form, the indium element (In), gallium element (Ga) and aluminum element (Al) are preferably present within a composition range R_{E}′ surrounded by points (R16-1), (R3), (R4-1) and (R17-1) below represented by atomic % ratios in the In—Ga—Al ternary composition diagram.

In:Ga:Al=80:1:19 (R16-1)

In:Ga:Al=90:1:9 (R3)

In:Ga:Al=90:8.5:1.5 (R4-1)

In:Ga:Al=80:18.5:1.5 (R17-1)

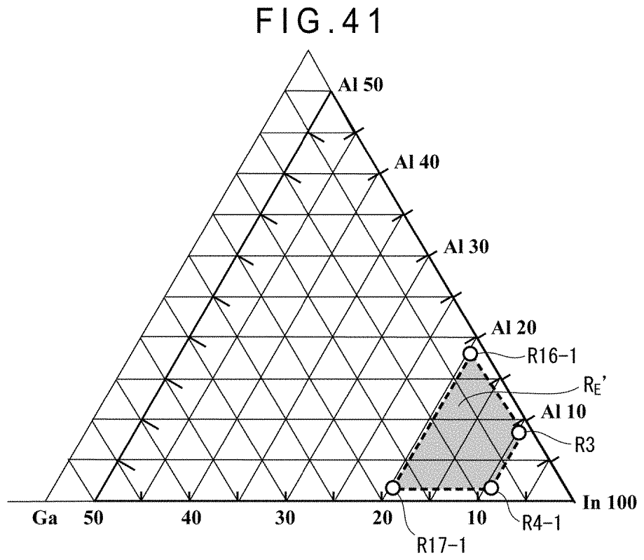

FIG. 41 shows an In—Ga—Al ternary composition diagram. FIG. 41 shows the composition range R_{E}′ surrounded by the above (R16-1), (R3), (R4-1) and (R17-1).

The sintered body having a composition falling within the composition range R_{E} surrounded by the above (R16), (R3), (R4) and (R17) and the sintered body having a composition falling within the composition range R_{E}′ surrounded by the above (R16-1), (R3), (R4-1) and (R17-1) exhibit a low bulk resistivity and a unique electrical conductivity. This is considered because the oxide sintered body according to the exemplary embodiment contains crystal grains of the crystalline structure compound A having an unknown structure, and an atomic packing (closest packing structure) has a unique structure to generate a low resistant sintered body. This means that, depending on a difference in a grain size of material powders to be used and a difference in a grain size of crashed powder mixture and a mixture state, a contact state of indium oxide powders, gallium oxide powders and aluminum oxide powders differs, and a progress of solid-phase reaction (element diffusion status) during subsequent sintering differs. In addition, it is considered that, for instance, a difference in a surface activity due to a production method of indium oxide, gallium oxide, and aluminum oxide materials also affects a solid phase reaction. Further, it is considered that due to a difference in a temperature-increase speed during sintering, a holding time at the maximum temperature, a cooling speed during cooling, and the like, and a difference in the progress of the solid phase reaction due to a difference in a gas type to flow during the sintering and conditions of a flowrate, and the like, the final product differs and an amount of impurities differs. It is considered that a generation speed of the crystalline structure compound A differs due to the above factors, consequently to cause a reaction to generate impurities such as InGaO₃, which is a reaction product of In₂O₃ and Ga₂O₃, and AlGaO₃, which is a reaction product of Al₂O₃ and Ga₂O₃.

In this composition range R_{E}, when mixed powders of indium oxide, gallium oxide and aluminum oxide are calcined at a temperature of 1400 degrees C., in a range where an aluminum-added amount is small, of the composition range R_{E}, the Bixbyite crystalline compound phase represented by In₂O₃ used as the material, a InGaO₃ that is a reaction product of In₂O₃ and Ga₂O₃, and a gallium oxide phase in which at least one of indium element or an aluminum element is solid-dissolved may be observed. In this case, a preferably composition range is the composition range R_{E}′.

In the exemplary form of the second oxide sintered body, the atomic % ratios of the indium element (In), gallium element (Ga) and aluminum element (Al) are further preferably in ranges represented by formulae (14) to (16) below.

83≤In/(In+Ga+Al)≤90 (14)

3≤Ga/(In+Ga+Al)≤15 (15)

1.7≤Al/(In+Ga+Al)≤15 (16)

In the formulae (14) to (16), In, Al and Ga respectively represent the number of atoms of the indium element, aluminum element and gallium element in the oxide sintered body.

A relative density of the second oxide sintered body is preferably 95% or more. The relative density of the second oxide sintered body is more preferably 96% or more, further preferably 97% or more.

At 95% or more of the relative density of the second oxide sintered body, a strength of the obtained target is increased, thereby preventing breakage of the target and occurrence of abnormal electrical discharge when a film is formed at a large power. Moreover, at 95% or more of the relative density of the second oxide sintered body, the film density of the obtained oxide film is not improved, thereby preventing deterioration in TFT properties and decrease in TFT stability.

The relative density is measurable according to the method described in Examples.

A bulk resistivity of the second oxide sintered body is preferably 15 mΩ·cm or less. When the bulk resistivity of the second oxide sintered body is 15 mΩ·cm or less, the second oxide sintered body is sintered body having a sufficiently low bulk resistivity, so that the second oxide sintered body can be more preferably used as the sputtering target. When the bulk resistivity of the second oxide sintered body is low, the resistivity of the obtained target is decreased to generate a stable plasma. Moreover, when the bulk resistivity of the second oxide sintered body is low, arc discharge (also called as fireball discharge) becomes unlikely to occur, thereby preventing a target surface from being melted or the target from being cracked.

The bulk resistivity is measurable according to the method described in Examples.

### First Dispersion System

In the second oxide sintered body, the crystal grains of the Bixbyite crystalline compound represented by In₂O₃ are preferably dissolved in a phase formed of the crystal grains of the crystalline structure compound A.

When the crystal grains of the Bixbyite crystalline compound represented by In₂O₃ are dissolved in the phase formed of the crystal grains of the crystalline structure compound A, a ratio of an area S_{A} of the crystalline structure compound A to an area S_{T} of a view field (herein, the area ratio is sometimes referred to as S_{X}: the area ratio is S_{X}=(S_{A}/S_{T})×100), in the view field when the oxide sintered body is observed with an electron microscope, is preferably 70% or more and less than 100%. When the area ratio S_{X} is 70% or more and less than 100%, the crystal grains of the Bixbyite crystalline compound represented by In₂O₃ are dissolved in a phase formed of the connected crystal grains of the crystalline structure compound A.

In the second oxide sintered body, it is more preferable that the crystal grains of the Bixbyite crystalline compound represented by In₂O₃ are dissolved in the phase formed of the crystal grains of the crystalline structure compound A, and the second oxide sintered body has a composition within the composition range R_{B}.

In the second oxide sintered body, it is further preferable that the crystal grains of the Bixbyite crystalline compound represented by In₂O₃ are dissolved in the phase formed of the crystal grains of the crystalline structure compound A, the area ratio S_{X} is 70% or more and less than 100%, and the second oxide sintered body has a composition within the composition range R_{B}.

The composition of the first oxide sintered body partially overlaps with the composition of the second oxide sintered body. This means that, even with the composition of the first oxide sintered body, depending on the mixture state of the materials, calcination condition and the like, a phase in which the crystal grains of the Bixbyite crystalline compound represented by In₂O₃ are dissolved is sometimes deposited in a phase formed of the crystal grains of the crystalline structure compound A. Also in this case, the area ratio S_{X} of the area where the crystal grains of the Bixbyite crystalline compound represented by In₂O₃ are dissolved in the phase formed of the crystal grains of the crystalline structure compound A is 70% or more and less than 100%.

A composition range of the oxide sintered body in which the crystal grains of the Bixbyite crystalline compound represented by In₂O₃ is dissolved in the phase formed of crystal grains of the crystalline structure compound A sometimes changes depending on production conditions of the oxide sintered body such as the sintering temperature and the sintering time, but generally falls within the composition range R_{B} surrounded by the above (R1), (R2), (R7), (R8) and (R9) when explained using FIG. 2 although cannot be clarified.

When the area ratio S_{X} is 70% or more and less than 100%, the Bixbyite crystalline compound represented by In₂O₃ preferably contains at least one of a gallium element or an aluminum element.

### Connecting Phase

The second oxide sintered body preferably contains a phase in which the crystal grains of the crystalline structure compound A are connected to each other and a phase in which the crystal grains of the Bixbyite crystalline compound represented by In₂O₃ are connected to each other. Herein, sometimes, the phase in which the crystal grains of the Bixbyite crystalline compound represented by In₂O₃ are connected to each other is referred to as a connecting phase I, and the phase in which the crystal grains of the crystalline structure compound A are connected to each other is referred to as a connecting phase II.

When the second oxide sintered body includes the connecting phase I and the connecting phase II, a ratio (area ratio S_{X}) of an area S_{A} of the crystalline structure compound A to an area S_{T} in the view field when the second oxide sintered body is observed with an electron microscope is preferably more than 30% and less than 70%.

It is more preferable that the second oxide sintered body includes the connecting phase I and the connecting phase II and further has at least one of a composition within the composition range R_{C} or a composition within the composition range R_{C}′.

It is further preferable that the second oxide sintered body includes the connecting phase I and the connecting phase II, has the area ratio S_{X} ranging from more than 30% and less than 70%, and further has at least one of a composition within the composition range R_{C} or a composition within the composition range R_{C}′.

A composition range of the oxide sintered body having the connecting phase in which the crystal grains of the crystalline structure compound A are connected to each other and the phase in which the crystal grains of the Bixbyite crystalline compound represented by In₂O₃ are connected to each other sometimes changes depending on production conditions of the oxide sintered body such as the sintering temperature and the sintering time, but generally falls within at least one of the composition range R_{C} surrounded by the above (R10), (R11), (R12), (R13) and (R14) or the composition range R_{C}′ surrounded by the above (R10), (R11), (R12-1), (R13-1) and (R14) when explained using FIGS. 3 and 39 although cannot be clarified.

Also in a region out of the composition range R_{C}′ and a region out of the composition range R_{C}′, the oxide sintered body sometimes contains the phase in which the crystal grains of the crystalline structure compound A are connected to each other and the phase in which the crystal grains of the Bixbyite crystalline compound represented by In₂O₃ are connected to each other. It is considered that the strength of the oxide sintered body itself is improved by having these connecting phases in the oxide sintered body. By using such an oxide sintered body, a sputtering target having excellent durability, in which cracks are less likely to occur due to thermal stress during sputtering, can be obtained.

When the area ratio S_{X} is 30% or more and less than 70%, the Bixbyite crystalline compound represented by In₂O₃ preferably contains at least one of a gallium element or an aluminum element.

### Second Dispersion System

In the second oxide sintered body, the crystal grains of the crystalline structure compound A are preferably dispersed in the phase formed of the crystal grains of the Bixbyite crystalline compound represented by In₂O₃.

When the crystal grains of the crystalline structure compound A are preferably dispersed in the phase formed of the crystal grains of the Bixbyite crystalline compound represented by In₂O₃, the ratio (area ratio S_{X}) of the area S_{A} of the crystalline structure compound A to the area S_{T} in the view field when the oxide sintered body is observed with an electron microscope is preferably more than 0% and 30% or less. When the area ratio S_{X} is more than 0% and 30% or less, the crystal grains of the crystalline structure compound A are dispersed in the phase in which the crystal grains of the Bixbyite crystalline compound represented by In₂O₃ are connected to each other.

In the second oxide sintered body, it is more preferable that the crystal grains of the crystalline structure compound A are dispersed in the phase formed of the crystal grains of the Bixbyite crystalline compound represented by In₂O₃ and the second oxide sintered body further has at least one of a composition within the composition range R_{D} or a composition within the composition range R_{D}′.

Moreover, in the second oxide sintered body, it is further preferable that the crystal grains of the crystalline structure compound A are dispersed in the phase formed of the crystal grains of the Bixbyite crystalline compound represented by In₂O₃ and the second oxide sintered body further has at least one of a composition within the composition range R_{D} or a composition within the composition range R_{D}′.

A composition range of the oxide sintered body in which the crystal grains of the crystalline structure compound A are dispersed in the phase formed of the crystal grains of the Bixbyite crystalline compound represented by In₂O₃ sometimes changes depending on production conditions of the oxide sintered body such as the sintering temperature and the sintering time, but generally falls within at least one of the composition range R_{D} surrounded by the above (R3), (R4), (R12), (R15) and (R16) or the composition range R_{D}′ surrounded by the above (R3), (R4-1), (R12-1), (R15) and (R16) when explained using FIGS. 4 and 40 although cannot be clarified.

In at least one of a region out of the composition range R_{D} or a region out of the composition range R_{D}′, the crystal grains of the crystalline structure compound A sometime are not dispersed in the phase formed of the crystal grains of the Bixbyite crystalline compound represented by In₂O₃. It is considered that the oxide sintered body having the phase in which the crystal grains of the crystalline structure compound A are dispersed exhibits a small bulk resistivity and an improved strength of the oxide sintered body itself. By using such an oxide sintered body, a sputtering target having excellent durability, in which cracks are less likely to occur due to thermal stress during sputtering, can be obtained. Moreover, it is considered that the crystal grains per se of the crystalline structure compound A are highly electric-conductive grains, and therefore, the oxide sintered body containing the crystal grains of the crystalline structure compound A exhibits a high mobility. By using the oxide sintered body having a phase in which the crystal grains of the crystalline structure compound A are dispersed, a difference in electric conductivity between the crystal grains inside the sintered body is eliminated, so that the oxide sintered body can be more stably sputtered than an oxide sintered body including gallium oxide or aluminum oxide alone or in a form of a compound such as InGaO₃ or GaAlO₃. Moreover, it is considered that coexistence of Ga and Al in the Bixbyite crystalline compound represented by In₂O₃ decreases a lattice constant, the decrease in the lattice constant shortens In interatomic distance to form an electric conductive path, whereby an oxide semiconductor having a high carrier mobility can be obtained. It can be judged that Ga and Al are solid-dissolved in the Bixbyite crystalline compound represented by In₂O₃ by measuring a composition with EDS and confirming that Ga and Al are present in In₂O₃ crystal and the lattice constant of In₂O₃ crystal obtained by the XRD measurement is smaller than that of a typical In₂O₃.

When the area ratio S_{X} is more than 0% and 30% or less, the Bixbyite crystalline compound represented by In₂O₃ preferably contains at least one of a gallium element or an aluminum element.

### Lattice Constant

In the second oxide sintered body, a lattice constant of the Bixbyite crystalline compound represented by In₂O₃ is preferably in a range from 10.05×10⁻¹⁰ m to 10.114×10⁻¹⁰ m.

The lattice constant of the Bixbyite crystalline compound represented by In₂O₃ is considered to change by solid-dissolving at least one of a gallium element or an aluminum element in the Bixbyite structure. Particularly, by solid-dissolving at least one of a gallium metal ion or an aluminum metal ion which are smaller than an indium metal ion, the lattice constant is considered to become smaller than that of In₂O₃ in a typical Bixbyite structure. It is considered that a decrease in the lattice constant improves packing of elements to obtain effects such as an improvement in thermal conductivity of the sintered body, a reduction in the bulk resistivity, and an improvement in the strength. Further, it is considered that use of the sintered body enables a stable sputtering.

When the lattice constant of the Bixbyite crystalline compound represented by In₂O₃ is 10.05×10⁻¹⁰ m or more, it is considered that such an effect as the stress inside the crystal grain is dispersed without increasing is obtained to increase the strength of the target.

When the lattice constant of the Bixbyite crystalline compound represented by In₂O₃ is 10.114×10⁻¹⁰ m or less, strain inside of the Bixbyite crystalline compound represented by In₂O₃ can be prevented from increasing, and consequently, the oxide sintered body or the sputtering target can be prevented from being cracked. Moreover, the sputtering target formed of the second oxide sintered body is used for forming a thin-film transistor, such an effect as to improve the mobility of the thin-film transistor is obtained.

The lattice constant of the Bixbyite crystalline compound represented by In₂O₃ in the oxide sintered body is preferably in a range from 10.06×10⁻¹⁰ m to 10.110×10⁻¹⁰ m, further preferably from 10.07×10⁻¹⁰ m to 10.109×10⁻¹⁰ m.

The lattice constant of the Bixbyite crystalline compound represented by In₂O₃ contained in the oxide sintered body can be calculated by Whole Pattern Fitting (WPF) analysis on a basis of an XRD pattern obtained by X-ray diffraction (XRD) measurement by crystalline structure analysis software.

The oxide sintered body according to the exemplary embodiment may consist essentially of indium (In) element, gallium (Ga) element, aluminum (Al) element and oxygen (O) element. In this case, the oxide sintered body according to the exemplary embodiment may contain inevitable impurities. For instance, 70 mass % or more, 80 mass % or more, or 90 mass % or more of the oxide sintered body according to the exemplary embodiment may be indium (In) element, gallium (Ga) element, aluminum (Al) element and oxygen (O) element. Moreover, the oxide sintered body according to the exemplary embodiment may consist of indium (In) element, gallium (Ga) element, aluminum (Al) element and oxygen (O) element. The inevitable impurities means elements that are not intentionally added but mixed in a material and during production steps. The same applies to the description below.

Examples of the inevitable impurities include alkali metal, alkaline earth metal (e.g., Li, Na, K, Rb, Mg, Ca, Sr, Ba), hydrogen (H) element, boron (B) element, carbon (C) element, nitrogen (N) element, fluorine (F) element, silicon (Si) element, and chlorine (CI) element.

### Measurement of Impurity Concentrations (H, C, N, F, Si, Cl)

Impurity concentrations (H, C, N, F, Si, Cl) in the obtained oxide sintered body can be quantitatively evaluated using a sector-dynamic secondary ion mass spectrometer SIMS analysis (IMS 7f-Auto, manufactured by AMETEK CAMECA).

Specifically, firstly, sputtering is performed on the oxide sintered body (measurement target) to a 20-μm depth from a surface of the oxide sintered body using primary ions Cs⁺ at 14.5 kV of an accelerating voltage. Subsequently, mass spectral intensities of impurities (H, C, N, F, Si, Cl) are integrated while the sputtering is performed for 100 μm square of raster, 30 μm square of a measurement area, and 1 μm of depth with primary ions.

Further, in order to calculate absolute values of the respective impurity concentrations from the mass spectrum, each impurity is implanted into the sintered body by controlling a dose amount by ion implantation to prepare a standard sample having a known impurity concentration. The mass spectral intensities of impurities (H, C, N, F, Si, Cl) are obtained from the standard sample by SIMS analysis, and the relational expression between the absolute value of the impurity concentration and the mass spectral intensity is used as a calibration curve.

Finally, using the mass spectral intensities of the oxide sintered body (measurement target) and the calibration curve, the impurity concentrations of the measurement target are calculated and taken as the absolute values of the impurity concentrations (atom·cm⁻³).

### Measurement of Impurity Concentrations (B, Na)

Impurity concentrations (B, Na) in the obtained oxide sintered body also can be quantitatively evaluated using the SIMS analysis (IMS 7f-Auto, manufactured by AMETEK CAMECA). The absolute values (atom·cm⁻³) of the impurity concentrations of the measurement target can be obtained by the same evaluation as the measurement of H, C, N, F, Si and CI except that the mass spectrum of each impurity is measured with O₂⁺ of the primary ions and 5.5 kV of the accelerating voltage of the primary ions.

### Production Method of Sintered Body

The oxide sintered body according to the exemplary embodiment is producible by mixing, molding and sintering material powders.

Examples of the material include an indium compound, gallium compound, and aluminum compound, which are preferably in a form of oxides. Specifically, indium oxide (In₂O₃), gallium oxide (Ga₂O₃), and aluminum oxide (Al₂O₃) are suitably usable.

Indium oxide powders are not particularly limited. Industrially commercially available indium oxide powders can be used. The indium oxide powders is preferably at a high purity, for instance, 4N (0.9999) or more. As the indium compound, not only oxides but also indium salts such as chlorides, nitrates, and acetates may be used.

Gallium oxide powders are not particularly limited. Industrially commercially available gallium oxide powders can be used. The gallium oxide powders is preferably at a high purity, for instance, 4N (0.9999) or more. As the gallium compound, not only oxides but also gallium salts such as chlorides, nitrates, and acetates may be used.

Aluminum oxide powders are not particularly limited. Industrially commercially available aluminum oxide powders can be used. The aluminum oxide powders is preferably at a high purity, for instance, 4N (0.9999) or more. As the aluminum compound, not only oxides but also aluminum salts such as chlorides, nitrates, and acetates may be used.

The mixing method of the material powders to be used may be wet mixing or dry mixing, and is preferably a mixing method in which the wet mixing is used in combination after the dry mixing.

A mixing step is not particularly limited, and the material powders can be mixed and pulverized once or twice or more. As a mixing and pulverizing means, for example, a known device such as a ball mill, a bead mill, a jet mill or an ultrasonic device can be used. The mixing and pulverizing means is preferably a wet mixing using a bead mill.

The material prepared in the above mixing step is molded by a known method to obtain a molded product, and the molded product is sintered to obtain an oxide sintered body.

In the molding step, the mixed powder obtained in the mixing step is subjected to, for instance, pressure-forming to form a molding body. Through the above step, the material powder is molded into a shape of a product (e.g. a shape suitable for a sputtering target).

Examples of molding process include mold molding, casting molding, and injection molding. In order to obtain a sintered body having a high sintering density, Cold Isostatic Pressing (CIP) or the like is preferably used for the molding.

A molding aid may be used in the molding process. Examples of the molding aid include polyvinyl alcohol, methyl cellulose, polywax, and oleic acid.

In the sintering step, the molding body obtained in the molding step is sintered.

The molding body is sintered under sintering conditions: under atmospheric pressure, oxygen gas atmosphere or oxygen gas pressurization, usually at from 1200 degrees C. to 1550 degrees C., usually 30 minutes to 360 hours, preferably 8 hours to 180 hours, more preferably 12 hours to 96 hours.

When the sintering temperature is less than 1200 degrees C., the density of the target may be not easily increased or too much time may be required in order to sinter the molding body. On the other hand, if the sintering temperature exceeds 1550 degrees C., the composition may shift or the furnace may be damaged due to the vaporization of the components.

When the sintering time is 30 minutes or more, it is easy to increase the density of the target. If the sintering time is longer than 360 hours, the producing time is too long and the cost is high, so that it cannot be practically adopted. When the sintering time falls within the above range, the relative density can be easily improved and the bulk resistivity can be easily lowered.

Since the oxide sintered body according to the exemplary embodiment contains the crystalline structure compound A, a stable sputtering can be achieved by using a sputtering target containing the oxide sintered body, and a high process durability and a high mobility can be achieved in TFT including a thin film produced through the sputtering.

### Sputtering Target

A sputtering target according to the exemplary embodiment can be obtained by using the oxide sintered body according to the exemplary embodiment.

For example, the sputtering target according to the exemplary embodiment can be obtained by cutting and polishing an oxide sintered body and bonding the oxide sintered body to a backing plate.

A bonding ratio between the sintered body and the backing plate is preferably 95% or more. The bonding ratio can be checked by X-ray CT.

The sputtering target according to the exemplary embodiment includes the oxide sintered body according to the exemplary embodiment and the backing plate.

The sputtering target according to the exemplary embodiment preferably includes the oxide sintered body according to the exemplary embodiment, and a cooler/holder such as the backing plate, which is, as required, provided to sintered body.

An oxide sintered body (target material) forming the sputtering target according to the exemplary embodiment can be obtained by grinding the oxide sintered body according to the exemplary embodiment. Therefore, the target material is the same as the oxide sintered body according to the exemplary embodiment as a substance. Therefore, the same description of the oxide sintered body according to the exemplary embodiment applies to the target material.

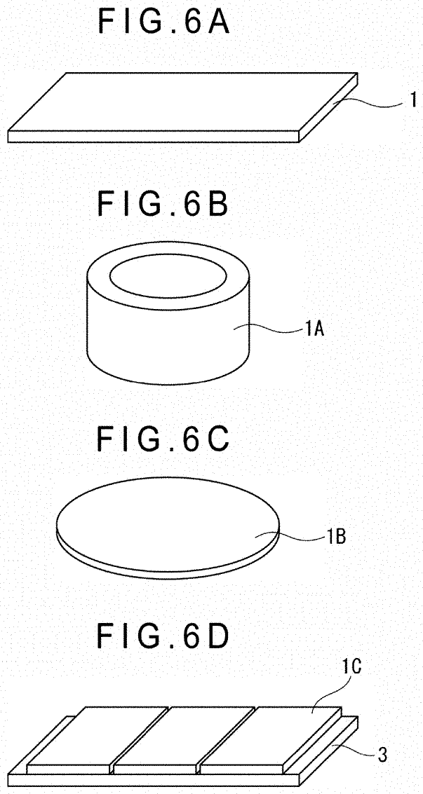

FIG. 6 shows perspective views of shapes of the sputtering target.

The sputtering target may be shaped in a plate as shown in a numeral reference 1 in FIG. 6A.

The sputtering target may be shaped in a hollow cylinder as shown in a numeral reference 1A in FIG. 6B.

When the sputtering target is shaped in a plate, a planar shape may be rectangular as shown in the numeral reference 1 in FIG. 6A. or circular as shown in a numeral reference 1B in FIG. 6C. The oxide sintered body may be integrally molded, or may be of a multi-divided type in which a plurality of divided oxide sintered bodies (numeral reference 1C) are fixed to the backing plate 3 as shown in FIG. 6D.

The backing plate 3 is a holder/cooler for the oxide sintered body. The backing plate 3 is preferably made of a material with excellent thermal conductivity (e.g. copper).

It should be noted that the shape of the oxide sintered body forming the sputtering target is not limited to the shapes shown in FIG. 6.

The sputtering target is produced, for instance, according to the following steps.

A step for grinding a surface of the oxide sintered body (grinding step).

A step for bonding the oxide sintered body on the backing plate (bonding step).

The above steps will be specifically described below.

### Grinding Step

In a grinding step, the oxide sintered body is cut into a shape suitable for attachment to a sputtering device.

The surface of the oxide sintered body often has a sintered portion in a highly oxidized state and/or an uneven surface. Moreover, the oxide sintered body needs to be cut into a predetermined size.

A surface of the oxide sintered body is preferably ground by 0.3 mm or more. A grinding depth is preferably 0.5 mm or more, more preferably 2 mm or more. When the grinding depth is 0.3 mm or more, the fluctuating portion of the crystal structure near the surface of the oxide sintered body can be removed.

For instance, it is preferable to grind the oxide sintered body with a surface grinder to obtain a material having an average surface roughness Ra of 5 μm or less. Further, the sputtering surface of the sputtering target may be mirror-finished so that the average surface roughness Ra is 1000×10⁻¹⁰ m or less. For mirror polishing (polishing), known polishing techniques such as mechanical polishing, chemical polishing, and mechanochemical polishing (combination of mechanical polishing and chemical polishing) can be used. For instance, the surface may be polished using a fixed-abrasive-grain polisher (polishing liquid: water) to #2000 or finer grain size, or may be lapped using diamond-paste polishing material after lapping using a loose-abrasive-grain lapping material (polishing material: SiC paste etc.). The polishing method is not limited to the above. Examples of the polishing material include #200, #400, and even #800 polishing materials.

The oxide sintered body after the polishing step is preferably cleaned with an air blower or washed with running water and the like. When a foreign substance is to be removed using an air blower, air is preferably sucked with a dust catcher provided at a side opposite a nozzle for effective removal. It should be noted that ultrasonic cleaning may further be performed in view of the limited cleaning power of the air blower and running water. The ultrasonic cleaning is effectively performed with multiple frequencies ranging from 25 kHz to 300 kHz. For instance, it is favorable to perform ultrasonic cleaning by oscillating 12 kinds of frequencies in 25 kHz increments between frequencies in a range from 25 kHz to 300 kHz.

### Bonding Step

In a bonding step, the oxide sintered body after grinding is bonded to the backing plate using a low melting point metal. Metal indium is preferably used as the low melting point metal. Also, metal indium containing at least one of gallium metal or stannum metal is preferably usable as the low melting point metal.

Since the sputtering target according to the exemplary embodiment uses the oxide sintered body containing the crystalline structure compound A, a stable sputtering can be achieved by using this sputtering target, and a high process durability and a high mobility can be achieved in TFT including a thin film produced through the sputtering.

The sputtering target has been described as the above.

### Crystalline Oxide Thin Film

A crystalline oxide thin film according to the exemplary embodiment can be formed using the sputtering target according to the exemplary embodiment.

The crystalline oxide thin film according to the exemplary embodiment preferably contains the indium element (In), gallium element (Ga) and aluminum element (Al), and the indium element (In), gallium element (Ga) and aluminum element (Al) are preferably present within a composition range R_{E} surrounded by points (R16), (R3), (R4) and (R17) below represented by atomic % ratios in the In—Ga—Al ternary composition diagram.

In:Ga:Al=82:1:17 (R16)

In:Ga:Al=90:1:9 (R3)

In:Ga:Al=90:9:1 (R4)

In:Ga:Al=82:17:1 (R17)

FIG. 5 shows an In—Ga—Al ternary composition diagram. FIG. 5 shows the composition range R_{E} surrounded by the above (R16), (R3), (R4) and (R17).

The crystalline oxide thin film according to the exemplary embodiment preferably contains the indium element (In), gallium element (Ga) and aluminum element (Al), and the indium element (In), gallium element (Ga) and aluminum element (Al) are also preferably present within a composition range R_{E}′ surrounded by points (R16-1), (R3), (R4-1) and (R17-1) below represented by atomic % ratios in the In—Ga—Al ternary composition diagram.

In:Ga:Al=80:1:19 (R16-1)

In:Ga:Al=90:1:9 (R3)

In:Ga:Al=90:8.5:1.5 (R4-1)

In:Ga:Al=80:18.5:1.5 (R17-1)

FIG. 41 shows an In—Ga—Al ternary composition diagram. FIG. 41 shows the composition range R_{E}′ surrounded by the above (R16-1), (R3), (R4-1) and (R17-1).

The crystalline oxide thin film according to the exemplary embodiment can provide a thin-film transistor having a high process durability and a high mobility.

The crystalline oxide thin film having at least one of a composition falling within the composition range R_{E} surrounded by the above (R16), (R3), (R4) and (R17) or a composition falling within the composition range R_{E}′ surrounded by the above (R16-1), (R3), (R4-1) and (R17-1) has a crystal lattice constant of 10.114×10⁻¹⁰ m or less, and exhibits a unique electrical conductivity by having a unique atomic packing structure. This is considered because the oxide sintered body contains crystal grains of the crystalline structure compound A having an unknown structure, a crystalline oxide thin film having an atomic packing with a unique structure is generated. The oxide sintered body is used for the sputtering target and the sputtering target is used for forming a film. The formed film, which is an amorphous film, is subsequently heated for further crystallization, so that a crystalline oxide thin film can be obtained. Alternatively, a crystalline oxide thin film can be obtained by forming a thin film containing nano-crystals while heating. Since the lattice constant of the crystals of the crystalline oxide thin film is 10.114×10⁻¹⁰ m or less, the crystalline oxide thin film is formed of indium oxide crystals in which at least one of a Ga element or an Al element is solid-dissolved and the indium oxide crystals in which at least one of a Ga element or an Al element is solid-dissolved have a dense packing structure, whereby, in the crystalline oxide thin film, an indium atomic distance is shorter and 5S orbits of indium more overlap than a typical indium oxide thin film. With these actions, a thin film transistor having the crystalline oxide thin film has high mobility and operates more stably. Due to the stability of packing of the atoms in the crystalline oxide thin film, a thin film transistor having less leakage current and excellent stability is obtainable.

In an exemplary form of the crystalline oxide thin film according to the exemplary embodiment, the atomic % ratios of the indium element (In), gallium element (Ga) and aluminum element (Al) are further preferably in ranges represented by formulae (17) to (19) below.

82≤In/(In+Ga+Al)≤90 (17)

3≤Ga/(In+Ga+Al)≤15 (18)

1.5≤Al/(In+Ga+Al)≤15 (19)

In the formulae (17) to (19), In, Al and Ga respectively represent the number of atoms of the indium element, aluminum element and gallium element in the oxide semiconductor thin-film.

In the exemplary form of the crystalline oxide thin film according to the exemplary embodiment, the atomic % ratios of the indium element (In), gallium element (Ga) and aluminum element (Al) are further preferably in ranges represented by formulae (17-1), (18-1) and (19-1) below.

80≤In/(In+Ga+Al)≤90 (17-1)

3≤Ga/(In+Ga+Al)≤15 (18-1)

1.5≤Al/(In+Ga+Al)≤10 (19-1)

In the formulae (17-1), (18-1) and (19-1), In, Al and Ga respectively represent the number of atoms of the indium element, aluminum element and gallium element in the oxide semiconductor thin-film.

In the exemplary form of the crystalline oxide thin film according to the exemplary embodiment, the atomic % ratios of the indium element (In), gallium element (Ga) and aluminum element (Al) are more preferably in ranges represented by formulae (17-2), (18-2) and (19-2) below.

80≤In/(In+Ga+Al)≤90 (17-2)

8≤Ga/(In+Ga+Al)≤15 (18-2)

1.7≤Al/(In+Ga+Al)≤8 (19-2)

In the formulae (17-2), (18-2) and (19-2), In, Al and Ga respectively represent the number of atoms of the indium element, aluminum element and gallium element in the oxide semiconductor thin-film.

When the ratio of In element in the film formed by using the sputtering target is equal to or more than the lower limit of the formula (17-1) or the formula (17-2), a crystalline oxide thin film can be easily obtained. When the ratio of In element in the film formed by using the sputtering target is equal to or less than the upper limit of the formula (17-1) or the formula (17-2), a mobility of TFT using the obtained crystalline oxide thin film is likely to become high.

When the ratio of Ga element in the film formed by using the sputtering target is equal to or more than the lower limit of the formula (18-1) or the formula (18-2), a mobility of TFT using the obtained crystalline oxide thin film is likely to become high and a band gap thereof is likely to become larger than 3.5 eV. When the ratio of Ga element in the film formed by using the sputtering target is equal to or less than the upper limit of the formula (18-1) or the formula (18-2), Vth of TFT using the obtained crystalline oxide thin film can be prevented from significantly shifting toward a negative value and a on/off ratio thereof is likely to increase.

When the ratio of Al element in the film formed by using the sputtering target is equal to or more than the upper limit of the formula (19-1) or the formula (19-2), a mobility of TFT using the obtained crystalline oxide thin film is likely to become high. When the ratio of Al element in the film formed by using the sputtering target is equal to or less than the upper limit of the formula (19-1) or the formula (19-2), Vth of TFT using the obtained crystalline oxide thin film can be prevented from significantly shifting toward a negative value.

The crystalline oxide thin film according to the exemplary embodiment is preferably a Bixbyite crystal represented by In₂O₃.

The crystalline oxide thin film according to the exemplary embodiment becomes the Bixbyite crystal, which is represented by In₂O₃, obtained by crystalizing a formed film by heating, or by crystalizing an amorphous film by heating after the film formation.

The thin-film transistor using the crystalline oxide thin film exhibits a high mobility and a favorable stability.

In the crystalline oxide thin film according to the exemplary embodiment, a lattice constant of Bixbyite crystal represented by In₂O₃ is preferably 10.05×10⁻¹⁰ m or less, more preferably 10.03×10⁻¹⁰ m or less, further preferably 10.02×10⁻¹⁰ m or less, still further preferably 10×10⁻¹⁰ m or less.

In the crystalline oxide thin film according to the exemplary embodiment, a lattice constant of Bixbyite crystal represented by In₂O₃ is preferably 9.9130×10⁻¹⁰ m or more, more preferably 9.9140×10⁻¹⁰ m or more, further preferably 9.9150×10⁻¹⁰ m or more.

The lattice constant of the Bixbyite crystal represented by In₂O₃ in the crystalline oxide thin film is smaller than 10.114×10⁻¹⁰ m shown by a typical indium oxide. This is considered to be because the packing of atoms in the crystalline oxide thin film according to the exemplary embodiment becomes dense, and the crystalline oxide thin film according to the exemplary embodiment has a unique structure. Accordingly, the thin-film transistor using the crystalline oxide thin film according to the exemplary embodiment exhibits a high mobility, a small leak current, and a favorable photostability due to the bandgap of 3.5 eV or more.

The metal elements contained in the crystalline oxide thin film according to the exemplary embodiment need to include indium, gallium and aluminum and may consist essentially of indium, gallium and aluminum. In this case, inevitable impurities may be contained in the amorphous oxide semiconductor film. Indium, gallium and aluminum may account for 80 atomic % or more, 90 atomic % or more, 95 atomic % or more, 96 atomic % or more, 97 atomic % or more, 98 atomic % or more, or 99 atomic % or more of the metal elements contained in the crystalline oxide thin film according to the exemplary embodiment. Also the metal element contained in the crystalline oxide thin film according to the exemplary embodiment may consist of indium, gallium and aluminum.

### Amorphous Oxide Thin Film

An amorphous oxide thin film according to the exemplary embodiment contains indium oxide, gallium oxide and aluminum oxide as main components.

Since the amorphous oxide thin film is amorphous, many levels are usually made in a band gap. Accordingly, absorption at ends of the band occurs, where carriers or vacancies are created by absorption of, especially, the short-wavelength light, so that threshold voltage (Vth) of the thin-film transistor (TFT) for which the amorphous oxide thin film is used may be changed to significantly deteriorate the TFT properties or the thin-film transistor may not serve as a transistor.

The amorphous oxide thin film according to the exemplary embodiment simultaneously contains the indium oxide, gallium oxide, and aluminum oxide, so that the absorption end shifts toward the short-wavelength side, and the amorphous oxide thin film does not absorb the light in a visible light region, thereby improving photostability. The presence of gallium ions and aluminum ions, whose ion diameters are smaller than the ion diameter of indium, reduces the distance between positive ions, thereby improving the carrier mobility in TFT. Further, since the indium oxide, gallium oxide, and aluminum oxide are simultaneously contained, an amorphous oxide semiconductor film with excellent carrier mobility, transparency and photostability can be provided.

The “indium oxide, gallium oxide, and aluminum oxide as main components” herein means that indium oxide, gallium oxide, and aluminum oxide accounts for 50 mass % or more, preferably 70 mass % or more, more preferably 80 mass % or more, further preferably 90 mass % or more of the oxides in the oxide film.

When the contents of the indium oxide, gallium oxide, and aluminum oxide are 50 mass % or more of the oxides, saturation mobility in the thin-film transistor is unlikely to be deteriorated.

Whether the oxide thin film is “amorphous” herein can be determined based on an absence of clear peak(s) in an X-ray diffraction measurement of the oxide film (i.e. showing a broad pattern).

The amorphous oxide thin film can provide excellent uniformity of the film surface and reduce in-plane unevenness of the TFT properties.

The crystalline oxide thin film according to the exemplary embodiment can provide a thin-film transistor having a high process durability and a high mobility.

A preferable exemplary form of the amorphous oxide thin film according to the exemplary embodiment is an amorphous oxide thin film containing the indium element (In), gallium element (Ga) and aluminum element (Al) which are present within a composition range RF surrounded by (R16), (R17) and (R18) below represented by atomic % ratios in the In—Ga—Al ternary composition diagram.

In:Ga:Al=82:1:17 (R16)

In:Ga:Al=82:17:1 (R17)

In:Ga:Al=66:17:17 (R18)

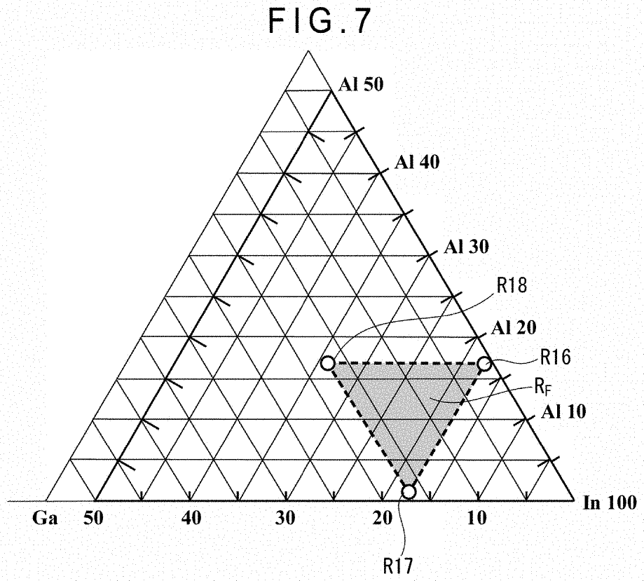

FIG. 7 shows an In—Ga—Al ternary composition diagram. FIG. 7 shows the composition range RF surrounded by the above (R16), (R17), and (R18).

A preferable exemplary form of the amorphous oxide thin film according to the exemplary embodiment is an amorphous oxide thin film containing the indium element (In), gallium element (Ga) and aluminum element (Al) which are present within a composition range RF′ surrounded by (R16-1), (R17-1) and (R18-1) below represented by atomic % ratios in the In—Ga—Al ternary composition diagram.

In:Ga:Al=80:1:19 (R16-1)

In:Ga:Al=80:18.5:1.5 (R17-1)

In:Ga:Al=62.5:18.5:19 (R18-1)

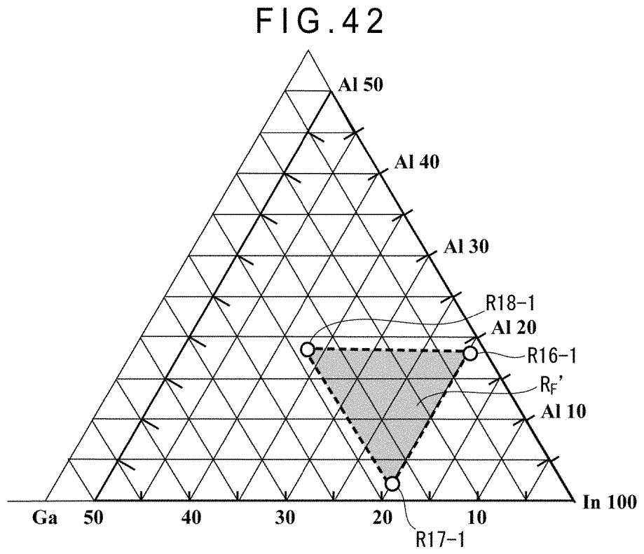

FIG. 42 shows an In—Ga—Al ternary composition diagram. FIG. 42 shows the composition range RF′ surrounded by the above (R16-1), (R17-1), and (R18-1).

A thin film having at least one of the composition range RF surrounded by the above (R16), (R17), and (R18) or the composition range RF′ surrounded by the above (R16-1), (R17-1), and (R18-1) is an amorphous thin film. On the other hand, the lattice constant of the Bixbyite crystal represented by In₂O₃ in the crystalline oxide thin film according to the exemplary embodiment is far smaller than a typically expected lattice constant. Therefore, the crystalline oxide thin film is considered to have a unique atomic-packing structure. This unique atomic-packing formation acts to shorten the indium interatomic distance so as to form an amorphous structure similar to the dense packing structure of the crystalline thin film without forming a completely disordered structure even if the film becomes amorphous. With this action, the 5S orbits of the indium elements are more likely to overlap with each other, and as a result, the thin-film transistor having the amorphous oxide thin film according to the exemplary embodiment operates stably. With the stability of the atomic packing in the amorphous oxide thin film, the thin-film transistor having less leakage current and excellent stability is obtained.

Depending on the crystallization temperature and the heating method, the film may be crystallized or be kept in an amorphous state immediately after the film formation. By selecting the crystallization method as desired, the amorphous oxide thin film having at least one of the composition within the composition range RF surrounded by (R16), (R17) and (R18) or the composition range RF′ surrounded by (R16-1), (R17-1) and (R18-1) can be obtained.

In an exemplary form of the amorphous oxide thin film according to the exemplary embodiment, the atomic % of the indium element (In), gallium element (Ga) and aluminum element (Al) is further preferable in a range represented by formulae (20) to (22) below.

70≤In/(In+Ga+Al)≤82 (20)

3≤Ga/(In+Ga+Al)≤15 (21)

1.5≤Al/(In+Ga+Al)≤15 (22)

In the formulae (20) to (22), In, Al and Ga respectively represent the number of atoms of the indium element, aluminum element and gallium element in the oxide semiconductor thin-film.

In the exemplary form of the amorphous oxide thin film according to the exemplary embodiment, the atomic % of the indium element (In), gallium element (Ga) and aluminum element (Al) is further preferable in a range represented by formulae (20-1), (21-1) and (22-1) below.

70≤In/(In+Ga+Al)≤80 (20-1)

3≤Ga/(In+Ga+Al)<15 (21-1)

2≤Al/(In+Ga+Al)≤15 (22-1)

In the formulae (20-1), (21-1) and (22-1), In, Al and Ga respectively represent the number of atoms of the indium element, aluminum element and gallium element in the oxide semiconductor thin-film.

Herein, the atomic ratio of each of the metal elements in the oxide thin-film (the crystalline oxide thin film and the amorphous oxide thin film) can be determined by measuring an abundance amount of each of the elements through induced plasma emission spectrometer (ICP-AES) measurement or XRF (X-Ray Fluorescence) measurement. An inductively coupled plasma emission spectrometer can be used for the ICP measurement. A thin-film X-ray fluorescence spectrometer (AZX400, manufactured by Rigaku Corporation) can be used for the XRF measurement.

The content (atomic ratio) of each of the metal elements in the oxide thin-film can also be analyzed using a sector-dynamic secondary ion mass spectrometer SIMS analysis at an accuracy equivalent to that of induced plasma emission analysis. A reference material is prepared by forming source/drain electrodes (made of the same material as in a TFT device) of a channel length on an upper surface of a reference oxide thin-film whose atomic ratio of the metal elements is known by measurement using the inductively coupled plasma emission spectrometer or the thin-film X-ray fluorescence spectrometer. Then, the oxide semiconductor layer is analyzed using a sector-dynamic SIMS (Secondary Ion Mass Spectrometer) (IMS 7f-Auto, manufactured by AMETEK, Inc.) to measure a mass spectrum intensity of each of the elements, thereby preparing plot calibration curves for the concentrations and mass spectrum intensity of the known elements. Next, the atomic ratio in the oxide semiconductor thin-film of an actual TFT device is calculated with reference to the above-described calibration curves based on the spectrum intensity obtained by the sector-dynamic SIMS (Secondary Ion Mass Spectrometry) analysis. As a result of the calculation, it can be confirmed that the calculated atomic ratio falls within 2 atomic % of the atomic ratio of the oxide semiconductor thin-film separately measured by the thin-film X-ray fluorescent spectrometer or the inductively coupled plasma emission spectrometer.

The metal elements contained in the amorphous oxide thin film according to the exemplary embodiment need to include indium, gallium and aluminum and may consist essentially of indium, gallium and aluminum. In this case, inevitable impurities may be contained in the amorphous oxide semiconductor film. Indium, gallium and aluminum may account for 80 atomic % or more, 90 atomic % or more, 95 atomic % or more, 96 atomic % or more, 97 atomic % or more, 98 atomic % or more, or 99 atomic % or more of the metal elements contained in the amorphous oxide thin film according to the exemplary embodiment. Also the metal element contained in the amorphous oxide thin film according to the exemplary embodiment consist of indium, gallium and aluminum.

In another preferably exemplary form of the amorphous oxide thin film according to the exemplary embodiment is an amorphous oxide thin film having a composition represented by a composition formula (1) below.

(InₓGa_{y}Al_{z})₂O₃ (1)

In composition formula (1),

0.47≤x≤0.53,

0.17≤y≤0.33,

0.17≤z≤0.33, and

x+y+z=1.

In another preferably exemplary form of the amorphous oxide thin film according to the exemplary embodiment is an amorphous oxide thin film having a composition represented by a composition formula (2) below.

(InₓGa_{y}Al_{z})₂O₃ (2)

In the composition formula (2),

0.47≤x≤0.53,

0.17≤y≤0.43,

0.07≤z≤0.33, and

x+y+z=1.

A bulk resistivity of the oxide sintered body having a composition in a region represented by the composition formula (1) or the composition formula (2) is lower than a bulk resistivity at the surrounding region of the oxide sintered body and exhibits a unique electric conductivity. This is considered to be because the oxide sintered body has an unknown structure to have a unique structure of an atomic packing, resulting in generation of a low resistant sintered body. A thin film produced using the sputtering target containing the oxide sintered body acts to shorten the indium interatomic distance so as to form an amorphous structure similar to the dense packing structure of the crystalline thin film without forming a completely disordered structure even if the film becomes amorphous. With this action, the 5S orbits of the indium element is more likely to overlap with each other, and, as a result, the thin-film transistor having this film according to the exemplary embodiment operates stably. With the stability of the atomic packing, the thin-film transistor having less leak current and excellent stability is obtainable.

### Forming Method of Amorphous Oxide Thin Film

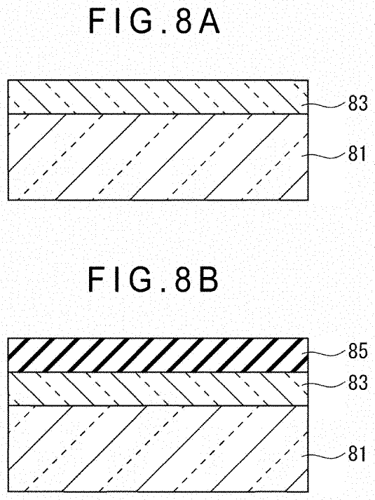

The amorphous oxide thin film according to the exemplary embodiment is formed by sputtering a sputtering target obtained from the oxide sintered body according to the exemplary embodiment and another exemplary embodiment (see FIG. 8A).

Other than by sputtering, the amorphous oxide thin film can be formed, for instance, by a method selected from the group consisting of vapor deposition, ion plating, and pulse laser vapor deposition.

The method of forming the amorphous oxide thin film according to the exemplary embodiment is applicable to the crystalline oxide thin film according to the exemplary embodiment.

The atomic composition of the amorphous oxide thin film according to the exemplary embodiment is usually the same as the atomic composition of the sputtering target (oxide sintered body) used for forming the film.

A case where the amorphous oxide thin film is formed on a substrate by sputtering the sputtering target obtained from the oxide sintered body according to the exemplary embodiment and another exemplary embodiment will be described below.

As the sputtering, a method selected from the group consisting of DC sputtering, RF sputtering, AC sputtering, and pulse DC sputtering is applicable. With either method, sputtering without abnormal electrical discharge is possible.

The sputtering gas may be a mixture gas of argon and oxidative gas. The oxidative gas is gas selected from the group consisting of O₂, CO₂, O₃, and H₂O.

A thin-film formed by sputtering on a substrate can be kept amorphous under the conditions below even after the thin-film is annealed, whereby excellent semiconductor properties can be exhibited.

The annealing temperature is, for instance, 500 degrees C. or less, preferably in a range from 100 to 500 degrees C., further preferably in a range from 150 to 400 degrees C., especially preferably 250 to 400 degrees C. The annealing time is usually 0.01 to 5.0 hours, preferably 0.1 to 3.0 hours, more preferably 0.5 to 2.0 hours.

The atmosphere for annealing is, though not particularly limited, preferably atmospheric air or oxygen-circulation atmosphere in terms of carrier controllability, more preferably atmospheric air. During the annealing, a lamp annealing machine, laser annealing machine, thermal plasma machine, hot-blast heater, contact heater or the like is usable under the presence or absence of oxygen.

The annealing (heat treatment) is preferably performed after a protection film covering the thin-film on the substrate is formed (see FIG. 8(B)).

The protection film can be any film made of one selected from the group consisting of SiO₂, SiON, Al₂O₃, Ta₂O₅, TiO₂, MgO, ZrO₂, CeO₂, K₂O, Li₂O, Na₂O, Rb₂O, Sc₂O₃, Y₂O₃, Hf₂O₃, CaHfO₃, PbTiO₃, BaTa₂O₆, and SrTiO₃. Among the above, the protection film is preferably any film made of one selected from the group consisting of SiO₂, SiON, Al₂O₃, Y₂O₃, Hf₂O₃, and CaHfO₃, more preferably a film of SiO₂ or Al₂O₃. The number of oxygen in the above oxides is not necessarily the same as a stoichiometric ratio (for instance, representable by any of SiO₂ or SiOx). The protection film is adapted to serve as a protective insulating film.

The protection film is capable of being formed through plasma CVD or sputtering, preferably formed through sputtering in a rare-gas atmosphere containing oxygen.

The thickness of the protection film is suitably set as desired, for instance, in a range from 50 to 500 nm.

### Thin-Film Transistor

Examples of the thin-film transistor according to the exemplary embodiment includes a thin-film transistor containing the crystalline oxide thin film according to the exemplary embodiment, a thin-film transistor containing the amorphous oxide thin film according to the exemplary embodiment, and a thin-film transistor containing both of the crystalline oxide thin film and the amorphous oxide thin film according to the exemplary embodiment.

A channel layer of the thin-film transistor is preferably the crystalline oxide thin film according to the exemplary embodiment or the amorphous oxide thin film according to the exemplary embodiment.

When the thin-film transistor according to the exemplary embodiment has amorphous oxide thin film according to the exemplary embodiment as the channel layer, the rest of the device arrangement in the thin-film transistor is not particularly limited, but any known device arrangement is employable.

Another exemplary form of the thin-film transistor according to the exemplary embodiment is a thin-film transistor containing an oxide semiconductor thin-film containing the indium element (In), gallium element (Ga) and aluminum element (Al) which are present within a composition range surrounded by points (R1), (R2), (R3), (R4), (R5) and (R6) below represented by atomic % ratios in the In—Ga—Al ternary composition diagram.

In:Ga:Al=45:22:33 (R1)

In:Ga:Al=66:1:33 (R2)

In:Ga:Al=90:1:9 (R3)

In:Ga:Al=90:9:1 (R4)

In:Ga:Al=54:45:1 (R5)

In:Ga:Al=45:45:10 (R6)

The channel layer of the thin-film transistor is also preferably the oxide semiconductor thin-film present within the composition range surrounded by the above atomic % ratios (R1), (R2), (R3), (R4), (R5) and (R6) in the In—Ga—Al ternary composition diagram.

When the thin-film transistor according to the exemplary embodiment has, as the channel layer, the oxide semiconductor thin-film present within the composition range surrounded by the atomic % ratios (R1), (R2), (R3), (R4), (R5) and (R6) above in the In—Ga—Al ternary composition diagram, the rest of the device arrangement in the thin-film transistor is not particularly limited, but any known device arrangement is employable.

In the exemplary form of the oxide semiconductor thin-film containing the thin-film transistor according to the exemplary embodiment, the atomic % of the indium element (In), gallium element (Ga) and aluminum element (Al) is further preferable in a range represented by formulae (23) to (25) below.

48≤In/(In+Ga+Al)≤90 (23)

3≤Ga/(In+Ga+Al)≤33 (24)

1≤Al/(In+Ga+Al)≤30 (25)

In the formulae (23) to (25), In, Al and Ga respectively represent the number of atoms of the indium element, aluminum element and gallium element in the oxide semiconductor thin-film.

In the exemplary form of the oxide semiconductor thin-film containing the thin-film transistor according to the exemplary embodiment, the atomic % of the indium element (In), gallium element (Ga) and aluminum element (Al) is further preferable in a range represented by formulae (23-1), (24-1) and (25-1) below.

48≤In/(In+Ga+Al)≤90 (23-1)

3≤Ga/(In+Ga+Al)≤33 (24-1)

1.5≤Al/(In+Ga+Al)≤30 (25-1)

In the formulae (23-1), (24-1) and (25-1), In, Al and Ga respectively represent the number of atoms of the indium element, aluminum element and gallium element in the oxide semiconductor thin-film.

The thin-film transistor of the invention is suitably applicable to a display (e.g. liquid crystal display and organic EL display).

A film thickness of the channel layer in the thin-film transistor of the exemplary embodiment is typically in a range from 10 nm to 300 nm, preferably from 20 nm to 250 nm.

The channel layer in the thin-film transistor of the exemplary embodiment, which is usually used to provide an N-type region, is applicable in combination with various P-type semiconductors (e.g. P-type Si semiconductor, P-type oxide semiconductor, P-type organic semiconductor) to various semiconductor devices such as a PN junction transistor.

The thin-film transistor according to the exemplary embodiment is also applicable to various integrated circuits such as a field-effect transistor, logic circuit, memory circuit, and differential amplifier. In addition to the field-effect transistor, the thin-film transistor is also applicable to an electrostatic inductive transistor, Schottky barrier transistor, Schottky diode, and resistor.

The thin-film transistor according to the exemplary embodiment may be constructed in any manner without limitation and may have known structure such as bottom-gate, bottom-contact, and top-contact structures.

Among the above, the bottom-gate structure is advantageous in view of higher performance than thin-film transistors of amorphous silicon and ZnO. The bottom-gate structure is also preferable for the adaptability in reducing the number of masks during the production process, which results in reduction in the production cost of large-size displays and the like.

The thin-film transistor of the exemplary embodiment is suitably usable for a display.

Channel-etching bottom-gate thin-film transistors are especially preferable for use in large-size displays. The channel-etching bottom-gate thin-film transistors, which require a small number of photomasks in a photolithography process, allow the production of display panels at a low production cost. Especially, channel-etching bottom-gate and channel-etching top-contact thin-film transistors are preferable in terms of excellent performance (e.g. carrier mobility) and industrial applicability.

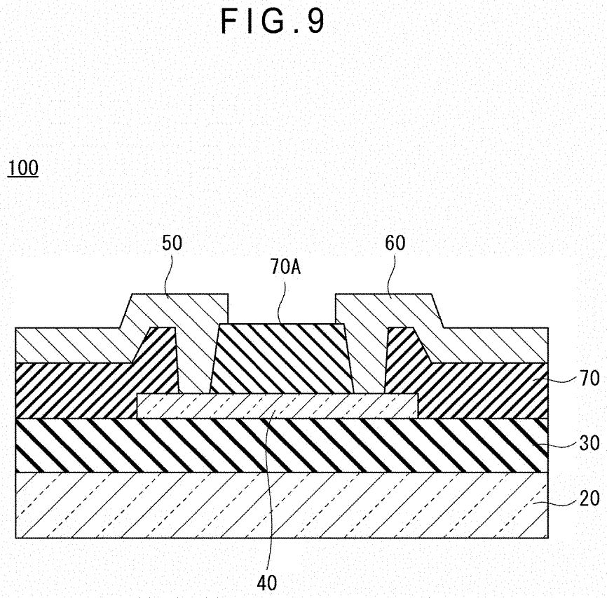

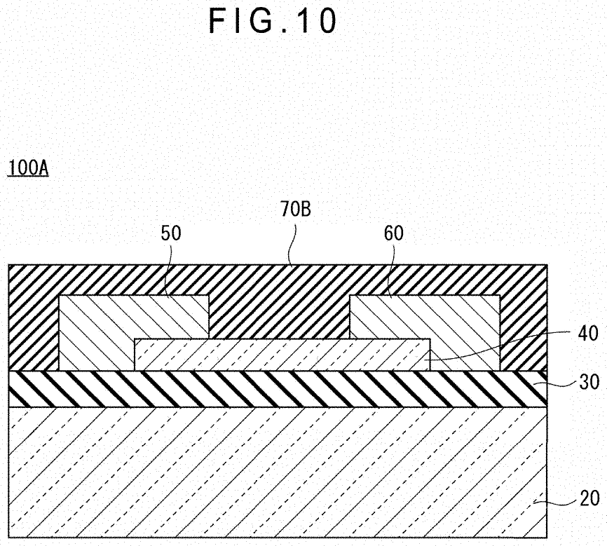

Specific examples of the thin-film transistor are shown in FIGS. 9 and 10.

As shown in FIG. 9, a thin-film transistor 100 includes a silicon wafer 20, a gate insulating film 30, an oxide semiconductor thin-film 40, a source electrode 50, a drain electrode 60, and interlayer insulating films 70, 70A.

The silicon wafer 20 defines a gate electrode. The gate insulating film 30, which is an insulating film for insulation between the gate electrode and the oxide semiconductor thin-film 40, is provided on the silicon wafer 20.

The oxide semiconductor thin-film 40 (channel layer) is provided on the gate insulating film 30. As the oxide semiconductor thin-film 40, the oxide thin-film (at least one of crystalline oxide thin film or the amorphous oxide thin film) according to the exemplary embodiment is usable.

The source electrode 50 and the drain electrode 60, which are conductive terminals for passing source current and drain current through the oxide semiconductor thin-film 40, are in contact with parts near respective ends of the oxide semiconductor thin-film 40.

The interlayer insulating film 70 is an insulating film for insulating parts other than the contact portions between the source electrode 50 (drain electrode 60) and the oxide semiconductor thin-film 40.

The interlayer insulating film 70A is an insulating film for insulating parts other than the contact portions between the source electrode 50 (drain electrode 60) and the oxide semiconductor thin-film 40. The interlayer insulating film 70A is also an insulating film for insulation between the source electrode 50 and the drain electrode 60, and also serves as a protection layer for the channel layer.

As shown in FIG. 10, the structure of a thin-film transistor 100A is substantially the same as the thin-film transistor 100, except that the source electrode 50 and the drain electrode 60 are in contact with both of the gate insulating film 30 and the oxide semiconductor thin-film 40, and that an interlayer insulating film 70B is integrally provided to cover the gate insulating film 30, the oxide semiconductor thin-film 40, the source electrode 50, and the drain electrode 60.

A still another form of the thin-film transistor according to the exemplary embodiment is a thin-film transistor having the oxide semiconductor thin-film in a laminate structure. As an example of this form, the oxide semiconductor thin-film 40 of the thin-film transistor 100 has a laminate structure. In the thin-film transistor in this form, the oxide semiconductor thin-film 40 as the channel layer preferably has the crystalline oxide thin film according to the exemplary embodiment as a first layer, and the amorphous oxide thin film according to the exemplary embodiment as a second layer. The crystalline oxide thin film according to the exemplary embodiment as the first layer is preferably an active layer of the thin-film transistor. It is preferable that the crystalline oxide thin film according to the exemplary embodiment as the first layer is in contact with the gate insulating film 30 and the amorphous oxide thin film according to the exemplary embodiment as the second layer is laminated on the first layer. The amorphous oxide thin film according to the exemplary embodiment as the second layer is preferably in contact with at least one of the source electrode 50 or the drain electrode 60. By laminating the first layer and second layer, a high mobility is achievable and a threshold voltage (Vth) is controllable to approximately 0 V.

The material for the drain electrode 60, the source electrode 50 and the gate electrode are not particularly limited but may be selected from generally known materials. In the examples shown in FIGS. 9 and 10, the silicon wafer is used for the substrate. Though the silicon wafer also serves as an electrode, the material of the electrode is not necessarily silicon.

For instance, the electrode may be a transparent electrode made of, for instance, ITO (Indium Tin Oxide), IZO (Indium Zinc Oxide), ZnO, and SnO₂, a metal electrode made of Al, Ag, Cu, Cr, Ni, Mo, Au, Ti, Ta, or the like, a metal electrode made of an alloy containing the above metal elements, or a laminated electrode of layers made of the alloy.

The gate electrode shown in FIGS. 9 and 10 may be formed on a substrate made of glass or the like.

The material for the interlayer insulating films 70, 70A and 70B is not particularly limited but may be selected as desired from generally known materials. Specifically, the interlayer insulating films 70, 70A, 70B may be made of a compound such as SiO₂, SiNx, Al₂O₃, Ta₂O₅, TiO₂, MgO, ZrO₂, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, and AlN.

When the thin-film transistor according to the exemplary embodiment is a back-channel-etching (bottom-gate) thin-film transistor, it is preferable to provide a protection film on the drain electrode, the source electrode and the channel layer. The protection film enhances the durability against a long-term driving of the TFT. In a top-gate TFT, the gate insulating film is formed on, for instance, the channel layer.

The protection film or the insulating film can be formed, for instance, through a CVD process, which sometimes entails high-temperature treatment. The protection film or the insulating film often contains impurity gas immediately after being formed, and thus preferably subjected to a heat treatment (annealing). The heat treatment removes the impurity gas to provide a stable protection film or insulating film, and, consequently, highly durable TFT device.

With the use of the oxide semiconductor thin-film according to the exemplary embodiment, the TFT device is less likely to be affected by the temperature in the CVD process and the subsequent heat treatment. Accordingly, the stability of the TFT properties can be enhanced even when the protection film or the insulating film is formed.

Among the transistor properties, On/Off characteristics determine display performance of display devices. When the thin-film transistor is used as a switching device of liquid crystal, On/Off ratio is preferably six or more digits. OLED, which is current-driven and whose On-current is of importance, also preferably has six or more digits On/Off ratio.

The thin-film transistor of the exemplary embodiment preferably has On/Off ratio equal to or more than 1×10⁶.

The On/Off ratio can be determined as a ratio [On current value/Off current value] of On current value (a value of Id when Vg=20 V) to Off current value (a value of Id when Vg=−10 V).

The carrier mobility in the TFT of the exemplary embodiment is preferably 5 cm²/Vs or more, more preferably 10 cm²/Vs or more.

The saturation mobility is determined based on a transfer function when a 20 V drain voltage is applied. Specifically, the saturation mobility can be calculated by: plotting a graph of a transfer function Id-Vg; calculating transconductance (Gm) for each Vg; and calculating the saturation mobility using a formula in a saturated region. It should be noted Id represents a current between the source and drain electrodes, and Vg represents a gate voltage when the voltage Vd is applied between the source and drain electrodes.

A threshold voltage (Vth) is preferably in a range from −3.0 V to 3.0 V, more preferably from −2.0 V to 2.0 V, further preferably from −1.0 V to 1.0 V. At the threshold voltage (Vth) of −3.0 V or more, a thin-film transistor with a high carrier mobility is obtainable. At the threshold voltage (Vth) of 3.0 V or less, a thin-film transistor with small Off current and a large On/Off ratio is obtainable.

The threshold voltage (Vth) is defined as Vg at Id=10⁻⁹ A based on the graph of the transfer function.

The On/Off ratio is preferably in a range from 10⁶ to 10¹², more preferably from 10⁷ to 10¹¹, further preferably from 10⁸ to 10¹⁰. At the On/Off ratio of 10⁶ or more, a liquid crystal display can be driven. At the On/Off ratio of 10¹² or less, an organic EL device with a large contrast can be driven. Moreover, at the On/Off ratio of 10¹² or less, the off current can be set at 10⁻¹¹ A or less, allowing an increase in image-holding time and improvement in sensitivity when the thin-film transistor is used for a transfer transistor or a reset transistor of a CMOS image sensor.

### Quantum-Tunneling Field-Effect Transistor

The oxide semiconductor thin-film of the exemplary embodiment is usable for a quantum-tunneling Field-Effect Transistor (FET).

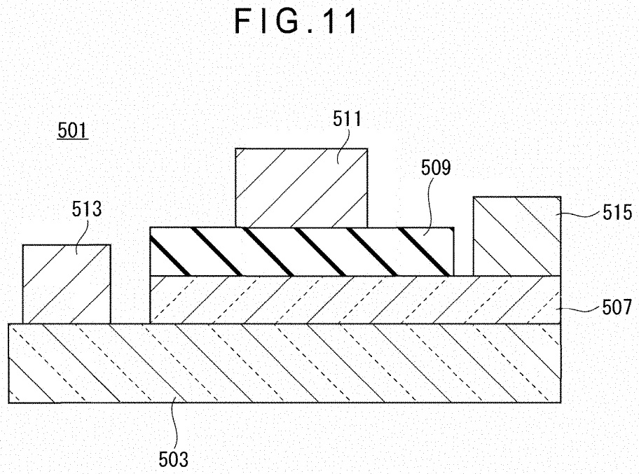

FIG. 11 is a schematic illustration (vertical cross section) of a quantum-tunneling FET (Field-Effect Transistor) in an exemplary form according to an exemplary embodiment.

A quantum-tunneling field-effect transistor 501 includes a p-type semiconductor layer 503, an n-type semiconductor layer 507, a gate insulating film 509, a gate electrode 511, a source electrode 513, and a drain electrode 515.

The p-type semiconductor layer 503, the n-type semiconductor layer 507, the gate insulating film 509, and the gate electrode 511 are laminated in this order.

The source electrode 513 is provided on the p-type semiconductor layer 503. The drain electrode 515 is provided on the n-type semiconductor layer 507.

The p-type semiconductor layer 503 is a layer of a p-type IV group semiconductor layer, which is a p-type silicon layer in the exemplary embodiment.

The n-type semiconductor layer 507 is an n-type oxide semiconductor thin-film according to the exemplary embodiment. The source electrode 513 and the drain electrode 515 are conductive films.

Though not shown in FIG. 11, an insulation layer may be provided on the p-type semiconductor layer 503. In this case, the p-type semiconductor layer 503 and the n-type semiconductor layer 507 are connected through a contact hole(s) defined by partially removing the insulation layer. Though not shown in FIG. 11, the quantum-tunneling field-effect transistor 501 may be provided with an interlayer insulating film covering an upper side of the quantum-tunneling field-effect transistor 501.

The quantum-tunneling field-effect transistor 501 is a current-switching quantum-tunneling FET (Field-Effect Transistor) for controlling the electric current tunneled through an energy barrier formed by the p-type semiconductor layer 503 and the n-type semiconductor layer 507 using a voltage applied to the gate electrode 511. With this structure, the band gap of the oxide semiconductor of the n-type semiconductor layer 507 can be increased, thereby decreasing the off current.

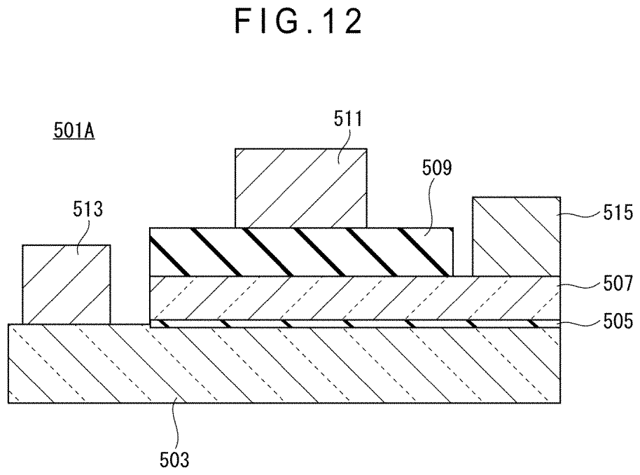

FIG. 12 is a schematic illustration (vertical cross section) of a quantum-tunneling field-effect transistor 501A according to another exemplary embodiment.

The structure of the quantum-tunneling field-effect transistor 501A is the same as the structure of the quantum-tunneling field-effect transistor 501 except that a silicon oxide layer 505 is interposed between the p-type semiconductor layer 503 and the n-type semiconductor layer 507. The off current can be reduced by the presence of the silicon oxide layer.

The thickness of the silicon oxide layer 505 is preferably 10 nm or less. At the thickness of 10 nm or less, the tunnel current securely passes through the energy barrier and the energy barrier can be securely formed with a constant barrier height, preventing the decrease or change in the tunneling current. The thickness of the silicon oxide layer 505 is preferably 8 nm or less, more preferably 5 nm or less, further preferably 3 nm or less, and especially preferably 1 nm or less.

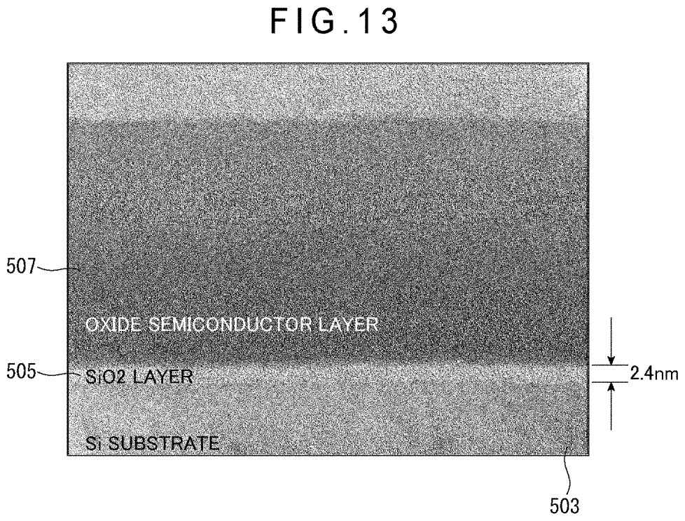

FIG. 13 is a TEM photograph of a portion where a silicon oxide layer 505 is formed between a p-type semiconductor layer 503 and an n-type semiconductor layer 507.

The n-type semiconductor layer 507 in both of the quantum-tunneling field-effect transistors 501 and 501A is an n-type oxide semiconductor.

The oxide semiconductor of the n-type semiconductor layer 507 may be amorphous. Since the oxide semiconductor forming the n-type semiconductor layer 507 is amorphous, the oxide semiconductor can be etched using an organic acid (e.g. oxalic acid) at a large difference in etching rate from the other layer(s), so that the etching process can be favorably performed without any influence on the metal layer (e.g. wiring).

The oxide semiconductor of the n-type semiconductor layer 507 may alternatively be crystalline. The crystalline oxide semiconductor exhibits a larger band gap than the amorphous oxide semiconductor, so that the off current can be reduced. Further, since the work function can be increased, the control over the current tunneled through the energy barrier formed by the p-type IV group semiconductor material and the n-type semiconductor layer 507 can be facilitated.

A non-limiting example of the production method of the quantum-tunneling field-effect transistor 501 will be described below.

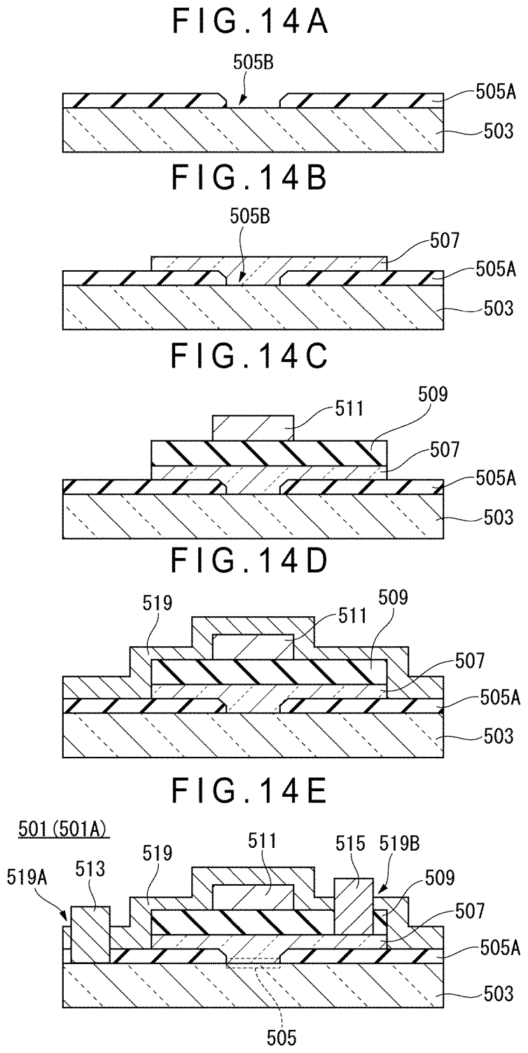

Initially, as shown in FIG. 14A, an insulating film 505A is formed on the p-type semiconductor layer 503. Then, a part of the insulating film 505A is removed by etching or the like to form a contact hole 505B.

Subsequently, as shown in FIG. 14B, the n-type semiconductor layer 507 is formed on the p-type semiconductor layer 503 and the insulating film 505A. At this time, the p-type semiconductor layer 503 and the n-type semiconductor layer 507 are connected through the contact hole 505B.

Subsequently, as shown in FIG. 14C, the gate insulating film 509 and the gate electrode 511 are formed in this order on the n-type semiconductor layer 507.

Then, as shown in FIG. 14D, an interlayer insulating film 519 is formed to cover the insulating film 505A, the n-type semiconductor layer 507, the gate insulating film 509 and the gate electrode 511.

Next, as shown in FIG. 14E, the insulating film 505A on the p-type semiconductor layer 503 and the interlayer insulating film 519 are partially removed to form a contact hole 519A, in which the source electrode 513 is provided.

Further, as shown in FIG. 14E, the gate insulating film 509 on the n-type semiconductor layer 507 and the interlayer insulating film 519 are partially removed to form a contact hole 5196, in which the drain electrode 515 is formed.

The quantum-tunneling field-effect transistor 501 is produced through the above process.

It should be noted that the silicon oxide layer 505 between the p-type semiconductor layer 503 and the n-type semiconductor layer 507 can be formed by applying a heat treatment at a temperature ranging from 150 degrees C. to 600 degrees C. after the n-type semiconductor layer 507 is formed on the p-type semiconductor layer 503. The quantum-tunneling field-effect transistor 501A can be produced through the process including the above additional step.

The thin-film transistor of the exemplary embodiment is preferably a doped-channel thin-film transistor. The doped-channel transistor refers to a transistor whose carrier in the channel is appropriately controlled not by the oxygen vacancy, which is easily affected by external stimuli such as atmosphere and temperature, but by an n-type doping, for achieving both high carrier mobility and high reliability.

### Usage of Thin-Film Transistor

The thin-film transistor according to the exemplary embodiment of the invention is also capable of being embodied as various integrated circuits such as a field-effect transistor, logic circuit, memory circuit, and differential amplifier, which are applicable to electronic devices. Further, the thin-film transistor according to the exemplary embodiment of the invention is also applicable to an electrostatic inductive transistor, Schottky barrier transistor, Schottky diode, and resistor, in addition to the field-effect transistor.

The thin-film transistor of the exemplary embodiment is suitably usable for a display, solid-state image sensor, and the like.

A display and a solid-state image sensor incorporating the thin-film transistor according to the exemplary embodiment will be described below.

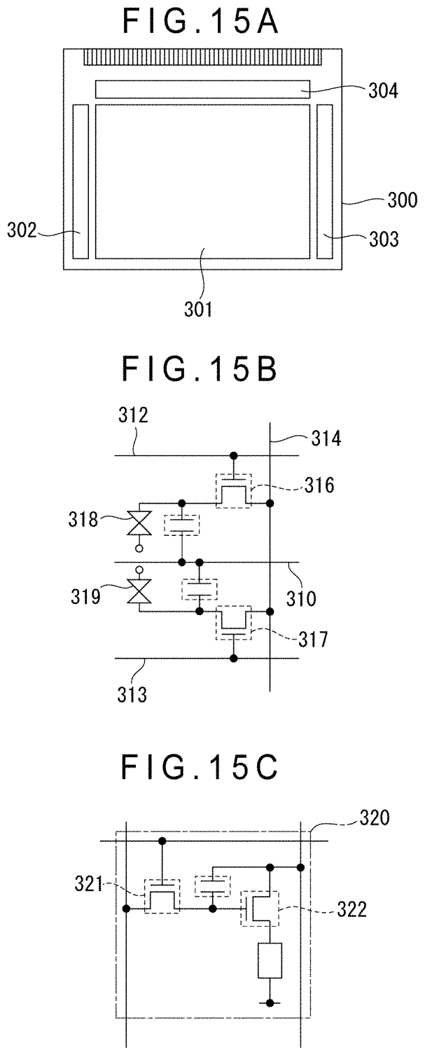

Initially, a display incorporating the thin-film transistor according to the exemplary embodiment of the invention will be described with reference to FIG. 15.

FIG. 15A is a top plan view of a display according to an exemplary embodiment of the invention. FIG. 15B is a circuit diagram showing a circuit of a pixel unit in a form of a liquid crystal device of the display according to the exemplary embodiment. FIG. 15B is a circuit diagram showing another circuit of a pixel unit in a form of an organic EL device of the display according to the exemplary embodiment.

The transistor in the pixel unit may be the thin-film transistor of the exemplary embodiment. The thin-film transistor of the exemplary embodiment is easily made into an n-channel type. Accordingly, a part of the drive circuit capable of being provided by an n-channel transistor is formed on the same substrate as the transistor of the pixel unit. A highly reliable display can be provided using the thin-film transistor of the exemplary embodiment for the pixel unit and/or the drive circuit.

FIG. 15A is a top plan view showing an example of an active matrix display. The display includes a substrate 300, and a pixel unit 301, a first scan line drive circuit 302, a second scan line drive circuit 303, and a signal line drive circuit 304 formed on the substrate 300. Multiple signal lines extend from the signal line drive circuit 304 to the pixel unit 301. Multiple scan lines extend from the first scan line drive circuit 302 and the second scan line drive circuit 303 to the pixel unit 301. Pixels each including a display element are provided in a matrix at intersections of the scan lines and the signal lines. The substrate 300 of the display is connected to a timing controller (controller, also referred to as a control IC) through a connector such as an FPC (Flexible Printed Circuit).

As shown in FIG. 15A, the first scan line drive circuit 302, the second scan line drive circuit 303, and the signal line drive circuit 304 are provided on the same substrate 300 as the pixel unit 301. Such an arrangement results in reduction in the number of external component (e.g. drive circuit) and, consequently, reduction in production cost. In addition, when the drive circuit is provided outside the substrate 300, the lines have to be extended and the connection between the lines increases. With the drive circuit being provided on the same substrate 300, the number of connections between the lines can be reduced, thereby improving the reliability and yield rate.

An example of a pixel circuit is shown in FIG. 15B. FIG. 9B shows a circuit of a pixel unit applicable to a pixel unit of a VA liquid crystal display.

The circuit of the pixel unit is applicable to a device having a plurality of pixel electrodes in one pixel. The pixel electrodes are each connected to different transistors, whereby each of the transistors is drivable in accordance with a different gate signal. Thus, the signals to be applied to the respective pixel electrodes of a multi-domain structure can be independently controlled.

A gate line 312 of a transistor 316 and a gate line 313 of a transistor 317 are separated so that different gate signals are inputted thereto. However, a source electrode or drain electrode 314 serving as a data line is common to the transistors 316 and 317. The transistors 316 and 317 may be the transistor of the exemplary embodiment. A highly reliable liquid crystal display can be thereby provided.

First and second pixel electrodes are electrically connected to the transistors 316 and 317, respectively. The first pixel electrode is separated from the second pixel electrode. Shapes of the first and second pixel electrodes are not particularly limited. For instance, the first pixel electrode may be V-shaped.

Gate electrodes of the transistors 316 and 317 are connected with the gate lines 312 and 313, respectively. Different gate signals can be inputted to the gate lines 312 and 313 so that the transistors 316 and 317 are operated at different timings, thereby controlling orientation of the liquid crystal.

A capacity line 310, a gate insulating film serving as a dielectric, and a capacity electrode electrically connected with the first pixel electrode or the second pixel electrode may be provided to define a holding capacity.

In a multi-domain structure, first and second liquid crystal devices 318 and 319 are provided in one pixel. The first liquid crystal device 318 includes the first pixel electrode, an opposing electrode, and a liquid crystal layer interposed between the first pixel electrode and the opposing electrode. The second liquid crystal device 319 includes the second pixel electrode, an opposing electrode, and a liquid crystal layer interposed between the second pixel electrode and the opposing electrode.

The pixel unit is not necessarily arranged as shown in FIG. 15B. The pixel unit shown in FIG. 15B may additionally include a switch, a resistor, a capacitor, a transistor, a sensor, and/or a logic circuit.

Another example of the pixel circuit is shown in FIG. 15C. Illustrated is a structure of a pixel unit in a display using an organic EL device.

FIG. 15C illustrates an applicable example of a circuit of a pixel unit 320. In this example, two n-channel transistors are used in one pixel. The oxide semiconductor film according to the exemplary embodiment is usable in a channel formation region of an n-channel transistor. The circuit of the pixel unit can be driven in accordance with digital pulse width modulation control.

A switching transistor 321 and a drive transistor 322 may be the thin-film transistor according to the exemplary embodiment of the invention. A highly reliable organic EL display can be thereby provided.

The circuit of the pixel unit is not necessarily arranged as shown in FIG. 15C. The circuit of the pixel unit shown in FIG. 15C may additionally include a switch, a resistor, a capacitor, a sensor, a transistor, and/or a logic circuit.

The thin-film transistor of the exemplary embodiment used in a display has been described above.

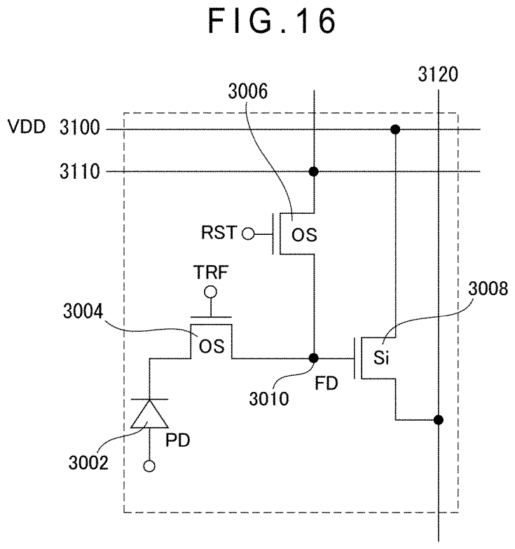

Next, a solid-state image sensor incorporating the thin-film transistor according to the exemplary embodiment of the invention will be described with reference to FIG. 16.

CMOS (Complementary Metal Oxide Semiconductor) image sensor is a solid-state image sensor including a signal charge accumulator for holding an electric potential, and an amplification transistor for transferring (outputting) the electric potential to a vertical output line. When the signal charge accumulator is charged or discharged by a possible leak current from the reset transistor and/or the transfer transistor of the CMOS image sensor, the electric potential of the signal charge accumulator changes. The change in the electric potential of the signal charge accumulator results in the change in the electric potential of the amplification transistor (i.e. shift from a desired value), deteriorating the quality of the captured image.

An effect of the thin-film transistor according to the exemplary embodiment of the invention incorporated in the reset transistor and transfer transistor of the CMOS image sensor will be described below. The amplification transistor may be any one of the thin-film transistor and a bulk transistor.

FIG. 16 illustrates an exemplary arrangement of the CMOS image sensor. The pixel includes a photodiode 3002 (photoelectric converter), a transfer transistor 3004, a reset transistor 3006, an amplification transistor 3008, and various lines. A plurality of the pixels are arranged in a matrix to form the sensor. A selector transistor may be electrically connected to the amplification transistor 3008. The characters in the transistor signs each represent a preferable material to be used for the transistors, where “OS” represents Oxide Semiconductor and “Si” represents silicon. The same applies to the other drawing(s).

The photodiode 3002 is connected to a source of the transfer transistor 3004. A signal charge accumulator 3010 (also referred to as FD (Floating Diffusion)) is provided to a drain of the transfer transistor 3004. The source of the reset transistor 3006 and the gate of the amplification transistor 3008 are connected to the signal charge accumulator 3010. A reset power line 3110 may be omitted in other embodiments. For instance, the drain of the reset transistor 3006 may be connected with a power line 3100 or a vertical output line 3120 instead of the reset power line 3110.

The oxide semiconductor film according to the exemplary embodiment of the invention, which may be made of the same material as the oxide semiconductor film used for the transfer transistor 3004 and the reset transistor 3006, may be used in the photodiode 3002.

The thin-film transistor of the exemplary embodiment used in a display has been described above.

### EXAMPLES

An aspect(s) of the invention will be described below with reference to Examples and Comparatives. It should however be noted that the scope of the invention is not limited to Examples.

### Preparation of Oxide Sintered Body

### Examples 1 to 14

Powders of gallium oxide, aluminum oxide, and indium oxide were weighed for compositions (atomic ratios) as shown in Tables 1 to 4, and put in a polyethylene pot and mixed/pulverized using a dry ball mill for 72 hours to prepare a mixture powder.

The mixture powder was put in a die and pressed at a pressure of 500 kg/cm² to prepare a molding body.

The molding body was compacted through CIP at a pressure of 2000 kg/cm².

Next, this compacted molding-body was placed in an atmospheric-pressure sintering furnace and was kept at 350 degrees C. for 3 hours. Subsequently, the temperature inside the furnace was raised at a temperature increase rate of 100 degrees C./hr., was kept at 1350 degrees C. for 24 hours, and was left and cooled to obtain an oxide sintered body.

The following items of the obtained oxide sintered body were evaluated.

Evaluation results are shown in Tables 1 to 4.

### Property Evaluation of Oxide Sintered Body

### (1) XRD Measurement

XRD (X-Ray Diffraction) of the obtained oxide sintered body was measured using an X-ray diffractiometer Smartlab under the conditions below. The resultant XRD chart was analyzed using JADE6 to determine the crystalline phase in the oxide sintered body.
Machine: Smartlab (manufactured by Rigaku Corporation)
X-ray: Cu—K α ray (wavelength 1.5418×10⁻¹⁰ m)
2θ-θ Reflection method, Continuous Scan (2.0°/min.)
Sampling interval: 0.02°
Slit DS (Divergence Slit), SS (Scattering Slit), RS (Receiving Slit): 1 mm

### (1-2) Lattice Constant

The XRD pattern obtained by the above XRD measurement was subjected to Whole Pattern Fitting (WPF) analysis using JADE6 to specify each of crystalline components included in the XRD pattern and calculate a lattice constant of an In₂O₃ crystalline phase in the obtained oxide sintered body.

### (2) Relative Density

The relative density of the obtained oxide sintered body was calculated. The “relative density” herein refers to a value represented by percentage obtained by dividing an actual density of the oxide sintered body, which is measured by Archimedes method, by a theoretical density of the oxide sintered body. In the invention, the theoretical density is calculated as follows.

Theoretical density=(total weight of material powder for the oxide sintered body)/(total volume of the material powder of the oxide sintered body)

For instance, when use amounts (charge amounts) of an oxide A_{X}, oxide B, oxide C, and oxide D, which are the material powders of the oxide sintered body, are represented by a(g), b(g), c(g), and d(g), respectively, the theoretical density can be calculated according to the formula below.

Theoretical density=(a+b+c+d)/((a/density of oxide A_{X})+(b/density of oxide B)+(c/density of oxide C)+(d/density of oxide D)

It should be noted that the density of each of the oxides is substantially equal to the specific gravity of each of the oxides. Accordingly, the value of the specific gravity described in “Handbook of Chemistry: Pure Chemistry, Chemical Society of Japan, revised 2nd ed. (MARUZEN-YUSHODO Company, Limited) was used as the value of the density.

(3) Bulk Resistivity (mΩ·cm)

The bulk resistivity (mΩ·cm) of the obtained oxide sintered body was measured according to a four-probe method (JIS R 1637:1998) using a resistivity meter Loresta (manufactured by Mitsubishi Chemical Corporation).

Five points (the center of the oxide sintered body, and four middle points between four corners of the oxide sintered body and the center of the oxide sintered body) were measured and averaged to calculate the bulk resistivity.

### (4) SEM-EDS Measurement Method

SEM observation, a ratio of crystal grains in the oxide sintered body, and a composition ratio were evaluated with Scanning Electron Microscope (SEM:)/Energy Dispersive X-ray Spectroscopy (EDS). The oxide sintered body cut into a 1 cm square or less was sealed into a 1-inch φ epoxy-based room temperature curing resin. Further, the sealed oxide sintered body was polished using abrasive paper #400, #600, #800, 3-μm diamond suspension water, and 1-μm silica water colloidal silica (for final finishing) in this order. The oxide sintered body was observed with an optical microscope, and polishing was performed until there were no polishing marks of 1 μm or more on the polished surface of the oxide sintered body. The surface of the polished oxide sintered body was subjected to SEM-EDS measurement using a scanning electron microscope SU8220 manufactured by Hitachi High-Technologies Corporation. The accelerating voltage was 8.0 kV, and an SEM image with an area size of 25 μm×20 μm was observed at a magnification of 3000 times, and EDS performed point measurement.

### (5) Identification of Crystalline Structure Compound A by EDS

For the EDS measurement, point measurements were performed at 6 or more points for different areas in one SEM image. The composition ratio of each element was calculated by EDS by identifying the element by the energy of fluorescent X-rays obtained from the sample and then converting the obtained data of each element into a quantitative composition ratio using the ZAF method.

(6) Calculation Method of Ratio of Crystalline Structure Compound A from SEM Image

The ratio of the crystalline structure compound A was calculated by performing image analysis on the SEM image using SPIP, Version 4.3.2.0 manufactured by Image Metrology. First, the contrast of the SEM image was quantified to obtain (maximum density-minimum density)×½ height, which was set as a threshold value. Next, the part equal to or less than the threshold value in the SEM image was defined as a hole, and the area ratio of the hole to the entire image was calculated. This area ratio was taken as the ratio of the crystalline structure compound A in the oxide sintered body.

### Evaluation Results

### Examples 1 and 2

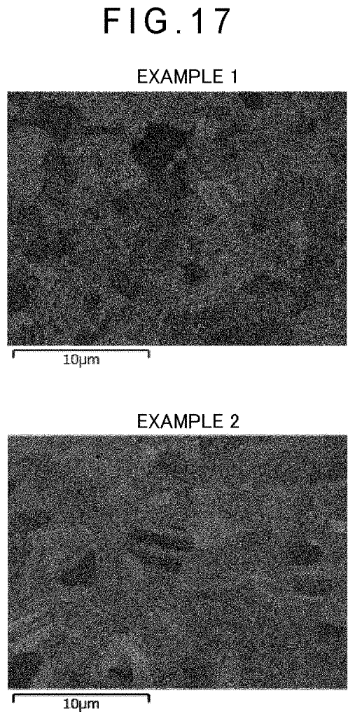

FIG. 17 shows SEM photographs of the oxide sintered bodies of Examples 1 and 2, respectively.

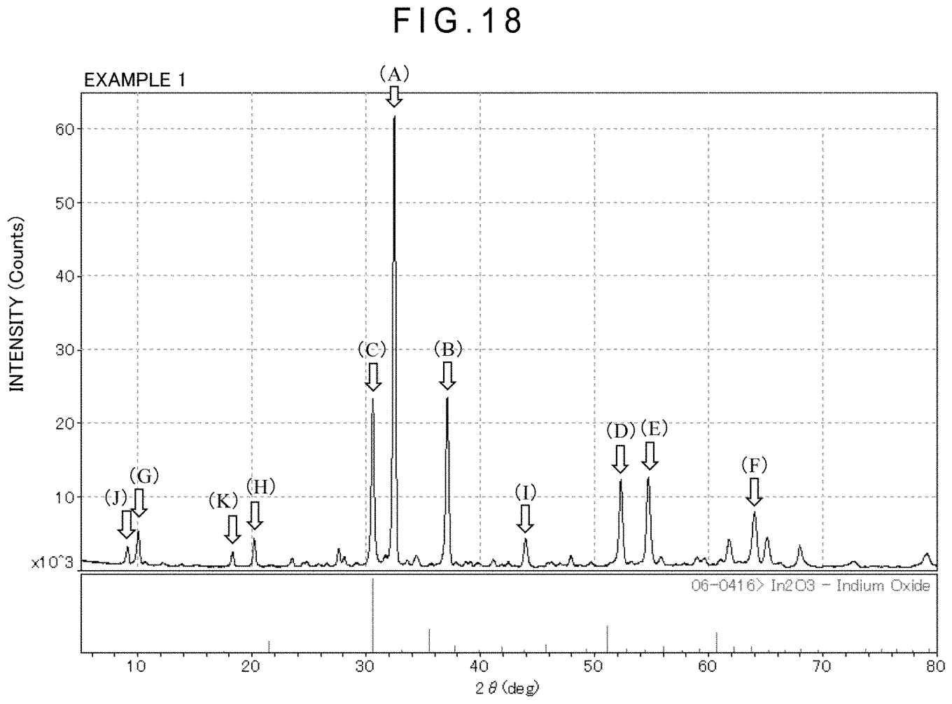

FIG. 18 shows the XRD measurement results (XRD chart) of the oxide sintered body of Example 1.

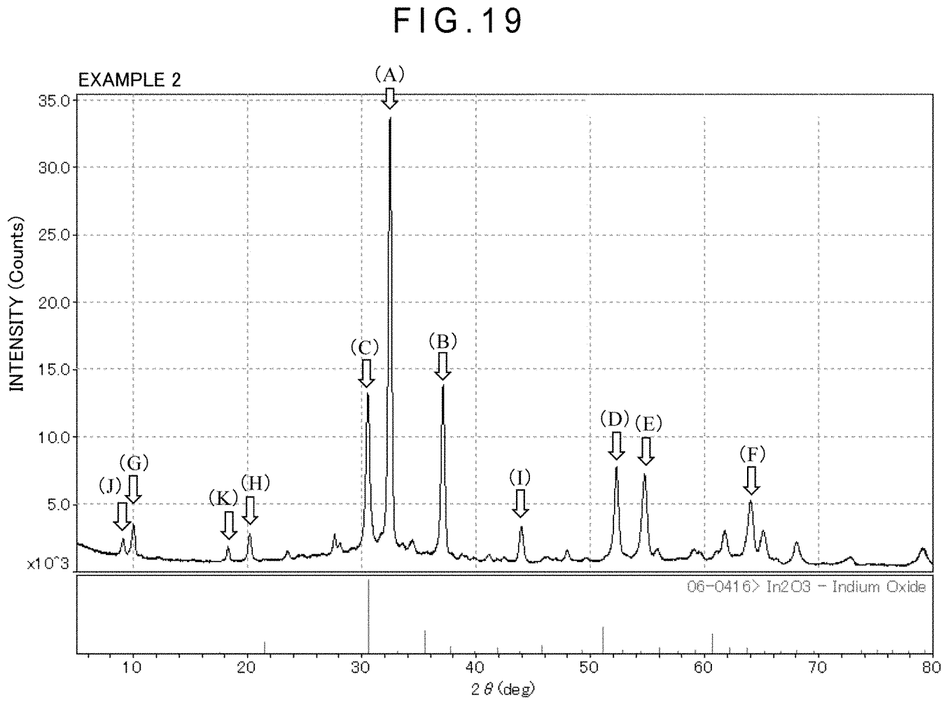

FIG. 19 shows the XRD measurement results (XRD chart) of the oxide sintered body of Example 2.

Table 1 shows composition ratios (atomic ratios) of In:Ga:Al obtained by the SEM-EDS measurement of the oxide sintered bodies of Examples 1 and 2.

TABLE 1

| | | Example 1 | Example 2 |
|---|---|---|---|
| Composition | In₂O₃ | 64.4 | 65.7 |
| (mass %) | Ga₂O₃ | 26.1 | 22.2 |
| | Al₂O₃ | 9.5 | 12.1 |
| Composition | In | 50.0 | 50.0 |
| (at %) | Ga | 30.0 | 25.0 |
| | Al | 20.0 | 25.0 |
| Production | Sintering Temperature | 1350 | 1350 |
| Conditions | (C) | | |
| | Sintering Time | 24 | 24 |
| | (hr) | | |
| Relative Density (%) | | 98.4 | 98.1 |
| Bulk Resistivity (mΩ · cm) | | 9.1 | 12.0 |
| XRD | Main Components | Crystalline | Crystalline |
| Measurement | | Structure | Structure |
| | | Compound A | Compound A |
| SEM-EDS | In | 49 | 50 |
| (at %) | Ga | 31 | 28 |
| | Al | 20 | 22 |
| | Ratio of Area of | 100 | 100 |
| | Crystalline Structure | | |
| | Compound A (%) | | |

It has been found from Table 1 that the oxide sintered bodies of Examples 1 and 2 each are the crystalline structure compound A satisfying the composition represented by the composition formula (1) or (2). This oxide sintered body has semiconductor properties and is useful.

As shown in the SEM image of FIG. 17, only a connecting phase of the crystalline structure compound A was observed in the oxide sintered body of Example 1. An indium oxide phase was not observed in a view field shown in the SEM image. The result of elemental analysis (inductively coupled plasma emission spectrophotometer (ICP-AES)) was In:Ga:Al=50:30:20 at %, which was the same as the charged composition. The composition of the connecting phase of the crystalline structure compound A in Example 1 was In:Ga:Al=49:31:20 at % as a result of SEM-EDS measurement, which was substantially the same as the charged composition.

As shown in the SEM image of FIG. 17, only a connecting phase of the crystalline structure compound A was observed in the oxide sintered body of Example 2. An indium oxide phase was not observed in a view field shown in the SEM image. The result of elemental analysis was In:Ga:Al=50:25:25 at %, which was the same as the charged composition. The composition of the connecting phase of the crystalline structure compound A in Example 2 was In:Ga:Al=50:28:22 at % as a result of SEM-EDS measurement, which was substantially the same as the charged composition.

As shown in FIGS. 18 and 19, the oxide sintered bodies of Examples 1 and 2 had a diffraction peak in each of ranges of an incidence angle (2θ) defined by the above (A) to (K) as measured by X-ray (Cu—K α ray) diffraction measurement. It has been found through JADE6 analysis that the crystal with the diffraction peaks in the respective ranges (A) to (K) does not match known compounds but has an unknown crystal phase.

In the XRD charts shown in FIGS. 18 and 19, there was no peak overlapping with the peaks of the indium oxide of the Bixbyite structure. Accordingly, it is considered that the oxide sintered bodies of Examples 1 and 2 do not substantially contain the indium oxide phase.

Table 1 also shows properties of the oxide sintered body of the crystalline structure compound A in each of Examples 1 and 2.

A relative density of the oxide sintered body of the crystalline structure compound A in each of Examples 1 and 2 was 97% or more.

A bulk resistivity of the oxide sintered body of the crystalline structure compound A in each of Examples 1 and 2 was 15 mΩ·cm or less.

It has been found that the resistivity of the oxide sintered body of the crystalline structure compound A in each of Examples 1 and 2 was sufficiently low and suitably usable as the sputtering target.

### Examples 3 and 4

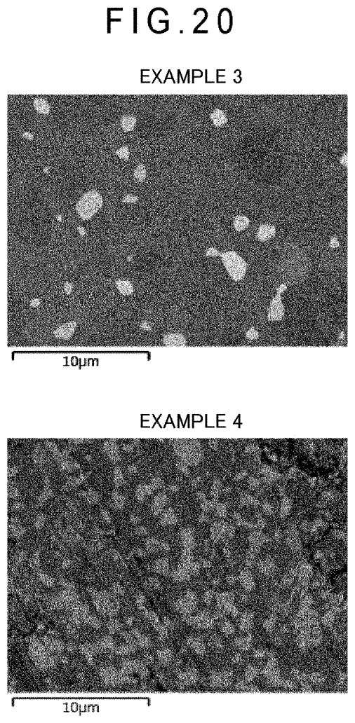

FIG. 20 shows SEM photographs of the oxide sintered bodies of Examples 3 and 4.

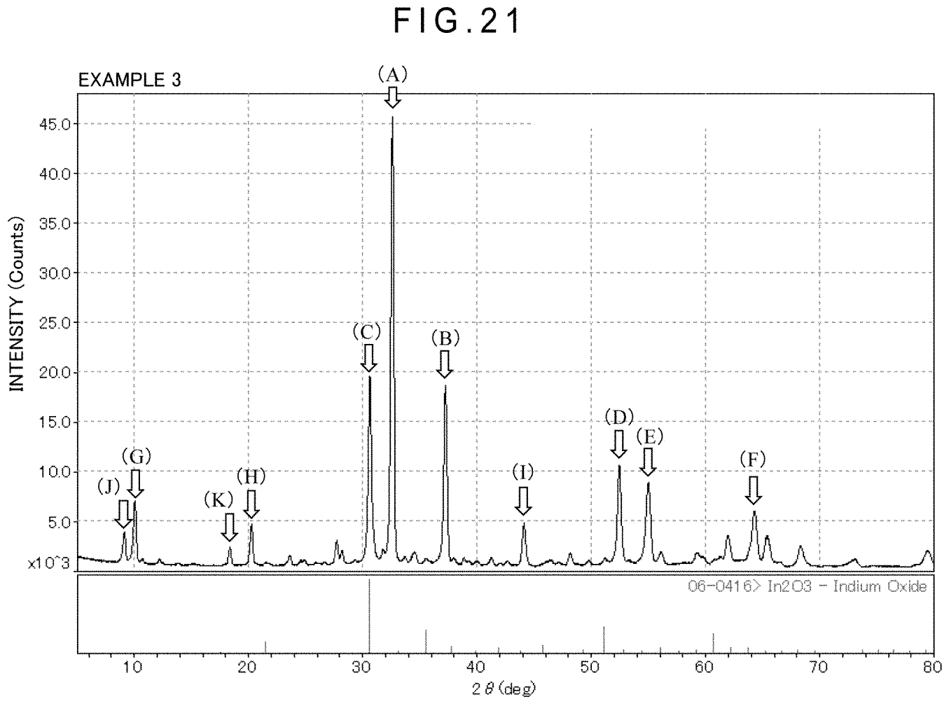

FIG. 21 shows XRD measurement results (XRD chart) of the oxide sintered body in Example 3.

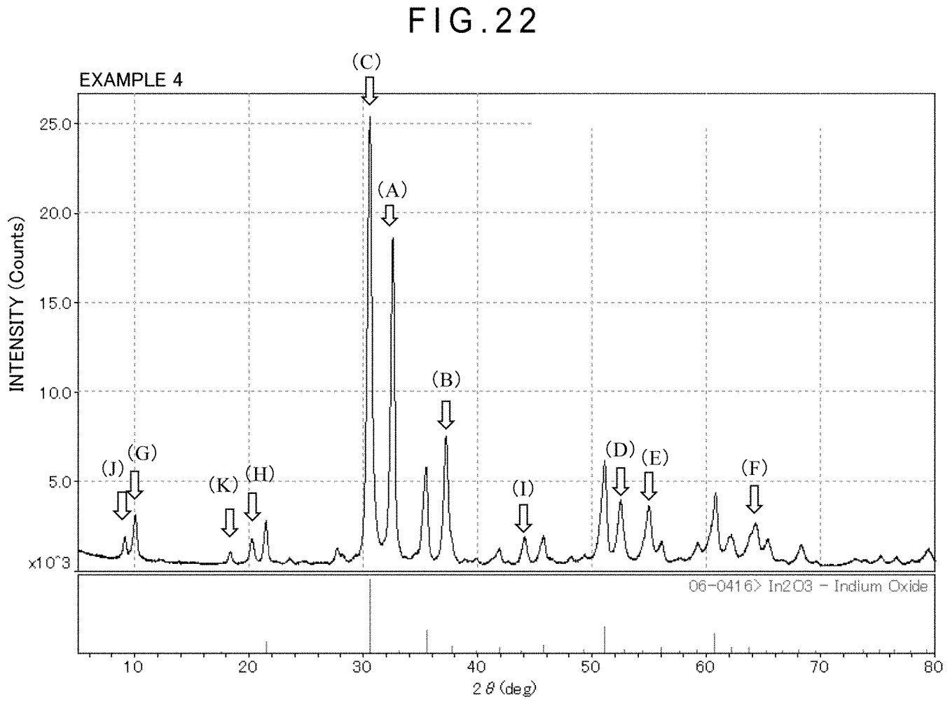

FIG. 22 shows XRD measurement results (XRD chart) of the oxide sintered body in Example 4.

Table 2 shows, in the sintered body of each of Examples 3 and 4, compositions, density (relative density), bulk resistivity, main components and sub components of XRD, composition analysis (composition ratio (atomic ratio) of In:Ga:Al) by SEM-EDS, and the like.

TABLE 2

| | | Example 3 | Example 4 |
|---|---|---|---|
| Composition | In₂O₃ | 67.1 | 78.0 |
| (mass %) | Ga₂O₃ | 18.1 | 12.0 |
| | Al₂O₃ | 14.8 | 10.0 |
| Composition | In | 50.0 | 63.4 |
| (at %) | Ga | 20.0 | 14.5 |
| | Al | 30.0 | 22.1 |
| Production | Sintering Temperature | 1350 | 1350 |
| Conditions | (° C.) | | |
| | Sintering Time | 24 | 24 |
| | (hr) | | |
| Relative Density (%) | | 98.0 | 97.0 |
| Bulk Resistivity (mΩ · cm) | | 14.9 | 14.4 |
| XRD | Main Component | Crystalline Structure | Crystalline Structure |
| Measurement | | Compound A | Compound A |
| | Sub Component | Ga-Al-doped In₂O₃ | Ga-Al-doped In₂O₃ |
| Lattice Constant of In₂O₃ Phase (10⁻¹⁰ m) | | Unmeasurable due to Minute | 10.10878 |
| | | Amount | |
| SEM-EDS of | In | 49 | 51 |
| Region of Main | Ga | 22 | 20 |
| Components | Al | 29 | 29 |
| (at %) | | | |
| SEM-EDS of | In | 96 | 91 |
| Region of Sub | Ga | 3 | 5 |
| Components | Al | 1 | 4 |
| (at %) | | | |
| Analysis by SEM- | Main Component | Crystalline Structure | Crystalline Structure |
| DES Measurement | | Compound A | Compound A |
| | Sub Component | Ga-Al-doped In₂O₃ | Ga-Al-doped In₂O₃ |
| | Ratio of Area of | 97 | 81 |
| | Crystalline Structure | | |
| | Compound A (%) | | |

It has been found from the SEM photograph shown in FIG. 20 that the oxide sintered bodies of Examples 3 and 4 are in a two-phase system: In₂O₃ crystals (light gray region in the SEM photographs) are mixed in a phase formed of the crystalline structure compound A (dark gray region in the SEM photographs).

In the oxide sintered body of Example 3, a connecting phase of the crystalline structure compound A was observed and the material In₂O₃ was observed in some parts of the connecting phase. As a results of the SEM-EDS measurement, a composition of the connecting phase in Example 3 was In:Ga:Al=49:22:29 at %, which was substantially the same as the charged composition. The connecting phase of Example 3 was the crystalline structure compound A satisfying the composition represented by the composition formula (1) or the composition formula (2).

FIG. 21 shows XRD measurement results of the oxide sintered body in Example 3. It has been found through JADE6 analysis that the crystal with the diffraction peaks does not match known compounds but has unknown crystal phase.

The ratio (area ratio S_{X}=(S_{A}/S_{T})×100) of the area S_{A} of the crystalline structure compound A (dark gray part) to the area S_{T} in the view field when the oxide sintered body of Example 3 was observed by SEM was 97%, and the area SB of In₂O₃ crystals (light gray part) was 3%. Each of the areas for calculating the area ratio S_{X} was calculated by image analysis (the above described “Calculation Method of Ratio of Crystalline Structure Compound A from SEM Image”).

In the oxide sintered body of Example 4, a connecting phase of the crystalline structure compound A was observed and the material In₂O₃ was observed in a part of the connecting phase. As a result of the SEM-EDS measurement, a composition of the connecting phase in Example 4 was In:Ga:Al=51:20:29 at %. The connecting phase of Example 4 was the crystalline structure compound A satisfying the composition represented by the composition formula (1) or the composition formula (2).

The ratio (area ratio S_{X}=(S_{A}/S_{T})×100) of the area S_{A} of the crystalline structure compound A (dark gray part) to the area S_{T} in the view field when the oxide sintered body of Example 4 was observed by SEM was 81%, and the area SB (light gray part) of In₂O₃ crystals was 19%. Each of the areas for calculating the area ratio S_{X} was calculated by image analysis (the above described “Calculation Method of Ratio of Crystalline Structure Compound A from SEM Image”).

As shown in FIG. 22, peaks in the crystalline structure compound A were observed in the XRD measurement of the oxide sintered body in Example 4. Further, in the XRD measurement of the oxide sintered body in Example 4, peaks (displayed by vertical lines in the drawing) caused by the Bixbyite crystalline compound represented by In₂O₃ were also observed. It has also been found from the XRD chart shown in FIG. 22 that crystal grains of the Bixbyite crystalline compound represented by In₂O₃ are dispersed in the phase formed of crystal grains of the crystalline structure compound A.

It has been found from the results of the XRD measurement and SEM-EDS analysis that the main component is the crystalline structure compound A and the subcomponent is the In₂O₃ crystal containing Ga and Al (Ga—Al-doped In₂O₃) in the oxide sintered bodies of Examples 3 and 4.

As shown in Table 2, the oxide sintered bodies of Examples 3 and 4 contain, as the main component, the crystalline structure compound A satisfying the range of the composition represented by the composition formula (1) or (2) and having diffraction peaks the below-defined ranges (A) to (K) of an incidence angle (2θ) observed by X-ray (Cu—K α ray) diffraction measurement.

Further, as shown in Table 2, the oxide sintered bodies of Examples 3 and 4 contains the In₂O₃ crystal, and the In₂O₃ crystal contains the gallium element and the aluminum element. The gallium element and the aluminum element are considered to be contained in the In₂O₃ crystal in a form of a solid solution such as a substitution solid solution and interstitial solid solution.

A lattice constant of the In₂O₃ crystal in the oxide sintered body of Example 3 was not quantatively determined since a height of the XRD peak was low and the number of the peaks was small.

A lattice constant of the In₂O₃ crystal in the oxide sintered body of Example 4 was 10.10878×10⁻¹⁰ m.

### Examples 5 and 6

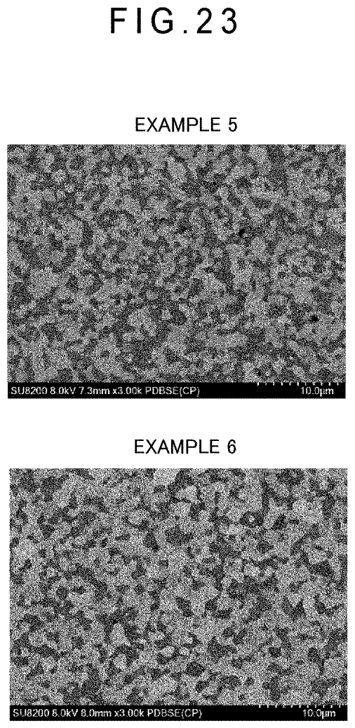

FIG. 23 shows SEM photographs of oxide sintered bodies in Examples 5 and 6.

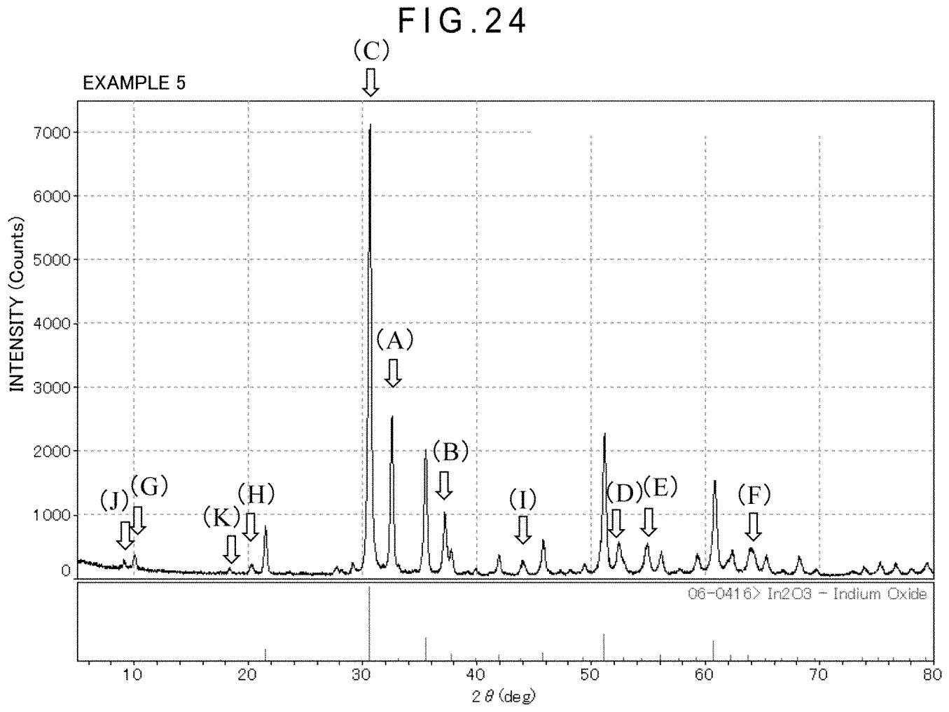

FIG. 24 shows an XRD chart of an oxide sintered body in Example 5.

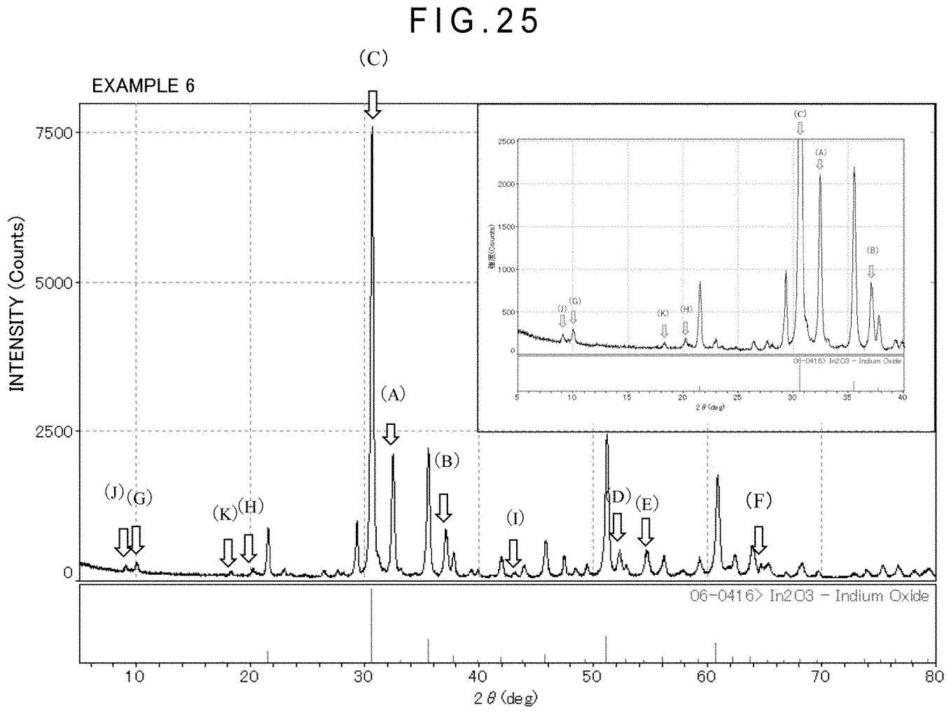

FIG. 25 shows an XRD chart of an oxide sintered body in Example 6.

Table 3 shows, in the sintered body of each of Examples 5 and 6, compositions, density (relative density), bulk resistivity, XRD analysis, and composition analysis (composition ratio (atomic ratio) of In:Ga:Al) by SEM-EDS, and the like.

TABLE 3

| | | Example 5 | Example 6 |
|---|---|---|---|
| Composition | In₂O₃ | 84.0 | 86.0 |
| (mass %) | Ga₂O₃ | 10.0 | 10.0 |
| | Al₂O₃ | 6.0 | 4.0 |
| Composition | In | 72.9 | 77.0 |
| (at %) | Ga | 12.9 | 13.3 |
| | Al | 14.2 | 9.7 |
| Production | Sintering Temperature | 1350 | 1350 |
| Conditions | (° C.) | | |
| | Sintering Time | 24 | 24 |
| | (hr) | | |
| Relative Density (%) | | 97.8 | 97.9 |
| Bulk Resistivity (mΩ · cm) | | 2.9 | 1.9 |
| XRD | Connecting Phase I | Ga-Al-doped In₂O₃ | Ga-Al-doped In₂O₃ |
| Measurement | Connecting Phase II | Crystalline Structure | Crystalline Structure |
| | | Compound A | Compound A |
| Lattice Constant of In₂O₃ Phase (10⁻¹⁰ m) | | 10.094 | 10.097 |
| SEM-EDS of Region | In | 96 | 95 |
| of Connecting | Ga | 3 | 4 |
| Phase I (Gray Part) | Al | 1 | 1 |
| (at %) | | | |
| SEM-EDS of Region | In | 49 | 49 |
| of Connecting | Ga | 25 | 30 |
| Phase II (Black Part) | Al | 26 | 21 |
| (at %) | | | |
| Analysis by SEM- | Type of Connecting | Ga-Al-doped In₂O₃ | Ga-Al-doped In₂O₃ |
| DES Measurement | Phase I | | |
| | Type of Connecting | Crystalline Structure | Crystalline Structure |
| | Phase II | Compound A | Compound A |
| | Ratio of Area of | 50 | 37 |
| | Crystalline Structure | | |
| | Compound A (%) | | |

As shown in FIG. 23, in the oxide sintered bodies in Examples 5 and 6, a phase in which crystal grains of the crystalline structure compound A were connected to each other (connecting phase II: a region shown in dark gray in the SEM photographs) and a phase in which crystal grains of indium oxide were connected to each other (connecting phase I: a region shown in light gray in the SEM photographs) were observed.

The ratio (area ratio S_{X}=(S_{A}/S_{T})×100) of the area S_{A} of the crystalline structure compound A (dark gray part) to the area S_{T} in the view field (FIG. 23) when the oxide sintered bodies of Examples 5 and 6 were observed by SEM was 50% for the oxide sintered body in Example 5 and 37% for the oxide sintered body in Example 6. Each of the areas for calculating the area ratio S_{X} was calculated by image analysis (the above described “Calculation Method of Ratio of Crystalline Structure Compound A from SEM Image”).

As shown in FIGS. 24 and 25, specific peaks caused by the crystalline structure compound A, namely, the peaks in the respective ranges (A) to (K) were observed in the XRD charts of the oxide sintered bodies in Examples 5 and 6.

As shown in FIG. 3, it has been found that, in the oxide sintered bodies in Examples 5 and 6, the phase in which the crystal grains of the crystalline structure compound A were connected to each other (connecting phase II: the region shown in dark gray in the SEM photographs) shows the composition represented by the composition formula (1) or the composition formula (2) as a result of the SEM-EDS analysis, and the phase in which crystal grains of the indium oxide were connected to each other (connecting phase I: a region shown in light gray in the SEM photographs) contained the gallium element and the aluminum element.

Moreover, it has been found that the composition (at %) of the oxide sintered body of each of Examples 5 and 6 is present in the composition range R_{C} shown in FIG. 3 and the composition range R_{C}′ shown in FIG. 39.

### Examples 7 and 14

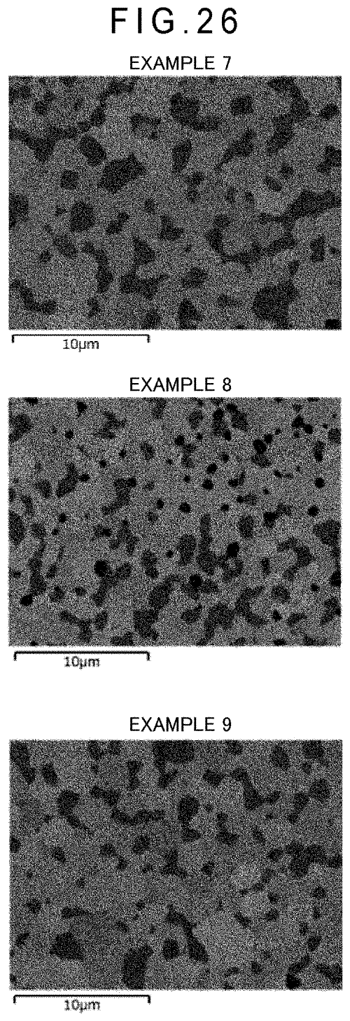

FIG. 26 shows SEM photographs of oxide sintered bodies in Examples 7 to 9.

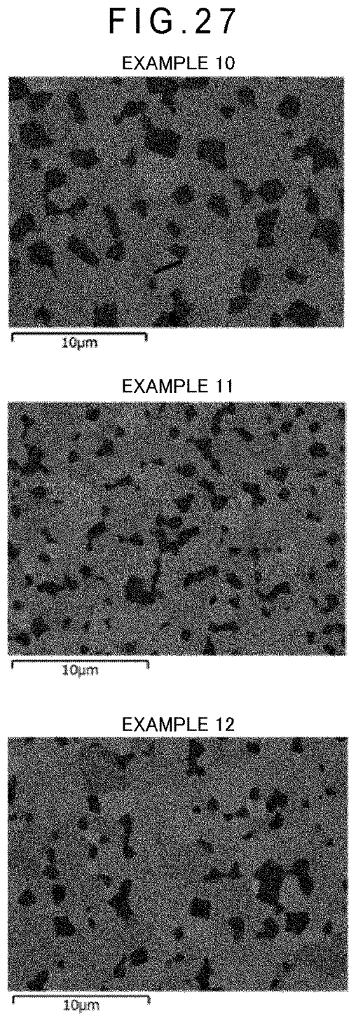

FIG. 27 shows SEM photographs of oxide sintered bodies in Examples 10 to 12.

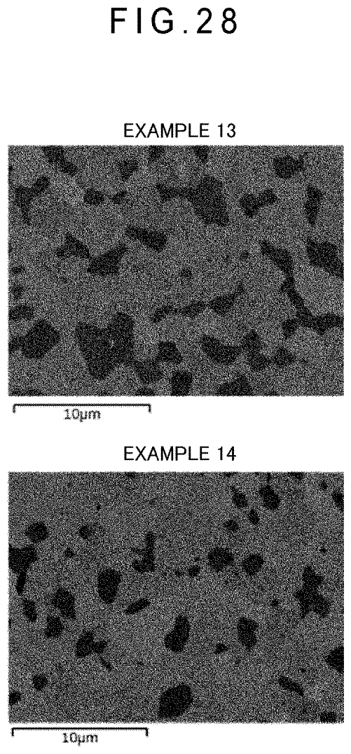

FIG. 28 shows SEM photographs of oxide sintered bodies in Examples 13 and 14.

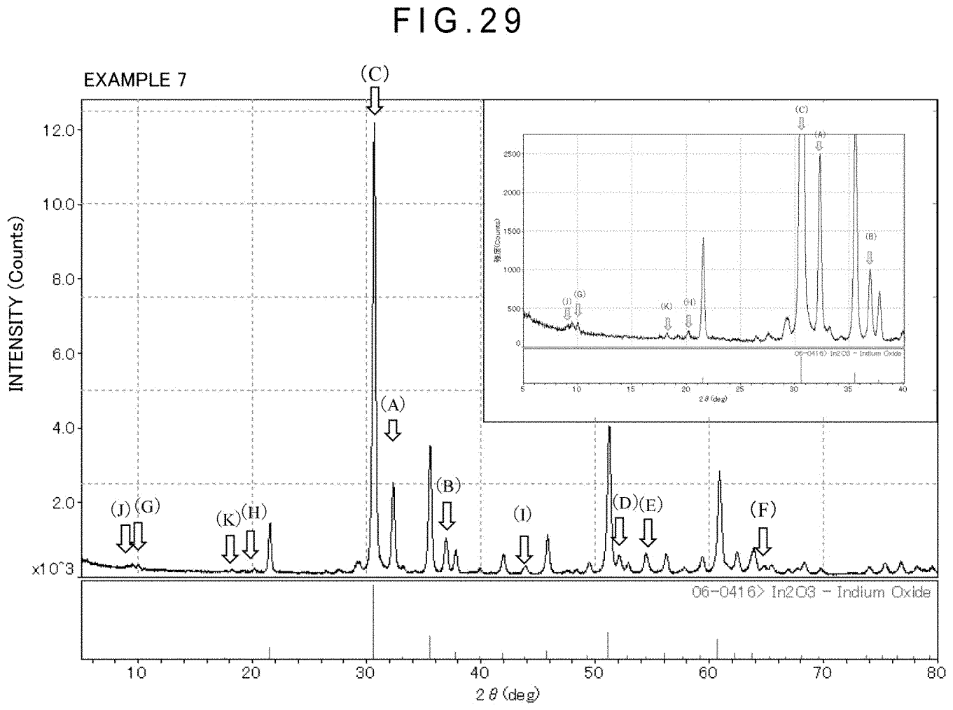

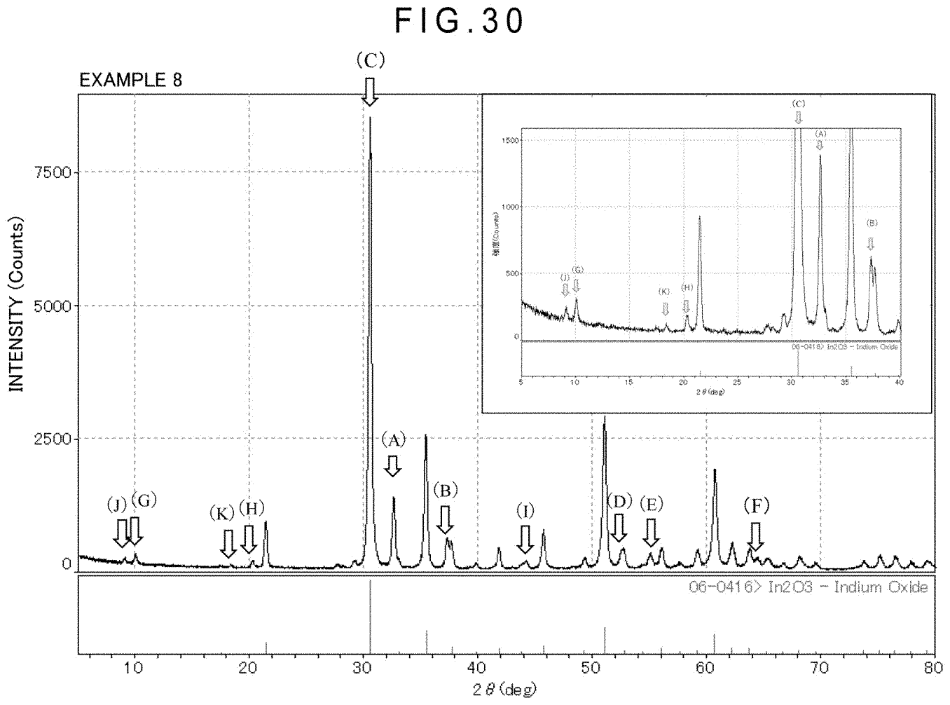

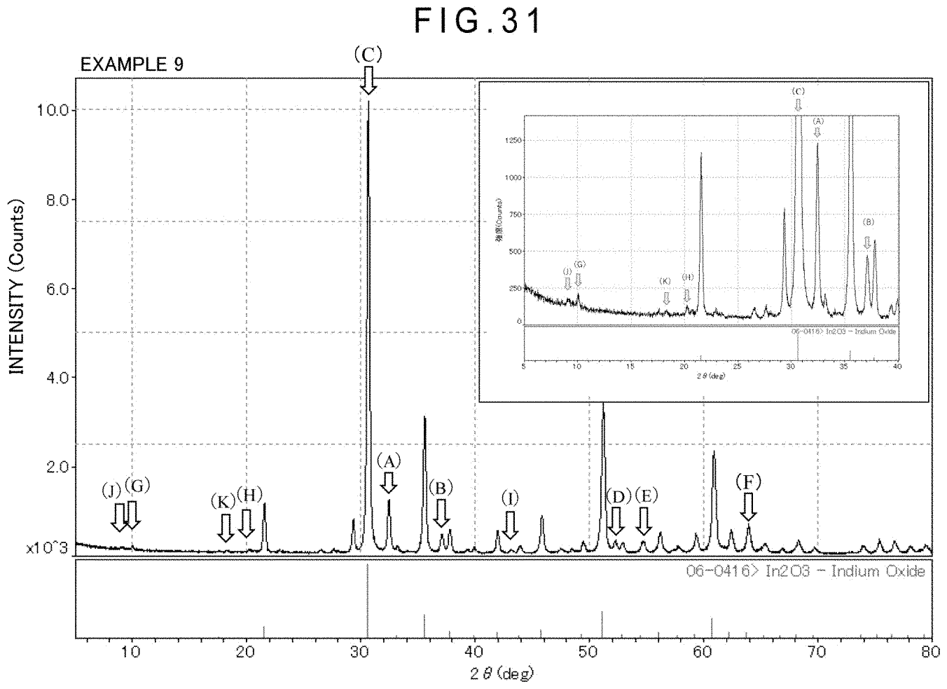

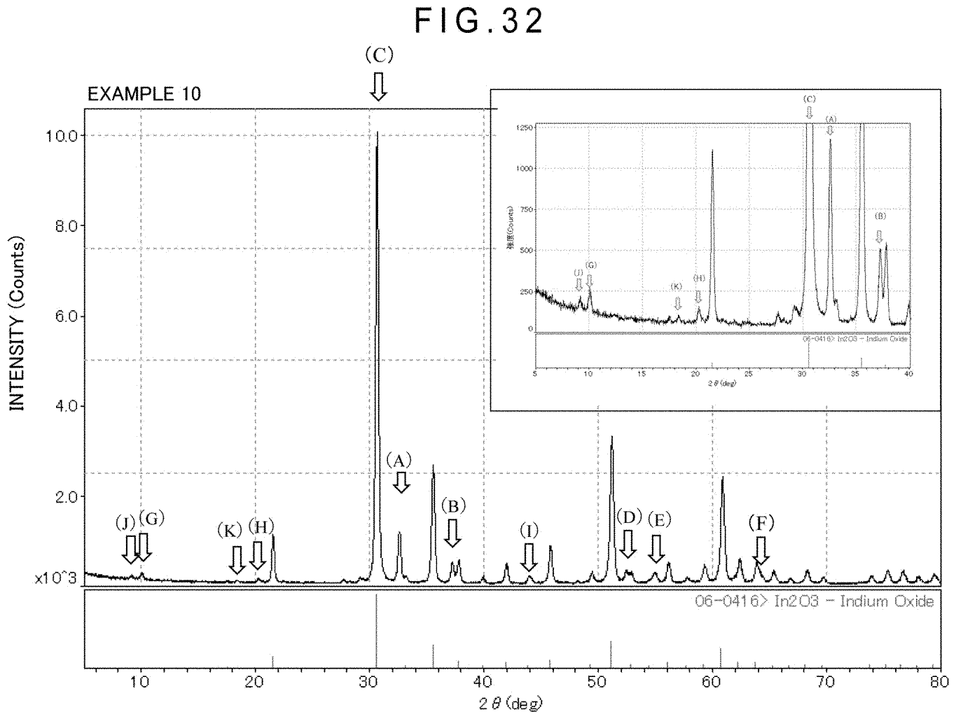

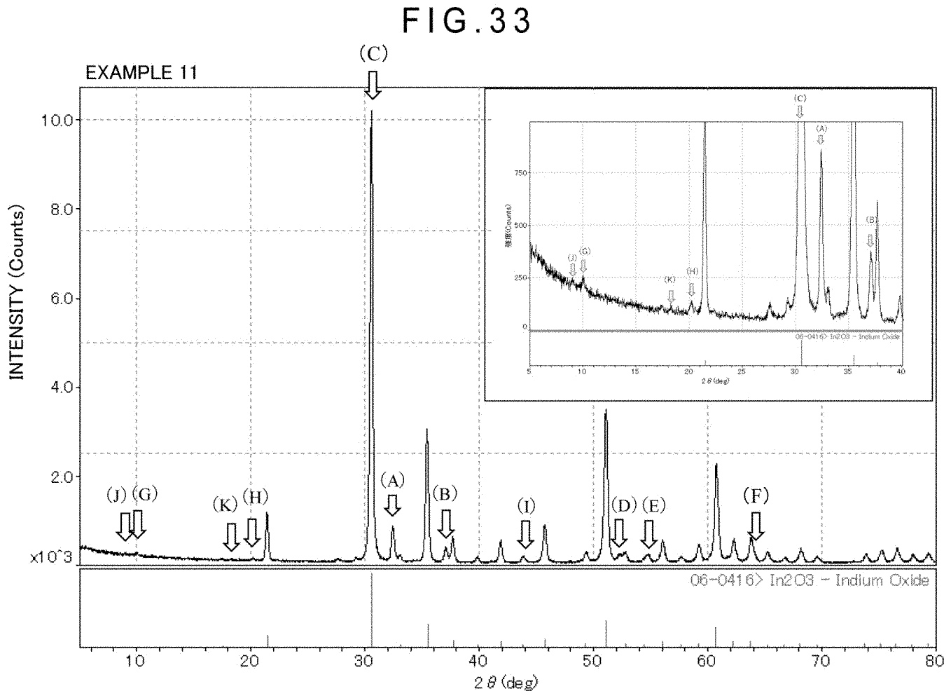

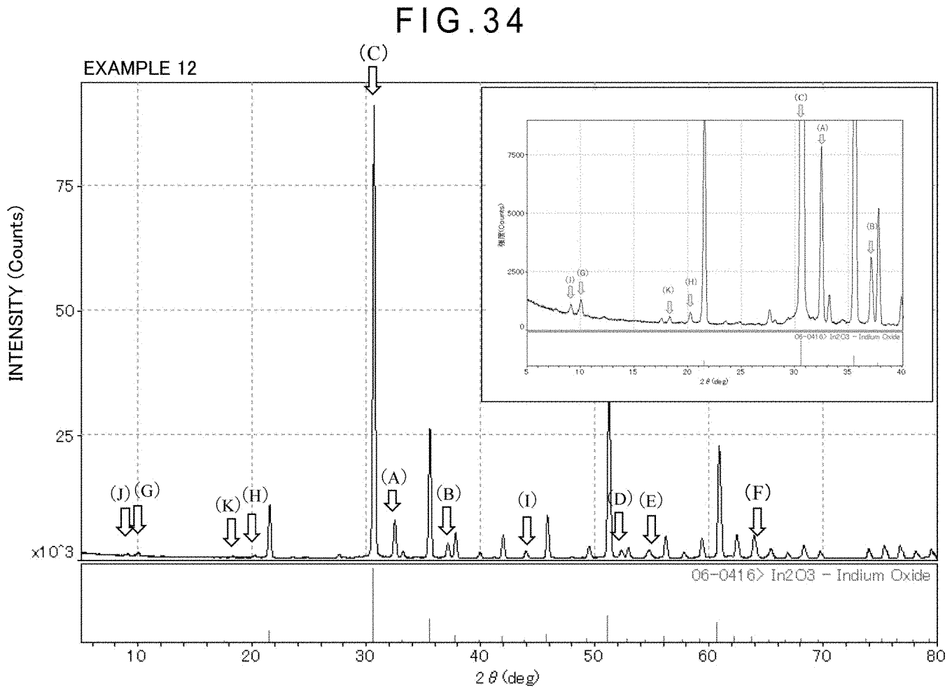

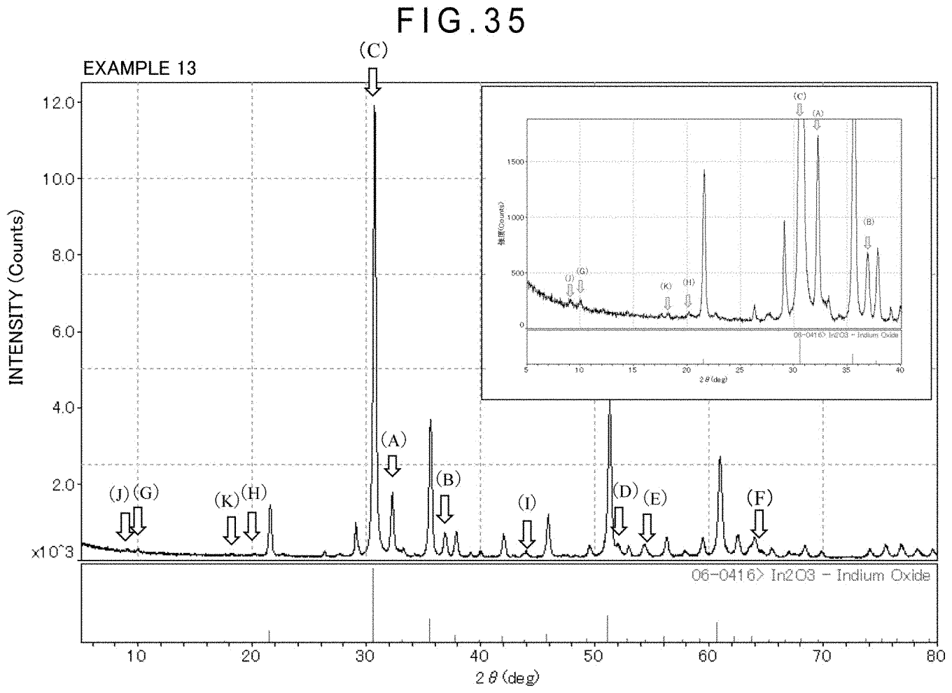

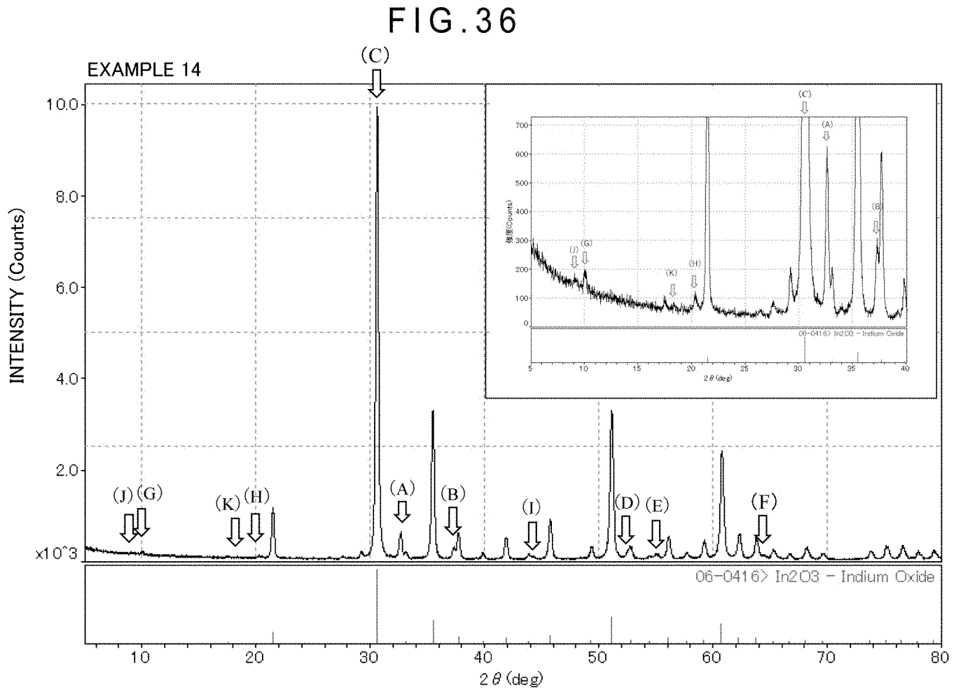

FIGS. 29 to 36 show enlarged views of XRD charts of the oxide sintered bodies of Examples 7 to 14.

Table 4 shows, in the sintered body of each of Examples 7 to 14, compositions, density (relative density), bulk resistivity, XRD analysis, and composition analysis (composition ratio (atomic ratio) of In:Ga:Al) by SEM-EDS, and the like.

TABLE 4

| | | Example 7 | Example 8 | Example 9 | Example 10 |
|---|---|---|---|---|---|
| Composition | In₂O₃ | 88.0 | 89.0 | 91.5 | 92.0 |
| (mass %) | Ga₂O₃ | 10.0 | 5.0 | 6.5 | 5.0 |
| | Al₂O₃ | 2.0 | 6.0 | 2.0 | 3.0 |
| Composition | In | 81.3 | 78.9 | 85.9 | 85.5 |
| (at %) | Ga | 13.7 | 6.6 | 9.0 | 6.9 |
| | Al | 5.0 | 14.5 | 5.1 | 7.6 |
| Production | Sintering Temperature | 1350 | 1350 | 1350 | 1350 |
| Conditions | (° C.) | | | | |
| | Sintering Time | 24 | 24 | 24 | 24 |
| | (hr) | | | | |
| Relative Density (%) | | 98.1 | 98.3 | 98.2 | 98.2 |
| Bulk Resistivity (mΩ · cm) | | 2.7 | 1.5 | 2.3 | 2.1 |
| XRD | Main Component | Ga-Al-doped | Ga-Al-doped | Ga-Al-doped | Ga-Al-doped |
| Measurement | | In₂O₃ | In₂O₃ | In₂O₃ | In₂O₃ |
| | Sub Component | Crystalline | Crystalline | Crystalline | Crystalline |
| | | Structure | Structure | Structure | Structure |
| | | Compound A | Compound A | Compound A | Compound A |
| Lattice Constant of In₂O₃ Phase (10⁻¹⁰ m) | | 10.083 | 10.101 | 10.089 | 10.094 |
| SEM-EDS of | In | 94 | 97 | 95 | 96 |
| Region of Main | Ga | 5 | 2 | 4 | 3 |
| Components | Al | 1 | 1 | 1 | 1 |
| (at %) | | | | | |
| SEM-EDS of | In | 50 | 48 | 49 | 48 |
| Region of Sub | Ga | 36 | 20 | 30 | 23 |
| Components | Al | 14 | 32 | 21 | 29 |
| (at %) | | | | | |
| Analysis by SEM- | Main Component | Ga-Al-doped | Ga-Al-doped | Ga-Al-doped | Ga-Al-doped |
| DES | | In₂O₃ | In₂O₃ | In₂O₃ | In₂O₃ |
| Measurement | Sub Component | Crystalline | Crystalline | Crystalline | Crystalline |
| | | Structure | Structure | Structure | Structure |
| | | Compound A | Compound A | Compound A | Compound A |
| | Ratio of Area of Crystalline | 29 | 27 | 22 | 24 |
| | Structure Compound A (%) | | | | |
| | | Example 11 | Example 12 | Example 13 | Example 14 |
| Composition | In₂O₃ | 93.0 | 93.5 | 90.0 | 94.0 |
| (mass %) | Ga₂O₃ | 5.0 | 5.0 | 9.0 | 4.0 |
| | Al₂O₃ | 2.0 | 1.5 | 1.0 | 2.0 |
| Composition | In | 87.9 | 89.1 | 84.9 | 89.2 |
| (at %) | Ga | 7.0 | 7.1 | 12.6 | 5.6 |
| | Al | 5.1 | 3.9 | 2.6 | 5.2 |
| Production | Sintering Temperature | 1350 | 1350 | 1350 | 1350 |
| Conditions | (° C.) | | | | |
| | Sintering Time | 24 | 24 | 24 | 24 |
| | (hr) | | | | |
| Relative Density (%) | | 98.4 | 98.5 | 98.9 | 97.6 |
| Bulk Resistivity (mΩ · cm) | | 2.3 | 2.8 | 3.0 | 2.4 |
| XRD | Main Component | Ga-Al-doped | Ga-Al-doped | Ga-Al-doped | Ga-Al-doped |
| Measurement | | In₂O₃ | In₂O₃ | In₂O₃ | In₂O₃ |
| | Sub Component | Crystalline | Crystalline | Crystalline | Crystalline |
| | | Structure | Structure | Structure | Structure |
| | | Compound A | Compound A | Compound A | Compound A |
| Lattice Constant of In₂O₃ Phase (10⁻¹⁰ m) | | 10.102 | 10.089 | 10.075 | 10.097 |
| SEM-EDS of | In | 95 | 95 | 93 | 96 |
| Region of Main | Ga | 4 | 4 | 6 | 3 |
| Components | Al | 1 | 1 | 1 | 1 |
| (at %) | | | | | |
| SEM-EDS of | In | 49 | 49 | 49 | 49 |
| Region of Sub | Ga | 27 | 29 | 41 | 20 |
| Components | Al | 24 | 22 | 10 | 31 |
| (at %) | | | | | |
| Analysis by SEM- | Main Component | Ga-Al-doped | Ga-Al-doped | Ga-Al-doped | Ga-Al-doped |
| DES | | In₂O₃ | In₂O₃ | In₂O₃ | In₂O₃ |
| Measurement | Sub Component | Crystalline | Crystalline | Crystalline | Crystalline |
| | | Structure | Structure | Structure | Structure |
| | | Compound A | Compound A | Compound A | Compound A |
| | Ratio of Area of Crystalline | 17 | 12 | 25 | 14 |
| | Structure Compound A (%) | | | | |

As shown in FIGS. 26 to 28, it was observed that the crystalline structure compound A (a region shown in black in the SEM photographs) was dispersed in a phase formed of crystal grains (a region shown in light gray in the SEM photographs) of the Bixbyite crystalline compound represented by In₂O₃ in the oxide sintered bodies of Examples 7 to 14.

The ratio (area ratio S_{X}=(S_{A}/S_{T})×100) of the area S_{A} of the crystalline structure compound A (black part) to the area S_{T} in the view field (FIGS. 26 to 28) when the oxide sintered bodies of Examples 7 to 14 were as follows.

Oxide sintered body in Example 7: 29%

oxide sintered body in Example 8: 27%

Oxide sintered body in Example 9: 22%

Oxide sintered body in Example 10: 24%

Oxide sintered body in Example 11: 17%

Oxide sintered body in Example 12: 12%

Oxide sintered body in Example 13: 25%

Oxide sintered body in Example 14: 14%

Each of the areas for calculating the area ratio S_{X} was calculated by image analysis (the above described “Calculation Method of Ratio of Crystalline Structure Compound A from SEM Image”).

As shown in FIGS. 29 to 36, specific peaks caused by the crystalline structure compound A, namely, the peaks in the respective ranges (A) to (K) were observed in the XRD measurement of the oxide sintered body in each of Examples 7 to 14.

As shown in Table 4, it has been found that, in the oxide sintered bodies in Examples 7 to 14, a phase in which crystal grains of the crystalline structure compound A were connected to each other (a region shown in black in the SEM photographs) shows the composition represented by the composition formula (1) or the composition formula (2) as a result of the SEM-EDS analysis, and the phase in which crystal grains of indium oxide were connected to each other (a region shown in light gray in the SEM photographs) contained the gallium element and the aluminum element.

Moreover, it has been found that the composition (at %) of the oxide sintered body of each of Examples 7 to 14 is present in the composition range R_{D} shown in FIG. 4 and the composition range R_{D}′ shown in FIG. 40.

### Comparative 1

An oxide sintered body was produced in the same manner as in Example 1 and the like except that the gallium oxide powders, aluminium oxide powders, and indium oxide powders were weighted so as to be compositions (at %) shown in Table 5.

The obtained oxide sintered body was evaluated in the same manner as in Example 1 and the like. Evaluation results are shown in Table 5.

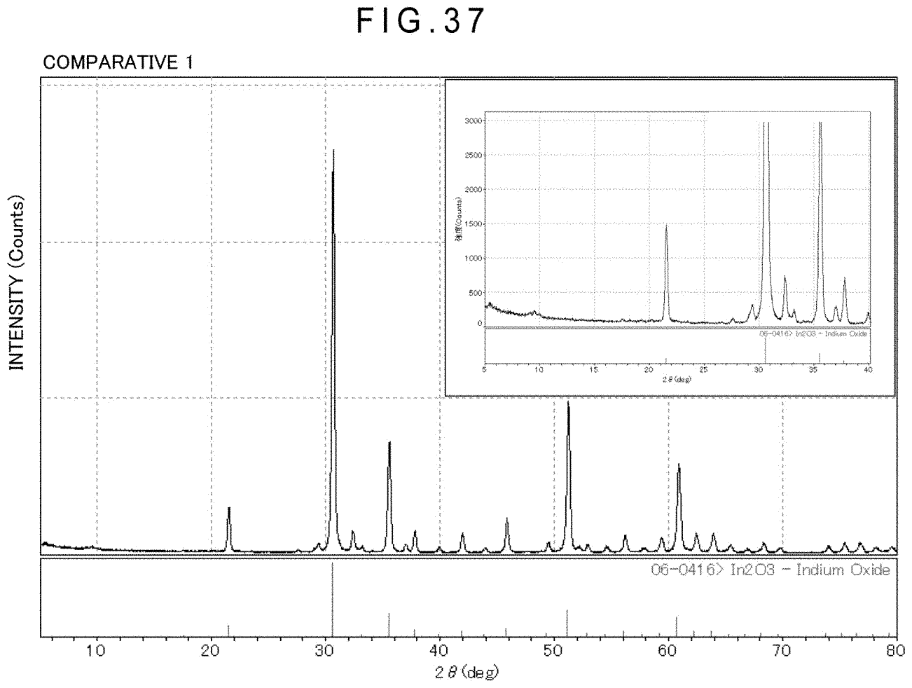

FIG. 37 shows XRD measurement results (XRD chart) of the oxide sintered body in Comparative 1.

TABLE 5

| | | Comparative 1 |
|---|---|---|
| Composition | In₂O₃ | 94.0 |
| (mass %) | Ga₂O₃ | 5.0 |
| | Al₂O₃ | 1.0 |
| Composition | In | 90.3 |
| (at %) | Ga | 7.1 |
| | Al | 2.6 |
| Production | Sintering Temperature | 1400 |
| Conditions | (° C.) | |
| | Sintering Time | 24 |
| | (hr) | |
| Relative Density (%) | | 98.3 |
| Bulk Resistivity (mΩ · cm) | | 2.5 |
| XRD | Main Component | Ga-Al-doped |
| Measurement | | In₂O₃ |
| | Sub Component | Undetected |

| | |
|---|---|
| Lattice Constant of In₂O₃ Phase (10⁻¹⁰ m) | 10.06859 |

According to Table 5, the oxide sintered body of Comparative 1 was an indium oxide sintered body doped with the gallium element and the aluminum element.

### Property Evaluation of Sputtering Target

### Sputtering Stability

An oxide sintered body of each of Examples was ground and polished to produce a 4-inch φ×5-mm thick sputtering target. Specifically, the ground and polished oxide sintered body was bonded to a backing plate to produce the sputtering target. A bonding rate of each of the sputtering targets was 98% or more. Moreover, warp was almost not observed. Each bonding rate was checked by X-ray CT.

DC sputtering at 400 W was continuously carried out for five hours using the produced sputtering target. The conditions on the surface of the target after the DC sputtering was visually checked. It was confirmed that no black foreign matter (nodules) was generated in all targets. It was also confirmed that there was no abnormal discharge such as arc discharge during DC sputtering.

### Preparation of Thin-Film Transistor

### (1) Film-Formation Step

An oxide sintered body of each of Examples was ground and polished to produce a 4-inch φ×5-mm thick sputtering target. At this time, the sputtering target was smoothly prepared without causing cracks or the like.

The produced sputtering target was used for sputtering on a silicon wafer 20 provided with a thermally oxidized film (gate insulating film: see FIG. 10) under conditions shown in Tables 6 to 8 through a metal mask to form a 50-nm thin film (oxide semiconductor layer). At this time, sputtering gas in a form of mixture gas of high-purity argon and 1% high-purity oxygen was used for sputtering.

Further, a sample provided solely with a 50-nm-thick oxide semiconductor layer on a glass substrate was simultaneously prepared under the same conditions. The glass substrate was made of ABC-G manufactured by Nippon Electric Glass Co., Ltd.

### (2) Formation of Source/Drain Electrodes

Next, source/drain electrodes in a form of titanium electrodes were formed through sputtering of titanium metal using a metal mask with a pattern corresponding to contact holes for the source/drain. The obtained sample was subjected to a heat treatment in atmospheric air at 350 degrees C. for 60 minutes to prepare a thin-film transistor (TFT) before the protective insulating film was formed.

### Property Evaluation of Semiconductor Film

Measurement of Hall Effect:

After the sample made of the glass substrate and the oxide semiconductor layer was subjected to a heat treatment under the same conditions as in the heat treatment after formation of semiconductor film in Tables 6 to 8, a 1×1 cm square sample piece was cut from the sample. Gold (Au) was applied on four corners of the cut sample piece using a metal mask and an ion coater to form a film at a size equal to or less than approximately 2 mm×2 mm. After the film was formed, indium solder was applied on the Au metal for enhanced electrical contact, thereby providing a Hall-effect measurement sample.

The Hall-effect measurement sample was set to a Hall-effect/specific resistance measurement system (ResiTest 8300, manufactured by TOYO Corporation) to evaluate the Hall effect at a room temperature and determine the carrier density and the mobility. The results are shown in “Film Properties of Semiconductor Film after Heat Treatment” in Tables 6 to 8. Further, the oxide semiconductor layer of the obtained sample was analyzed using an ICP-AES (Inductively Coupled Plasma-Atomic Emission Spectrometer, manufactured by Shimadzu Corporation). As a result, it has been found that the atomic ratio of the obtained oxide semiconductor film is the same as the atomic ratio of the oxide sintered body used for preparing the oxide semiconductor film.

Crystal Property of Semiconductor Film

On the sample made of a glass substrate and oxide semiconductor layer, the crystallinity of the film without being heated after the film was formed by sputtering (immediately after being deposited) and the film after the heat treatment after film-formation shown in Tables 6 to 8 was applied was evaluated through XRD (X-Ray Diffraction) measurement. The film before and after the heat treatment was subjected to the XRD measurement. In the XRD measurement, the film was described as “amorphous” when no peak was observed, whereas the film was described as a “crystal” when a peak was observed. When the film was crystal, a lattice constant was also described. When a broad pattern was observed instead of a clear peak, the film was described as a “nanocrystal.”

The XRD pattern obtained by the above XRD measurement was subjected to Whole Pattern Fitting (WPF) analysis using JADE6 to specify each of crystalline components included in the XRD pattern and calculate a lattice constant of an In₂O₃ crystalline phase in the obtained oxide sintered body.

Band Gap of Semiconductor Film:

Transmission spectrum of the sample made of glass substrate and oxide semiconductor layer and subjected to the heat treatment under the heat treatment conditions shown in Tables 6 to 8 was measured, whose results were plotted in a graph (abscissa axis: wavelength, ordinate axis: transmittance). Then, after the wavelength in abscissa axis was converted into energy (eV) and the transmittance in ordinate axis was converted into (αhv)². Herein, α: absorption coefficient, h: Planck's constant, and v: oscillation frequency. In the converted graph, a straight line was fitted to a rising portion of the absorption and an energy value (eV) at an intersection of the straight line with a base line was calculated as the band gap of the semiconductor film. Transmission spectrum was measured with a spectrophotometer UV-3100PC (manufactured by Shimadzu Corporation).

### Properties Evaluation of TFT

The saturation mobility, threshold voltage, On/Off ratio, and off current of the TFT before an insulation protection film (SiO₂ film) was formed were evaluated. The results are shown in “TFT properties after heat treatment and before formation of SiO₂ film” in Tables 6 to 8.

The saturation mobility was determined based on a transfer function when 0.1 V drain voltage was applied. Specifically, the saturation mobility was calculated by: plotting a graph of a transfer function Id-Vg; calculating transconductance (Gm) for each Vg; and calculating the saturation mobility using a formula in a linear region. It should be noted that Gm is represented by ∂(Id)/∂(Vg), and the linear mobility is defined by a maximum carrier mobility in a Vg range from −15 to 25 V. The linear mobility herein is evaluated according to the above unless otherwise specified. In the above, Id represents a current between source and drain electrodes, and Vg represents a gate voltage when the voltage Vd is applied between the source and drain electrodes.

The threshold voltage (Vth) is defined as Vg at Id=10⁻⁹ A based on the graph of the transfer function.

The On/Off ratio is determined as a ratio [On/Off] of On current value (a value of Id when Vg=20 V) to Off current value (a value of Id when Vg=−10 V).

TABLE 6

| | | Example A1 | Example A2 | Example A3 | Example A4 | Example A5 |
|---|---|---|---|---|---|---|
| | Sintered Body Used as Target | Example 7 | Example 9 | Example 10 | Example 11 | Example 12 |
| Formation | Atmospheric Gas | Ar + O₂ | Ar + O₂ | Ar + O₂ | Ar + O₂ | Ar + O₂ |
| Conditions of | Back-pressure before Film Formation (Pa) | 5 × 10⁻⁴ | 5 × 10⁻⁴ | 5 × 10⁻⁴ | 5 × 10⁻⁴ | 5 × 10⁻⁴ |
| Semiconductor | Sputter Pressure at Film Formation (Pa) | 0.5 | 0.5 | 0.5 | 0.5 | 0.5 |
| Film | Substrate Temperature | room | room | room | room | room |
| | at Film Formation (° C.) | temperature | temperature | temperature | temperature | temperature |
| | Direct Current (DC) Output (W) | 300 | 300 | 300 | 300 | 300 |
| | Oxygen Partial Pressure | 1 | 1 | 1 | 1 | 1 |
| | at Film Formation (%) | | | | | |
| | L/W of TFT (μm) | 200/1000 | 200/1000 | 200/1000 | 200/1000 | 200/1000 |
| | Film Thickness (nm) | 50 | 50 | 50 | 50 | 50 |
| Heat Treatment | Heat Treatment after Film Formation: | 350 | 350 | 350 | 350 | 380 |
| Conditions after | Temperature (° C.) | | | | | |
| Formation of | Temperature Increase Speed (° C./min) | 10 | 10 | 10 | 10 | 10 |
| Semiconductor | Time (min) | 60 | 60 | 60 | 60 | 60 |
| Film | Atmosphere | air | air | air | air | air |
| Film Properties of | Hall Measurement Carrier Density (cm⁻³) | 4.40 × 10¹⁸ | 1.67 × 10¹⁸ | 2.47 × 10¹⁷ | 2.57 × 10¹⁷ | 1.81 × 10¹⁷ |
| Semiconductor | Hall Measurement Mobility | 8.5 | 7.8 | 17.6 | 25.2 | 14.1 |
| Film after Heat | (cm²/V · sec) | | | | | |
| Treatment | Crystallinity just after Film Deposition (XRD) | amorphous | amorphous | amorphous | amorphous | amorphous |
| | Crystallinity just after Heating (XRD) | In₂O₃ crystal | In₂O₃ crystal | In₂O₃ crystal | In₂O₃ crystal | In₂O₃ crystal |
| | Band Gap of Semiconductor Film (eV) | 3.52 | 3.72 | 3.73 | 3.69 | 3.63 |
| | Lattice Constant of In₂O₃ (10⁻¹⁰ m) | 9.91617 | 9.95427 | 9.94796 | 9.97576 | 10.0168 |
| TFT Properties | Linear Mobility (cm²/V · sec) | 160 | 22.3 | 20.4 | 34.3 | 32.2 |
| after Heat | Vth (V) | −8.2 | 0.3 | 0.3 | 0.1 | −0.2 |
| Treatment and | On/Off Ratio | >1 × 10⁸ | >1 × 10⁷ | >1 × 10⁷ | >1 × 10⁷ | >1 × 10⁷ |
| before Formation | Off Current (A) | <1 × 10⁻¹¹ | <1 × 10⁻¹¹ | <1 × 10⁻¹¹ | <1 × 10⁻¹¹ | <1 × 10⁻¹¹ |
| of SiO₂ Film | | | | | | |

| | | Example A6 | Example A7 | Comparative B1 |
|---|---|---|---|---|
| | Sintered Body Used as Target | Example 13 | Example 14 | Comparative 1 |
| Formation | Atmospheric Gas | Ar + O₂ | Ar + O₂ | Ar + O₂ |
| Conditions of | Back-pressure before Film Formation (Pa) | 5 × 10⁻⁴ | 5 × 10⁻⁴ | 5 × 10⁻⁴ |
| Semiconductor | Sputter Pressure at Film Formation (Pa) | 0.5 | 0.5 | 0.5 |
| Film | Substrate Temperature | room | room | room |
| | at Film Formation (° C.) | temperature | temperature | temperature |
| | Direct Current (DC) Output (W) | 300 | 300 | 300 |
| | Oxygen Partial Pressure | 1 | 1 | 1 |
| | at Film Formation (%) | | | |
| | L/W of TFT (μm) | 200/1000 | 200/1000 | 200/1000 |
| | Film Thickness (nm) | 50 | 50 | 50 |
| Heat Treatment | Heat Treatment after Film Formation: | 350 | 350 | 350 |
| Conditions after | Temperature (° C.) | | | |
| Formation of | Temperature Increase Speed (° C./min) | 10 | 10 | 10 |
| Semiconductor | Time (min) | 60 | 60 | 60 |
| Film | Atmosphere | air | air | air |
| Film Properties of | Hall Measurement Carrier Density (cm⁻³) | 3.17 × 10¹⁷ | 1.62 × 10¹⁸ | 1.14 × 10¹⁸ |
| Semiconductor | Hall Measurement Mobility | 13.6 | 11.3 | 14.5 |
| Film after Heat | (cm²/V · sec) | | | |
| Treatment | Crystallinity just after Film Deposition (XRD) | amorphous | nanocrystal | amorphous |
| | Crystallinity just after Heating (XRD) | In₂O₃ crystal | In₂O₃ crystal | In₂O₃ crystal |
| | Band Gap of Semiconductor Film (eV) | 3.66 | 3.64 | 3.61 |
| | Lattice Constant of In₂O₃ (10⁻¹⁰ m) | 9.96505 | 9.9996 | 10.0566 |
| TFT Properties | Linear Mobility (cm²/V · sec) | 25.2 | 27.4 | 35.1 |
| after Heat | Vth (V) | −0.2 | 0.1 | −0.3 |
| Treatment and | On/Off Ratio | >1 × 10⁷ | >1 × 10⁷ | >1 × 10⁷ |
| before Formation | Off Current (A) | <1 × 10⁻¹¹ | <1 × 10⁻¹¹ | <1 × 10⁻¹¹ |
| of SiO₂ Film | | | | |

TABLE 7

| | | Example A8 | Example A9 | Example A10 |
|---|---|---|---|---|
| | Sintered Body Used as Target | Example 5 | Example 6 | Example 8 |
| Formation | Atmospheric Gas | Ar + O₂ | Ar + O₂ | Ar + O₂ |
| Conditions of | Back-pressure before Film Formation (Pa) | 5 × 10⁻⁴ | 5 × 10⁻⁴ | 5 × 10⁻⁴ |
| Semiconductor Film | Sputter Pressure at Film Formation (Pa) | 0.5 | 0.5 | 0.5 |
| | Substrate Temperature | room | room | room |
| | at Film Formation (° C.) | temperature | temperature | temperature |
| | Direct Current (DC) Output (W) | 300 | 300 | 300 |
| | Oxygen Partial Pressure | 1 | 1 | 1 |
| | at Film Formation (%) | | | |
| | L/W of TFT (μm) | 200/1000 | 200/1000 | 200/1000 |
| | Film Thickness (nm) | 50 | 50 | 50 |
| Heat Treatment | Heat Treatment after Film Formation: | 350 | 350 | 350 |
| Conditions after | Temperature (° C.) | | | |
| Formation of | Temperature Increase Speed (° C./min) | 10 | 10 | 10 |
| Semiconductor Film | Time (min) | 60 | 60 | 60 |
| | Atmosphere | air | air | air |
| Film Properties of | Hall Measurement Carrier Density (cm⁻³) | 1.92 × 10¹⁷ | 9.72 × 10¹⁷ | 2.84 × 10¹⁷ |
| Semiconductor Film | Hall Measurement Mobility | 16.5 | 21.8 | 22.4 |
| after Heat Treatment | (cm²/V · sec) | | | |
| | Crystallinity just after Film Deposition (XRD) | amorphous | amorphous | amorphous |
| | Crystallinity just after Heating (XRD) | amorphous | amorphous | amorphous |
| | Band Gap of Semiconductor Film (eV) | 3.24 | 3.23 | 3.25 |
| TFT Properties after | Linear Mobility (cm²/V · sec) | 12.5 | 15.8 | 14.3 |
| Heat Treatment and | Vth (V) | −0.1 | −0.2 | −0.2 |
| before Formation of | On/Off ratio | >1 × 10⁸ | >1 × 10⁸ | >1 × 10⁸ |
| SiO₂ Film | Off Current (A) | <1 × 10⁻¹² | <1 × 10⁻¹² | <1 × 10⁻¹² |

TABLE 8

| | | Example A12 | Example A13 | Example A14 |
|---|---|---|---|---|
| | Sintered Body Used as Target | Example 1 | Example 2 | Example 3 |
| Formation Conditions of | Atmospheric Gas | Ar + O₂ | Ar + O₂ | Ar + O₂ |
| Semiconductor Film | Back-pressure before Film Formation (Pa) | 5.E−04 | 5.E−04 | 5.E−04 |
| | Sputter Pressure at Film Formation (Pa) | 0.5 | 0.5 | 0.5 |
| | Substrate Temperature | room | room | room |
| | at Film Formation (° C.) | temperature | temperature | temperature |
| | Direct Current (DC) Output (W) | 300 | 300 | 300 |
| | Oxygen Partial Pressure | 1 | 1 | 1 |
| | at Film Formation (%) | | | |
| | L/W of TFT (μm) | 200/1000 | 200/1000 | 200/1000 |
| | Film Thickness (nm) | 50 | 50 | 50 |
| Heat Treatment | Heat Treatment after Film Formation: | 350 | 350 | 350 |
| Conditions after | Temperature (° C.) | | | |
| Formation of | Temperature Increase Speed (° C./min) | 10 | 10 | 10 |
| Semiconductor Film | Time (min) | 60 | 60 | 60 |
| | Atmosphere | air | air | air |
| Film Properties of | Hall Measurement Carrier Density (cm⁻³) | 2.31 × 10¹³ | 2.58 × 10¹² | 5.94 × 10¹² |
| Semiconductor Film | Hall Measurement Mobility | 1.6 × 10⁻² | 8.8 × 10⁻² | 6.2 × 10⁻² |
| after Heat Treatment | (cm²/V · sec) | | | |
| | Crystallinity just after Film Deposition (XRD) | amorphous | amorphous | amorphous |
| | Crystallinity just after Heating (XRD) | amorphous | amorphous | amorphous |
| TFT Properties after | Linear Mobility (cm²/V · sec) | 2.3 | 1.5 | 1.3 |
| Heat Treatment and | Vth (V) | 3.8 | 4.1 | 4.2 |
| before Formation of | On/Off Ratio | >1 × 10⁷ | >1 × 10⁷ | >1 × 10⁷ |
| SiO₂ Film | Off Current (A) | <1 × 10⁻¹³ | <1 × 10⁻¹³ | <1 × 10⁻¹³ |

The numbers of Examples and Comparatives corresponding to the used oxide sintered bodies are described in Tables 6 to 8.

Table 6 shows data of the thin-film transistors containing the respective crystalline oxide thin films.

The results of Examples A1 to A7 demonstrate that, by using the oxide sintered bodies of Examples 7 and 9 to 14 as the target, even when an oxygen partial pressure at the film formation is 1%, although the mobility is 20 cm²/(V·s) or more (high mobility), Vth can be kept at about 0V, so that a thin-film transistor exhibiting excellent TFT properties can be provided. Vth can be shifted to a positive value as the oxygen concentration in the formed film of the oxide semiconductor film is increased, thereby reaching a desired Vth.

Since Examples A2 to A7 demonstrate that the band gap of the semiconductor film exceeds 3.5 eV and transparency is excellent, it is considered that photostability is also high. Since the lattice constant of In₂O₃ is 10.05×10⁻¹⁰ m or less, it is considered that these high performances are caused by a unique packing of elements.

Table 7 shows data of the thin-film transistors containing the respective amorphous oxide thin films.

By using the oxide sintered bodies of Examples 5, 6 and 8 as the target, also when an oxygen partial pressure at the film formation was 1%, the mobility was as high as 12 cm²/(V·s) or more to show an excellent performance of the thin-film transistor.

Table 8 shows a data table of thin-film transistors containing the respective amorphous oxide thins film each having a composition represented by the composition formula (1) or the composition formula (2).

By using the oxide sintered bodies of Examples 1 to 3 as the target, also when the oxygen partial pressure at the film formation was 1%, a thin-film transistor exhibited an excellent stability. The stable thin-film transistor is obtained by a unique packing of the elements.

### Process Durability

In order to estimate process durability, a 100-nm-thick SiO₂ film was formed by CVD method at a substrate temperature of 250 degrees C. on the TFT device obtained in Example A4 and the TFT device obtained in Comparative B1, so that a TFT device in Example A15 and a TFT device in Comparative B2 were obtained. In the same manner as for the TFT device, an SiO₂ film was formed on the Hall-effect measurement sample under the same conditions, and the carrier density and the mobility were measured.

Subsequently, the TFT device and the Hall-effect measurement sample formed with the SiO₂ film were subjected to a heat treatment in atmospheric air at 350 degrees C. for 60 minutes, and the TFT property evaluation and the Hall-effect measurement were performed, results of which are shown in Table 9.

TABLE 9

| | Used TFT | Example A15 | Comparative B2 |
|---|---|---|---|
| | | Example A4 | Comparative B1 |
| Initial Properties of Used TFT | Linear Mobility (cm²/V · sec) | 34.3 | 35.1 |
| (TFT Properties after Heat | | | |
| Treatment and before | Vth (V) | 0.1 | −0.3 |
| Formation of SiO₂ Film (Data | On/Off Ratio | >1 × 10⁷ | >1 × 10⁷ |
| of Table 6 again Described) | Off Current (A) | <1 × 10¹¹ | <1 × 10¹¹ |
| Properties of Semiconductor | Substrate Temperature ° C. | 250 | 250 |
| Film after Formation of SiO₂ | Hall Measurement Carrier Density (cm⁻³) | 5.39 × 10¹⁹ | 2.63 × 10¹⁹ |
| Film by CVD | Hall Measurement Mobility | 70.2 | 38.6 |
| | (cm²/V · sec) | | |
| Properties of Semiconductor | Heat Treatment: Temperature (° C.) | 350 | 350 |
| Film after Heat Treatment after | Time (min) | 60 | 60 |
| Formation of SiO₂ Film by | Atmosphere | air | air |
| CVD | Hall Measurement Carrier Density (cm⁻³) | 7.15 × 10¹⁸ | 7.36 × 10¹⁹ |
| | Hall Measurement Mobility | 88.3 | 92.9 |
| | (cm²/V · sec) | | |
| TFT Properties obtained by | Linear Region Mobility (cm²/V · sec) | 35.5 | 38.3 |
| Heat Treatment after | Vth (V) | −0.4 | −8.4 |
| Formation of SiO₂ Film by | On/Off Ratio | >1 × 10⁸ | >1 × 10⁶ |
| CVD | Off Current (A) | <1 × 10¹² | <1 × 10¹⁰ |

The TFT device of Example A15 was a TFT device having favorable process durability since exhibiting a linear region mobility of 30 cm²/(V·s) or more, Vth of −0.4 V, normally-off property, the On/Off ratio of more than the eighth power of 10, and a low off-current. In contrast, the TFT device of Comparative B2 was not said to be a TFT device having favorable process durability as compared with the TFT device of Example A15 since exhibiting Vth of −8.4 V, normally-on property, the On/Off ratio of more than the sixth power of 10, and a high off-current although exhibiting a linear region mobility of 30 cm²/(V·s) or more.

### Example C1

Double-Layered TFT

In accordance with the procedure of the (1) film-formation step and the (2) formation of source/drain electrodes, and the conditions shown in Table 10 in the above-described [Preparation of Thin-Film Transistor], a TFT device was prepared and subjected to a heat treatment. TFT properties after the heat treatment were evaluated by the same method as the above-described <Properties Evaluation of TFT>. The evaluation results are shown in Table 10. The first layer is a film formed using the sputtering target of Example 7.0n the other hand, the second layer is a film formed using the sputtering target of Example 1. The first layer (film) is TFT exhibiting Vth of −8.2V and normally-on properties although having a high mobility. On the other hand, the second layer (film) exhibited Vth of +3.8 V although having a low mobility. The results shown in Table 10 demonstrate that laminating of the first layer and the second layer provides a TFT device having a high mobility and Vth controlled to about 0 V.

TABLE 10

| | | Example C1 |
|---|---|---|
| First Layer | Sintered body used as target | Example 7 |
| Formation Conditions of | Atmospheric Gas | Ar + O₂ |
| Semiconductor Film | Back-pressure before | 5 × 10⁻⁴ |
| | Film Formation (Pa) | |
| | Sputter Pressure at | 0.5 |
| | Film Formation (Pa) | |
| | Substrate Temperature | room |
| | at Film Formation (° C.) | temperature |
| | Direct Current (DC) Output (W) | 100 |
| | Oxygen Partial Pressure | 1 |
| | at Film Formation (%) | |
| | L/W of TFT (μm) | 200/1000 |
| | Film Thickness (nm) | 25 |
| Second Layer | Sintered Body Used as Target | Example 1 |
| Formation Conditions of | Atmospheric Gas | Ar + O₂ |
| Semiconductor Film | Back-pressure before | 5 × 10⁻⁴ |
| | Film Formation (Pa) | |
| | Sputter Pressure at | 0.5 |
| | Film Formation (Pa) | |
| | Substrate Temperature | room |
| | at Film Formation (° C.) | temperature |
| | Pulse Direct Current | 100 |
| | (DC) Output (W) | |
| | Oxygen Partial Pressure | 1 |
| | at Film Formation (%) | |
| | L/W of TFT (μm) | 200/1000 |
| | Film Thickness (nm) | 25 |
| Heat Treatment | Heat Treatment after Film | 350 |
| Conditions after | Formation: Temperature (° C.) | |
| Formation of | Temperature Increase | 10 |
| Semiconductor Film | Speed (° C./min) | |
| | Time (min) | 60 |
| | Atmosphere | air |
| TFT Properties after | Linear Mobility (cm²/V · sec) | 80 |
| Heat Treatment | Vth (V) | −0.6 |
| | On/Off Ratio | >1 × 10⁷ |
| | Off Current (A) | <1 × 10⁻¹² |

### Preparation of Oxide Sintered Body

### Examples 15 and 16

Powders of gallium oxide, aluminum oxide, and indium oxide were weighed for a composition (at %) as shown in Table 11, which were put in a polyethylene pot and mixed/pulverized using a dry ball mill for 72 hours to prepare mixture powders. An oxide sintered body was prepared and evaluated in the same manner as in Example 1 except that the sintering temperature and time were changed to those described in Table 11. Results are shown in Table 11.

TABLE 11

| | | Example 15 | Example 16 |
|---|---|---|---|
| Composition | In₂O₃ | 61.9 | 67.1 |
| (mass %) | Ga₂O₃ | 33.5 | 18.1 |
| | Al₂O₃ | 4.6 | 14.8 |
| Composition | In | 50 | 50 |
| (at %) | Ga | 40 | 20 |
| | Al | 10 | 30 |
| Production | Sintering Temperature | 1330 | 1380 |
| Conditions | (° C.) | | |
| | Sintering Time | 24 | 24 |
| | (hr) | | |
| Relative Density (%) | | 97.8 | 98.0 |
| Bulk Resistivity (mΩ · cm) | | 7.8 | 13.4 |
| XRD Measurement | Main Component | Crystalline Structure | Crystalline Structure |
| | | Compound A | Compound A |
| | Sub Component | — | — |
| Lattice Constant of In₂O₃ Phase (10⁻¹⁰ m) | | — | — |
| SEM-EDS of Region of | In | 49 | 50 |
| Main Component (at %) | Ga | 40 | 19 |
| | Al | 11 | 31 |
| SEM-EDS of Region of | In | — | — |
| Sub component (at %) | Ga | — | — |
| | Al | — | — |
| Analysis by SEM-DES | Main Component | Crystalline Structure | Crystalline Structure |
| Measurement | | Compound A | Compound A |
| | Sub Component | — | — |
| | Ratio of Area of | 100 | 100 |
| | Crystalline Structure | | |
| | Compound A (%) | | |

### Evaluation Results

### Examples 15 and 16

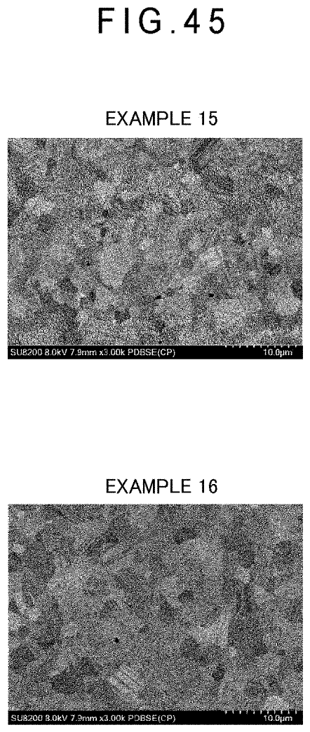

FIG. 45 shows SEM photographs of oxide sintered bodies in Examples 15 and 16.

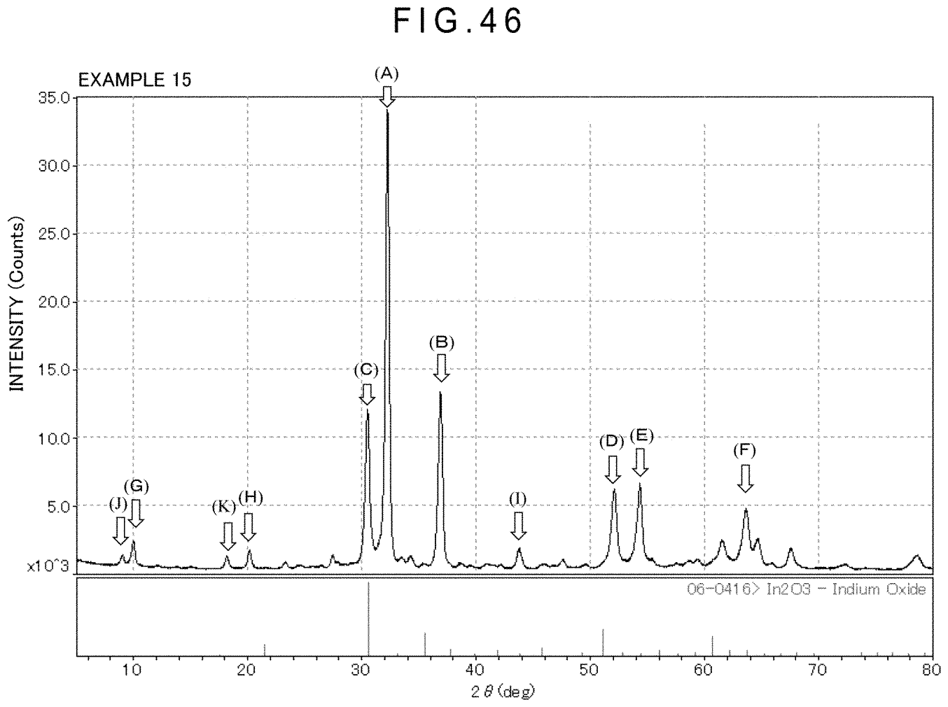

FIG. 46 shows XRD measurement results (XRD chart) of the oxide sintered body in Example 15.

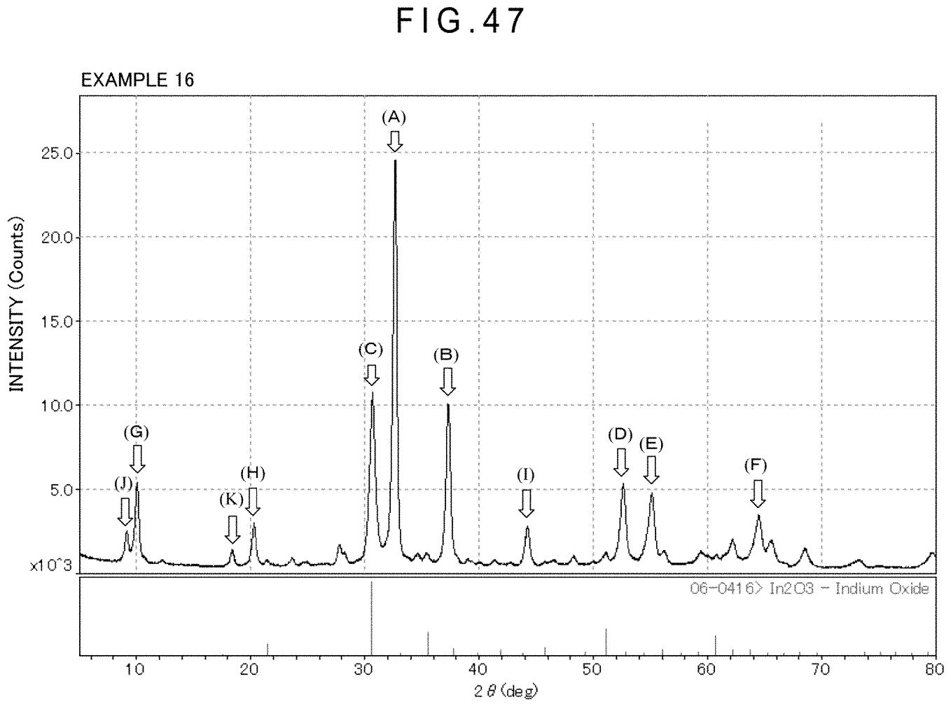

FIG. 47 shows XRD measurement results (XRD chart) of the oxide sintered body in Example 16.

Table 11 shows composition ratios (atomic ratios) of In:Ga:Al obtained by the SEM-EDS measurement of the oxide sintered bodies of Examples 15 and 16.

It has been found from Table 11 that the oxide sintered bodies of Examples 15 and 16 each are the crystalline structure compound A satisfying the composition represented by the composition formula (1) or the composition formula (2). This oxide sintered body has semiconductor properties and is useful.

As shown in the SEM image of FIG. 45, only a connecting phase of the crystalline structure compound A was observed in the oxide sintered body of Example 15. An indium oxide phase was not observed in a view field shown in the SEM image. The result of elemental analysis was In:Ga:Al=50:40:10 at %, which was the same as the charged composition. The composition of the connecting phase of the crystalline structure compound A in Example 15 was In:Ga:Al=49:40:11 at % as a result of SEM-EDS measurement, which was substantially the same as the charged composition.

As shown in the SEM image of FIG. 45, only a connecting phase of the crystalline structure compound A was observed in the oxide sintered body of Example 16. An indium oxide phase was not observed in a view field shown in the SEM image. The result of elemental analysis was In:Ga:Al=50:20:30 at %, which was the same as the charged composition. The composition of the connecting phase of the crystalline structure compound A in Example 16 was In:Ga:Al=50:19:31 at % as a result of SEM-EDS measurement, which was substantially the same as the charged composition.

As shown in FIGS. 46 and 47, the oxide sintered bodies of Examples 15 and 16 had a diffraction peak in each of ranges of an incidence angle (2θ) defined by the above (A) to (F) as measured by X-ray (Cu—K α ray) diffraction measurement. The oxide sintered bodies had a diffraction peak in each of ranges of an incidence angle (2θ) defined by the above (H) to (K) as measured by X-ray (Cu—K α ray) diffraction measurement. It has been found through JADE6 analysis that the crystal with diffraction peaks in the respective (A) to (K) ranges does not match known compounds but has unknown crystal phase.

In the XRD charts shown in FIGS. 46 and 47, there was no peak overlapping with the peaks of the indium oxide of the Bixbyite structure. Moreover, an image relating to indium oxide was not observed also in the SEM-EDS measurement. Accordingly, it is considered that the oxide sintered bodies of Examples 15 and 16 do not substantially contain the indium oxide phase.

Table 11 shows properties of the oxide sintered body of the crystalline structure compound A in each of Examples 15 and 16.

A relative density of the oxide sintered body of the crystalline structure compound A in each of Examples 15 and 16 was 97% or more.

A bulk resistivity of the oxide sintered body of the crystalline structure compound A in each of Examples 15 and 16 was 15 mΩ·cm or less.

It has been found that the resistivity of the oxide sintered body of the crystalline structure compound A in each of Examples 15 and 16 was sufficiently low and suitably usable as the sputtering target.

### Examples 17 to 22

Powders of gallium oxide, aluminum oxide, and indium oxide were weighed for a composition (at %) as shown in Table 12, which were put in a polyethylene pot and mixed/pulverized using a dry ball mill for 72 hours to prepare a mixture powder. An oxide sintered body was prepared and evaluated in the same manner as in Example 1 except that the sintering temperature and time were changed to those described in Table 12. Results are shown in Table 12.

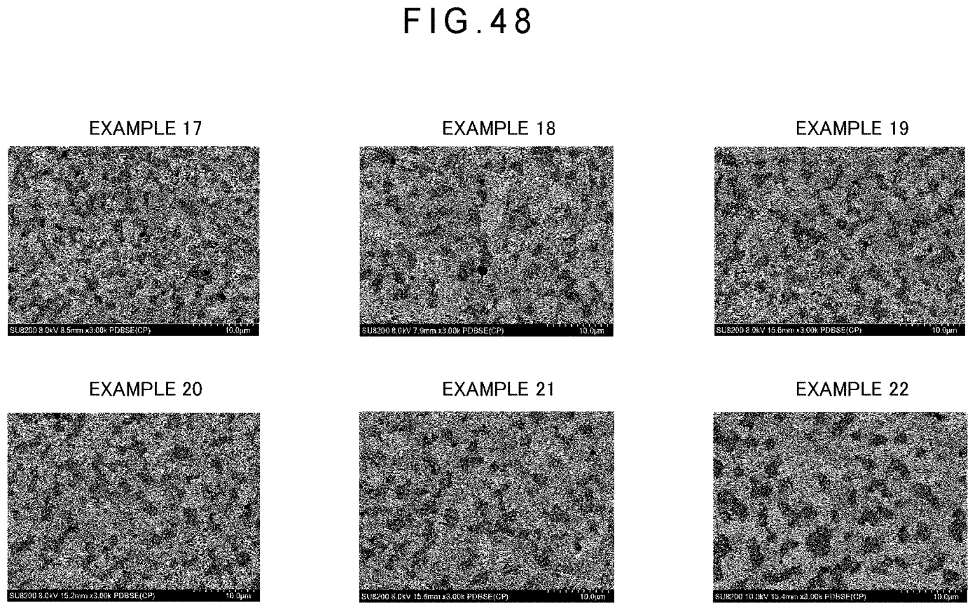

FIG. 48 shows SEM photographs of oxide sintered bodies in Examples 17 to 22.

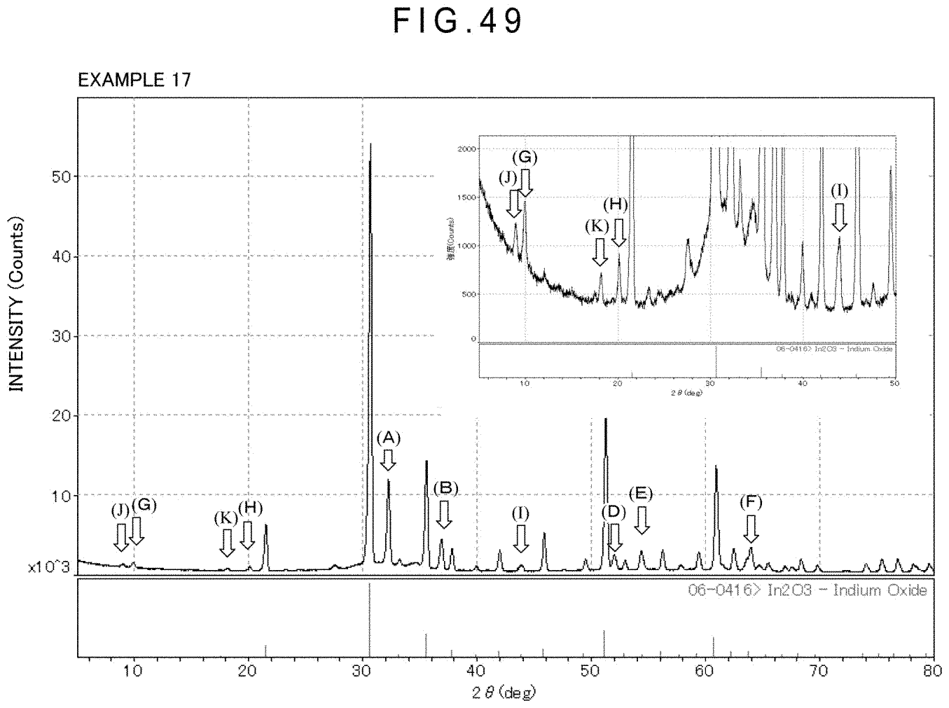

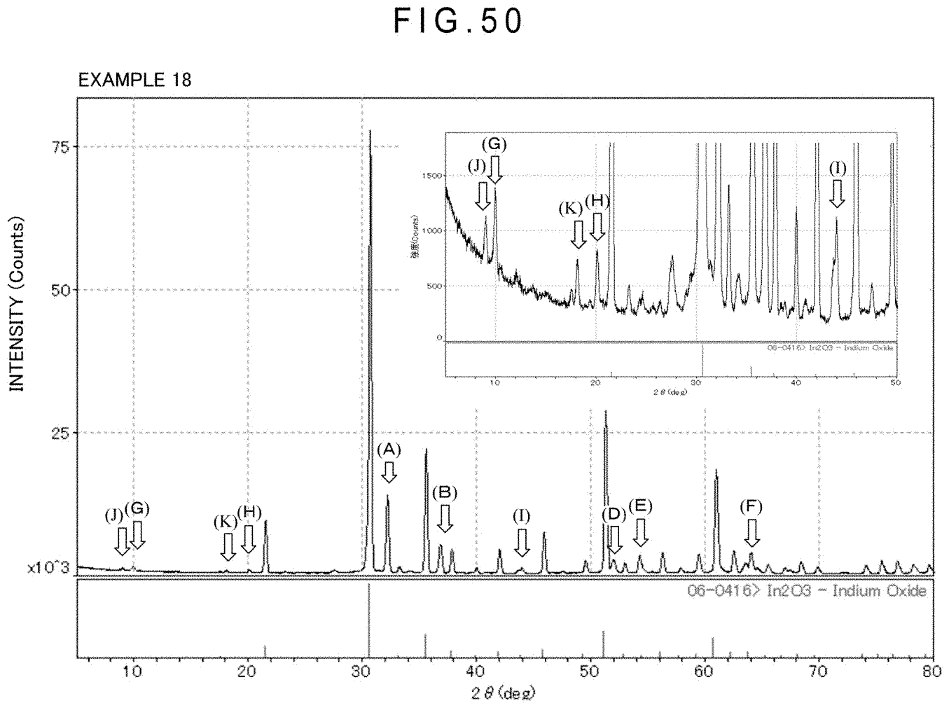

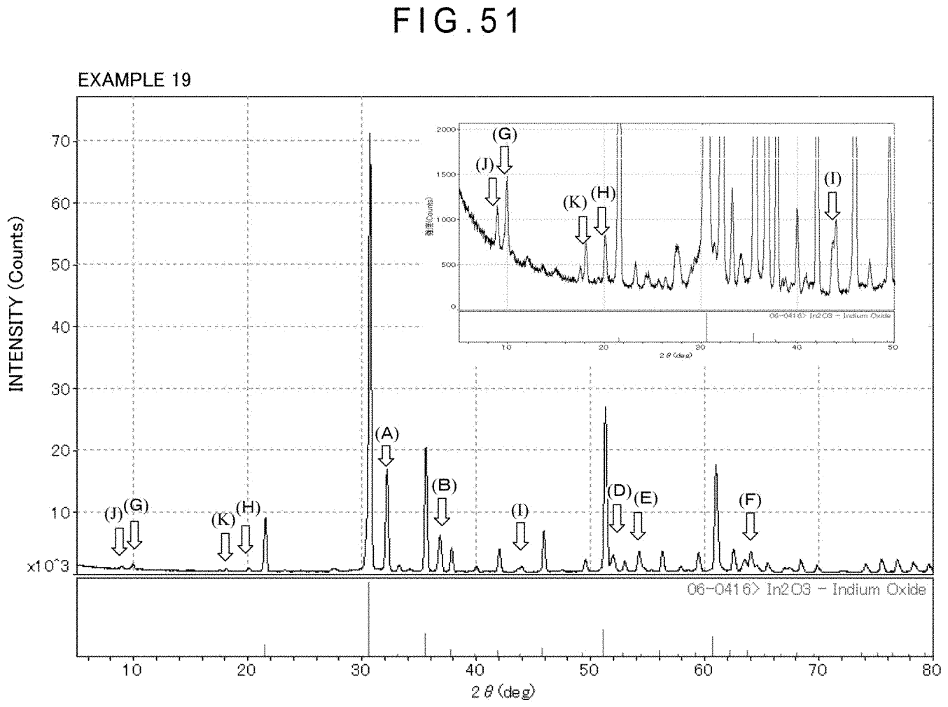

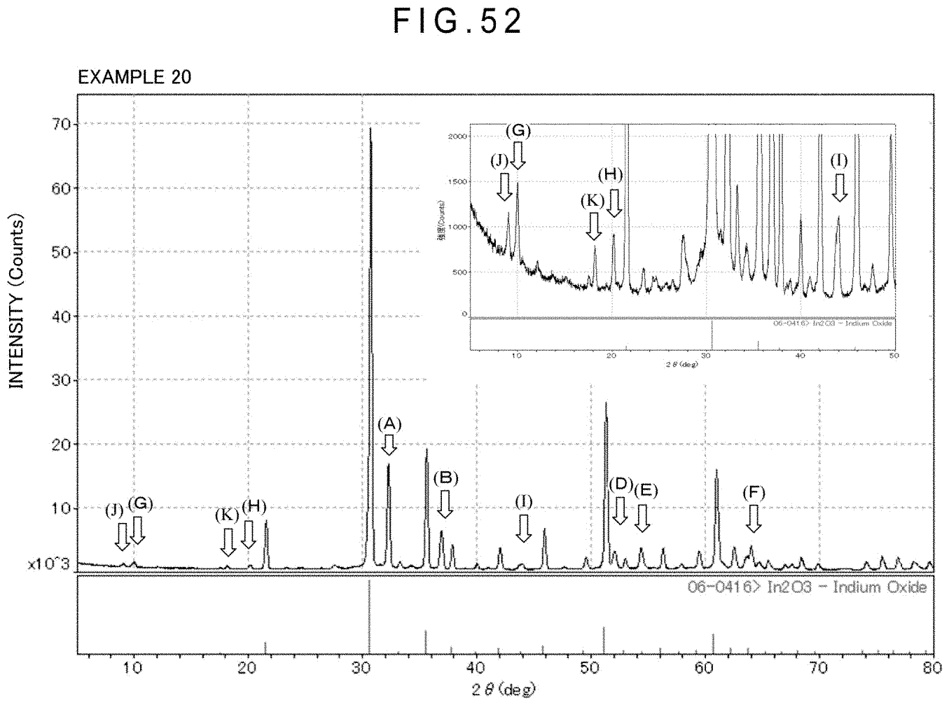

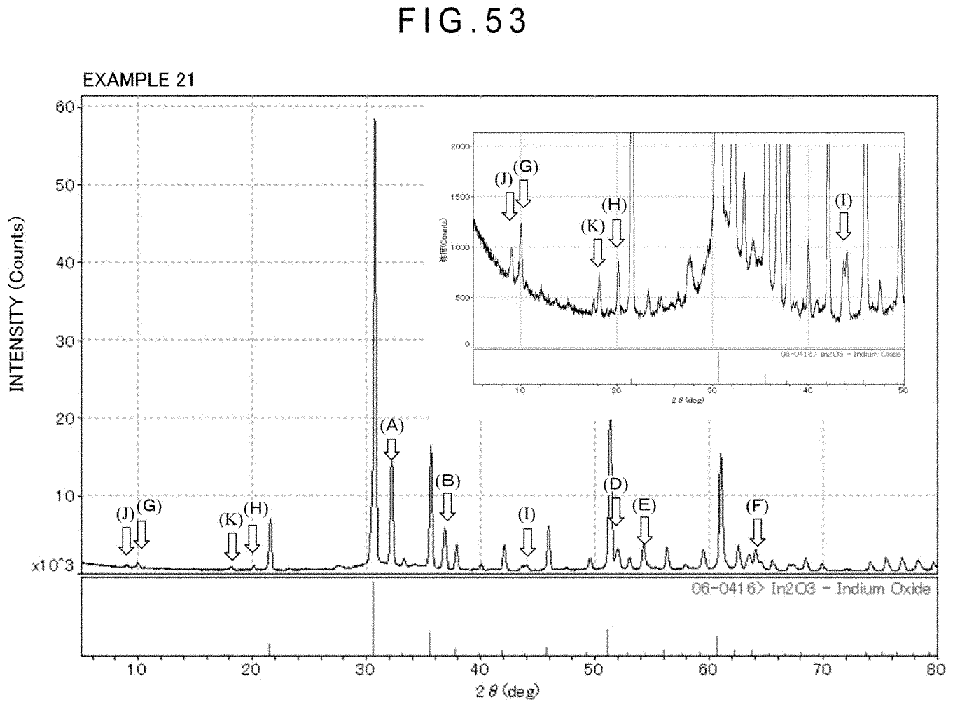

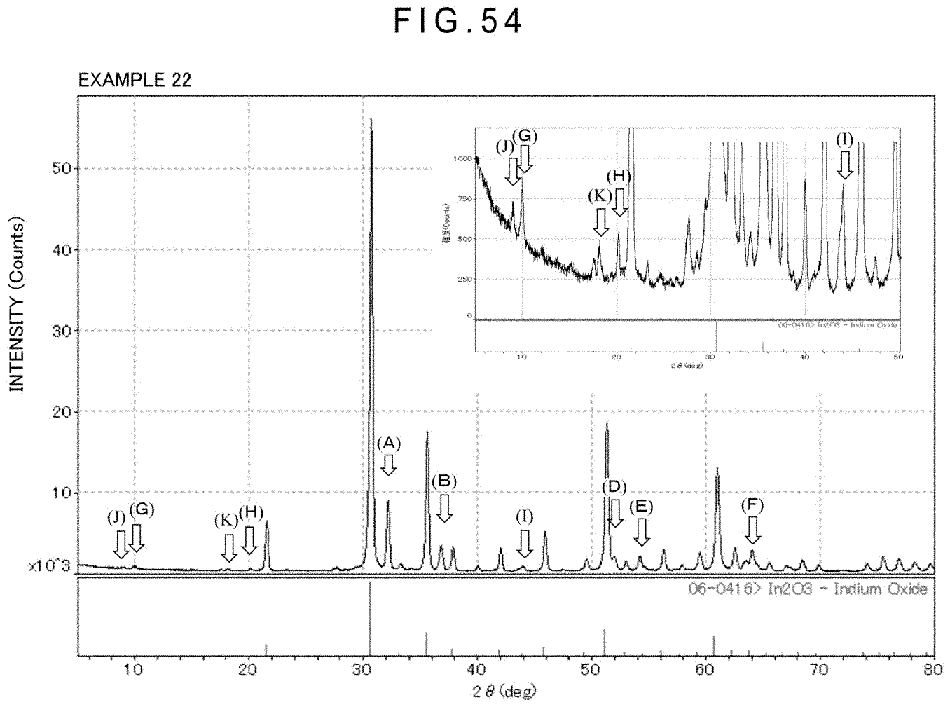

FIGS. 49 to 54 show enlarged views of XRD charts of the oxide sintered bodies of Examples 17 to 22.

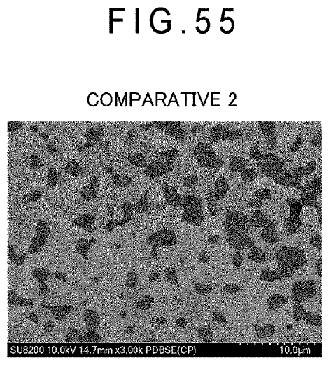

FIG. 55 shows an XRD chart of an oxide sintered body in Comparative 2.

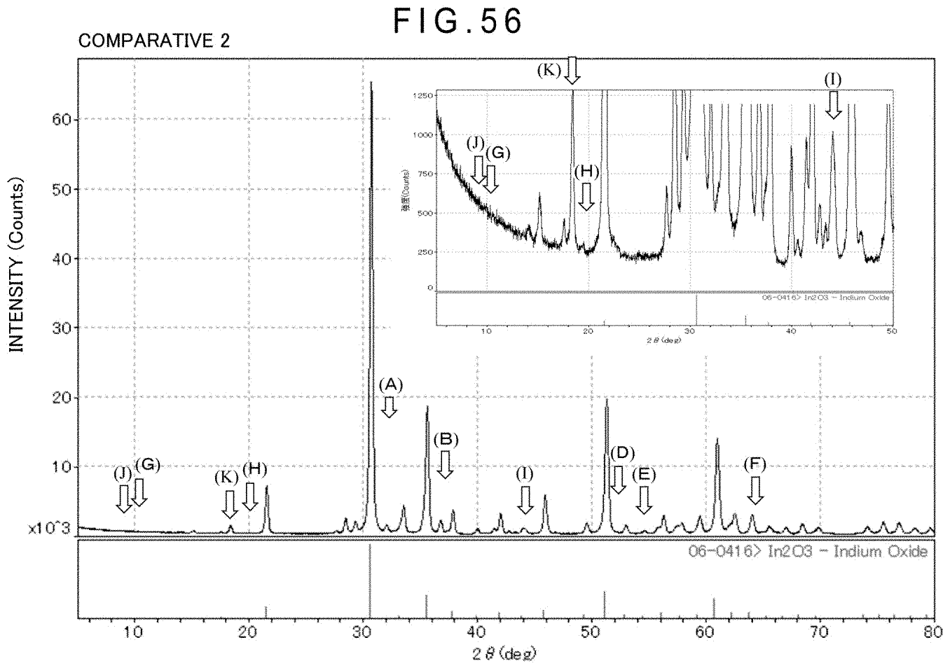

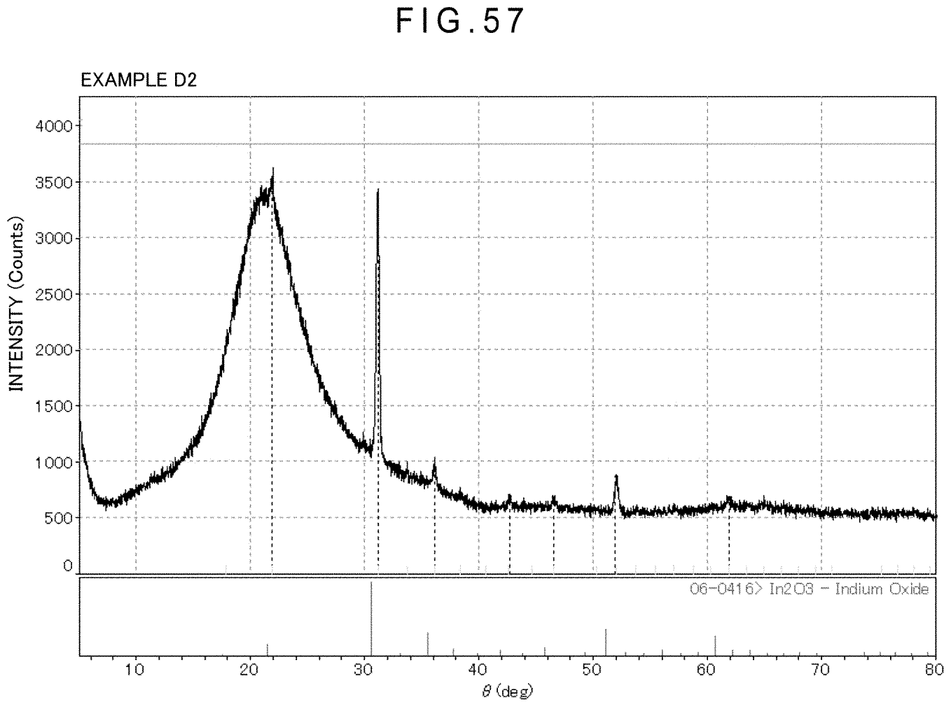

FIG. 56 shows an enlarged view of the XRD chart of the oxide sintered body in Comparative 2.

Table 12 shows, in the sintered body of each of Examples 17 to 22 and Comparative 2, compositions, density (relative density), bulk resistivity, XRD analysis, and composition analysis (composition ratio (atomic ratio) of In:Ga:Al) by SEM-EDS, and the like.

As shown in FIG. 48, it was observed that the crystalline structure compound A (a region shown in black in the SEM photographs) was dispersed in a phase formed of crystal grains (a region shown in light gray in the SEM photographs) of the Bixbyite crystalline compound represented by In₂O₃ in the oxide sintered bodies of Examples 17 to 22.

The ratio (area ratio S_{X}=(S_{A}/S_{T})×100) of the area S_{A} of the crystalline structure compound A (black part) to the area S_{T} in the view field (FIG. 48) when the oxide sintered bodies of Examples 17 to 21 were as follows.

Oxide sintered body in Example 17: 26%

Oxide sintered body in Example 18: 21%

Oxide sintered body in Example 19: 26%

Oxide sintered body in Example 20: 25%

Oxide sintered body in Example 21: 21%

Oxide sintered body in Example 22: 16%

Each of the areas for calculating the area ratio S_{X} was calculated by image analysis (the above described “Calculation Method of Ratio of Crystalline Structure Compound A from SEM Image”).

As shown in FIGS. 49 to 54, specific peaks caused by the crystalline structure compound A, namely, the peaks in the respective range (A) to (K) were observed in the XRD measurement of the oxide sintered body in each of Examples 17 to 22. In the XRD measurement, when a peak is too small to be confirmed, the peak can be observed clearly by enlarging the measurement sample and increasing the measurement time to reduce noise. A sample of about 5 mm×20 mm×4 mm thickness is usually used. However, at this time, a 4-inch φ×5-mm thick oxide sintered body was used.

TABLE 12

| | | Example 17 | Example 18 | Example 19 | Example 20 |
|---|---|---|---|---|---|
| Composition | In₂O₃ | 88.5 | 89.0 | 88.0 | 87.50 |
| (mass %) | Ga₂O₃ | 10.0 | 10.0 | 11.0 | 11.00 |
| | Al₂O₃ | 1.5 | 1.0 | 1.0 | 1.50 |
| Composition | In | 82.4 | 83.5 | 82.2 | 81.1 |
| (at %) | Ga | 13.8 | 13.9 | 15.2 | 15.1 |
| | Al | 3.8 | 2.6 | 2.6 | 3.8 |
| Production | Sintering Temperature | 1350 | 1350 | 1350 | 1350 |
| Conditions | (° C.) | | | | |
| | Sintering Time | 24 | 24 | 24 | 24 |
| | (hr) | | | | |
| Relative Density (%) | | 98.2 | 98.0 | 98.2 | 97.9 |
| Bulk Resistivity (mΩ · cm) | | 2.3 | 3.3 | 2.9 | 2.6 |
| XRD | Main Component | In₂O₃ | In₂O₃ | In₂O₃ | In₂O₃ |
| Measurement | | | | | |
| | Sub Component | Crystalline | Crystalline | Crystalline | Crystalline |
| | | Structure | Structure | Structure | Structure |
| | | Compound A | Compound A | Compound A | Compound A |
| Lattice Constant of In₂O₃ Phase (10⁻¹⁰ m) | | 10.087 | 10.083 | 10.085 | 10.088 |
| SEM-EDS of Region | In | 93 | 94 | 92 | 93 |
| of Main Component | Ga | 6 | 5 | 7 | 6 |
| (at %) | Al | 1 | 1 | 1 | 1 |
| SEM-EDS of Region | In | 49 | 50 | 49 | 50 |
| of Sub Component | Ga | 39 | 41 | 42 | 40 |
| (at %) | Al | 12 | 9 | 9 | 10 |
| Consideration from | Main Component | In₂O₃ | In₂O₃ | In₂O₃ | In₂O₃ |
| SEM-DES | Sub Component | Crystalline | Crystalline | Crystalline | Crystalline |
| Measurement | | Structure | Structure | Structure | Structure |
| | | Compound A | Compound A | Compound A | Compound A |
| | Ratio of Area of | 26 | 21 | 26 | 25 |
| | Crystalline Structure | | | | |
| | Compound A (%) | | | | |

| | | Example 21 | Example 22 | Comparative 2 |
|---|---|---|---|---|
| Composition | In₂O₃ | 87.0 | 88.80 | 87.65 |
| (mass %) | Ga₂O₃ | 12.0 | 10.50 | 12.00 |
| | Al₂O₃ | 1.0 | 0.75 | 0.35 |
| Composition | In | 80.9 | 83.50 | 82.39 |
| (at %) | Ga | 16.6 | 14.60 | 16.71 |
| | Al | 2.5 | 1.90 | 0.90 |
| Production | Sintering Temperature | 1350 | 1350 | 1400 |
| Conditions | (° C.) | | | |
| | Sintering Time | 24 | 24 | 24 |
| | (hr) | | | |
| Relative Density (%) | | 98.1 | 98.0 | 97.1 |
| Bulk Resistivity (mΩ · cm) | | 2.6 | 3.4 | 3.7 |
| XRD | Main Component | In₂O₃ | In₂O₃ | In₂O₃ |
| Measurement | | | | |
| | Sub Component | Crystalline | Crystalline | Crystalline Structure |
| | | Structure | Structure | Compound A |
| | | Compound A | Compound A | undetected |
| Lattice Constant of In₂O₃ Phase (10⁻¹⁰ m) | | 10.083 | 10.085 | 10.077 |
| SEM-EDS of Region | In | 92 | 93 | 93 |
| of Main Component | Ga | 7 | 6 | 7 |
| (at %) | Al | 1 | 1 | 0 |
| SEM-EDS of Region | In | 50 | 50 | 40 |
| of Sub Component | Ga | 41 | 40 | 55 |
| (at %) | Al | 9 | 10 | 5 |
| Consideration from | Main Component | In₂O₃ | In₂O₃ | In₂O₃ |
| SEM-DES | Sub Component | Crystalline | Crystalline | Estimated to be Al- |
| Measurement | | Structure | Structure | In-doped Ga₂O₃ |
| | | Compound A | Compound A | |
| | Ratio of Area of | 21 | 16 | — |
| | Crystalline Structure | | | |
| | Compound A (%) | | | |

As shown in Table 12, it has been found that, in the oxide sintered bodies in Examples 17 to 22, the phase in which crystals of the crystalline structure compound A were dispersed (a region shown in black in the SEM photographs) shows the composition represented by the composition formula (2) as a result of the SEM-EDS analysis, and the phase in which crystal grains of indium oxide were connected to each other (a region shown in light gray in the SEM photographs) contains the gallium element and the aluminum element.

Moreover, it has been found that the composition (at %) of the oxide sintered body of each of Examples 17 to 22 is present in the composition range R_{D} shown in FIG. 4 and the composition range R_{D}′ shown in FIG. 40.

In Comparative 2, a sintered body was prepared with aluminum oxide set at 0.35 mass % (0.90 at % in terms of the Al element) which falls out of the range of the invention, as shown in Table 12. As shown in Comparative 2, a Bixbyite phase represented by In₂O₃, in which gallium oxide is solid-dissolved, is deposited, and a phase supposed to be a gallium oxide phase having a composition ratio of Ga:In:Al=55:40:5 at % obtained by the EDS measurement and doped with the indium element and the aluminum element is deposited. In the XRD chart shown in FIG. 56, peaks derived from the Bixbyite phase represented by In₂O₃ and unknown peaks are observed, whereas the peaks corresponding to the peaks of the crystalline structure compound A of the invention, namely, the peaks in the respective the ranges (A) to (K) were not observed. Accordingly, the oxide sintered body of Comparative 2 is considered to contain no crystalline structure compound A.

### Examples D1 to D7 and Comparatives D1 to D2

Thin-film transistors of Examples D1 to D7 and Comparatives D1 to D2 were prepared in the same manner as the method described in the above-described [Preparation of Thin-Film Transistor] using the oxide sintered bodies of Examples 17 to 22 and Comparative 2, except that the conditions were changed to those shown in Table 13. The prepared thin-film transistors were evaluated in the same manner as in the above-described <Property Evaluation of Semiconductor Film> and <Property Evaluation of TFT>. Table 13 shows data of the thin-film transistors containing the respective crystalline oxide thin films.

TABLE 13

| | | Example D1 | Example D2 | Example D3 | Example D4 | Example D5 |
|---|---|---|---|---|---|---|
| | Sintered Body Used as Target | Example 17 | Example 18 | Example 19 | Example 20 | Example 21 |
| Formation Conditions | Atmospheric Gas | Ar + O₂ | Ar + O₂ | Ar + O₂ | Ar + O₂ | Ar + O₂ |
| of Semiconductor Film | Back-pressure before Film Formation (Pa) | 5 × 10⁻⁴ | 5 × 10⁻⁴ | 5 × 10⁻⁴ | 5 × 10⁻⁴ | 5 × 10⁻⁴ |
| | Sputter Pressure at Film Formation (Pa) | 0.5 | 0.5 | 0.5 | 0.5 | 0.5 |
| | Substrate Temperature | room | room | room | room | room |
| | at Film Formation (° C.) | temperature | temperature | temperature | temperature | temperature |
| | Direct Current (DC) Output (W) | 200 | 200 | 200 | 200 | 200 |
| | Oxygen Partial Pressure | 1 | 1 | 1 | 1 | 1 |
| | at Film Formation (%) | | | | | |
| | L/W of TFT (μm) | 200/1000 | 200/1000 | 200/1000 | 200/1000 | 200/1000 |
| | Film Thickness (nm) | 50 | 50 | 50 | 50 | 50 |
| Heat Treatment | Heat Treatment after Film Formation: | 350 | 350 | 350 | 350 | 350 |
| Conditions after | Temperature (° C.) | | | | | |
| Formation of | Temperature Increase Speed (° C./min) | 10 | 10 | 10 | 10 | 10 |
| Semiconductor Film | Time (min) | 60 | 60 | 60 | 60 | 60 |
| | Atmosphere | air | air | air | air | air |
| Film Properties of | Crystallinity just after Film Deposition (XRD) | amorphous | amorphous | amorphous | amorphous | amorphous |
| Semiconductor Film | Crystallinity just after Heating (XRD) | In₂O₃ crystal | In₂O₃ crystal | In₂O₃ crystal | In₂O₃ crystal | In₂O₃ crystal |
| after Heat Treatment | Band Gap of Semiconductor Film (eV) | 3.75 | 3.74 | 3.72 | 3.75 | 3.6 |
| | Lattice Constant of In₂O₃ Phase (10⁻¹⁰ m) | 9.918 | 9.954 | 9.928 | 9.914 | 9.914 |
| TFT Properties after | Linear Mobility (cm²/V · sec) | 34 | 32 | 41 | 36 | 45 |
| Heat Treatment and | Vth (V) | −0.6 | −0.3 | −12 | −0.9 | −15 |
| before Formation of | On/Off Ratio | >1 × 10⁸ | >1 × 10⁸ | >1 × 10⁶ | >1 × 10⁸ | >1 × 10⁶ |
| SiO₂ Film | Off Current (A) | <1 × 10⁻¹¹ | <1 × 10⁻¹² | <1 × 10⁻¹⁰ | <1 × 10⁻¹² | <1 × 10⁻¹⁰ |

| | | Example D6 | Comparative D1 | Comparative D2 |
|---|---|---|---|---|
| | Sintered Body Used as Target | Example 22 | Comparative 2 | Comparative 2 |
| Formation Conditions | Atmospheric Gas | Ar + O₂ | Ar + O₂ | Ar + O₂ |
| of Semiconductor Film | Back-pressure before Film Formation (Pa) | 5 × 10⁻⁴ | 5 × 10⁻⁴ | 5 × 10⁻⁴ |
| | Sputter Pressure at Film Formation (Pa) | 0.5 | 0.5 | 0.5 |
| | Substrate Temperature | room | room | room |
| | at Film Formation (° C.) | temperature | temperature | temperature |
| | Direct Current (DC) Output (W) | 200 | 200 | 200 |
| | Oxygen Partial Pressure | 1 | 1 | 1 |
| | at Film Formation (%) | | | |
| | L/W of TFT (μm) | 200/1000 | 200/1000 | 200/1000 |
| | Film Thickness (nm) | 50 | 50 | 50 |
| Heat Treatment | Heat Treatment after Film Formation: | 350 | 300 | 350 |
| Conditions after | Temperature (° C.) | | | |
| Formation of | Temperature Increase Speed (° C./min) | 10 | 10 | 10 |
| Semiconductor Film | Time (min) | 60 | 60 | 60 |
| | Atmosphere | air | air | air |
| Film Properties of | Crystallinity just after Film Deposition (XRD) | amorphous | amorphous | amorphous |
| Semiconductor Film | Crystallinity just after Heating (XRD) | In₂O₃ crystal | amorphous | In₂O₃ crystal |
| after Heat Treatment | Band Gap of Semiconductor Film (eV) | 3.72 | 3.4 | 3.64 |
| | Lattice Constant of In₂O₃ Phase (10⁻¹⁰ m) | 9.937 | — | 9.945 |
| TFT Properties after | Linear Mobility (cm²/V · sec) | 31 | conduction | conduction |
| Heat Treatment and | Vth (V) | −0.9 | — | — |
| before Formation of | On/Off Ratio | >1 × 10⁸ | — | — |
| SiO₂ Film | Off Current (A) | <1 × 10⁻¹² | — | — |

The results of Examples D1, D2, D4 and D6 demonstrate that, by using the oxide sintered bodies of Examples 17, 18, 20 and 22 as the target, even when an oxygen partial pressure at the film formation is 1%, although the mobility is 30 cm²/(V·s) or more (high mobility), Vth can be kept at about −0.9 to 0 V, so that a thin-film transistor exhibiting excellent TFT properties can be provided.

On the other hand, the results of Examples D3 and D5 demonstrate that, when the oxide sintered bodies of Examples 19 and 21 are used as the target, the mobility is an ultra high mobility exceeding 40 cm²/(V·s), although Vth becomes significantly negative. Such a material having an ultra high mobility is usable as a high mobility layer of a laminated TFT device in which two or more semiconductor layers are laminated.

Since Examples D1 to D5 demonstrate that the band gap of the semiconductor film exceeds 3.6 eV and transparency is excellent, it is considered that photostability is also high. Since the lattice constant of In₂O₃ is 10.05×10⁻¹⁰ m or less, it is considered that these high performances are caused by a unique packing of elements.

FIG. 56 shows the XRD chart of the semiconductor thin-film after being subjected to the heat treatment in Example D2. The large broad pattern around 20° for 28 is a halo pattern of the substrate. Meanwhile, clear peaks are observed around 22°, around 30°, around 36°, around 42°, around 46°, around 51°, and around 61°, indicating that the thin film is crystallized. Moreover, it can be seen from the peak fitting result that the thin film has the Bixbyite structure of In₂O₃. The diffraction peak near 30° is considered to be a diffraction pattern from the (222) plane of the Bixbyite structure of In₂O₃. The lattice constant of the thin film was 9.943 Å.

In Comparative D1, a film was formed at the oxygen partial pressure of 1% using the target obtained from the oxide sintered body of Comparative 2. The formed film was subjected to the heat treatment at 300 degrees C. for one hour. This heated film did not show any clear peak other than the halo pattern of the substrate in the XRD chart and was an amorphous film. This amorphous film was subjected to the TFT measurement. A switch property of the TFT did not appear to be kept in a conduction state, so that the amorphous film was judged to be a conductive film.

In Comparative D2, the film obtained in Comparative D1 was subjected to the heat treatment at 350 degrees C. for one hour. The crystalized film was measured in terms of the TFT properties. However, since the crystalized film was in a conduction state, the TFT properties were not obtained.

As a reference example, a sintered body containing gallium oxide of 10 mass % (14.1 at %) was prepared and used for forming a film at the oxygen partial pressure of 1%. The formed film was subjected to the heat treatment at 350 degrees C. for one hour. A lattice constant of the heated film was measured, resulting in 10.077×10⁻¹⁰ m.

### EXPLANATION OF CODES

1: oxide sintered body
3: backing plate
20: silicon wafer
30: gate insulating film
40: oxide semiconductor thin-film
50: source electrode
60: drain electrode
70: interlayer insulating film
70A: interlayer insulating film
70B: interlayer insulating film
100: thin-film transistor
100A: thin-film transistor
300: substrate
301: pixel unit
302: first scan line drive circuit
303: second scan line drive circuit
304: signal line drive circuit
310: capacity line
312: gate line
313: gate line
314: drain electrode
316: transistor
317: transistor
318: first liquid crystal device
319: second liquid crystal device
320: pixel unit
321: switching transistor
322: drive transistor
3002: photodiode
3004: transfer transistor
3006: reset transistor
3008: amplification transistor
3010: signal charge accumulator
3100: power line
3110: reset power line
3120: vertical output line

1-20. (canceled)

21. A crystalline oxide thin film comprising an indium element (In), a gallium element (Ga), and an aluminum element (Al), wherein
the indium element, the gallium element, and the aluminum element are present within a composition range surrounded by points (R16), (R3), (R4), and (R17) below represented by atomic % ratios in an In—Ga—Al ternary composition diagram,
In:Ga:Al=82:1:17 (R16),
In:Ga:Al=90:1:9 (R3),
In:Ga:Al=90:9:1 (R4), and
In:Ga:Al=82:17:1 (R17).

22. A crystalline oxide thin film comprising an indium element (In), a gallium element (Ga), and an aluminum element (Al), wherein
the indium element, the gallium element, and the aluminum element are present within a composition range surrounded by points (R16-1), (R3), (R4-1), and (R17-1) below represented by atomic % ratios in an In—Ga—Al ternary composition diagram,
In:Ga:Al=80:1:19 (R16-1),
In:Ga:Al=90:1:9 (R3),
In:Ga:Al=90:8.5:1.5 (R4-1), and
In:Ga:Al=80:18.5:1.5 (R17-1).

23. The crystalline oxide thin film according to claim 21, wherein the crystalline oxide thin film is a Bixbyite crystal represented by In₂O₃.

24. The crystalline oxide thin film according to claim 23, wherein a lattice constant of the Bixbyite crystal represented by In₂O₃ is equal to or less than 10.05×10¹⁰ m.

25. A thin-film transistor comprising the crystalline oxide thin film according to claim 21.

26. An amorphous oxide thin film comprising an indium element (In), a gallium element (Ga), and an aluminum element (Al), wherein
the indium element, the gallium element, and the aluminum element are present within a composition range surrounded by points (R16), (R17) and (R18) below represented by atomic % ratios in an In—Ga—Al ternary composition diagram,
In:Ga:Al=82:1:17 (R16),
In:Ga:Al=82:17:1 (R17), and
In:Ga:Al=66:17:17 (R18).

27. An amorphous oxide thin film comprising an indium element (In), a gallium element (Ga), and an aluminum element (Al), wherein
the indium element, the gallium element, and the aluminum element are present within a composition range surrounded by points (R16-1), (R17-1) and (R18-1) below represented by atomic % ratios in an In—Ga—Al ternary composition diagram,
In:Ga:Al=80:1:19 (R16-1),
In:Ga:Al=80:18.5:1.5 (R17-1), and
In:Ga:Al=62.5:18.5:19 (R18-1).

28. An amorphous oxide thin film comprising a composition represented by a composition formula (1) below,
(InₓGa_{y}Al_{z})₂O₃ (1)
where:
0.47≤x≤0.53,
0.17≤y≤0.33,
0.17≤z≤0.33, and
x+y+z=1.

29. An amorphous oxide thin film comprising a composition represented by a composition formula (2) below,
(InₓGa_{y}Al_{z})₂O₃ (2)
where:
0.47≤x≤0.53,
0.17≤y≤0.43,
0.07≤z≤0.33, and
x+y+z=1.

30. A thin-film transistor comprising the amorphous oxide thin film according to claim 26.

31. A thin-film transistor comprising an oxide semiconductor thin-film comprising an indium element (In), a gallium element (Ga) and an aluminum element (Al), wherein the indium element (In), the gallium element (Ga) and the aluminum element (Al) are present within a composition range surrounded by points (R1), (R2), (R3), (R4), (R5) and (R6) below represented by atomic % ratios in an In—Ga—Al ternary composition diagram,
In:Ga:Al=45:22:33 (R1),
In:Ga:Al=66:1:33 (R2),
In:Ga:Al=90:1:9 (R3),
In:Ga:Al=90:9:1 (R4),
In:Ga:Al=54:45:1 (R5), and
In:Ga:Al=45:45:10 (R6).

32. A thin-film transistor comprising:
a gate insulating film;
an active layer in contact with the gate insulating film;
a source electrode; and
a drain electrode, wherein
the active layer is a crystalline oxide thin film, the crystalline oxide thin film comprising an indium element (In), a gallium element (Ga), and an aluminum element (Al), wherein the indium element, the gallium element, and the aluminum element are present within a composition range surrounded by points (R16), (R3), (R4), and (R17) below represented by atomic % ratios in an In—Ga—Al ternary composition diagram,
the amorphous oxide thin film according to claim 26 is laminated on the active layer, and
the amorphous oxide thin film is in contact with at least one of the source electrode or the drain electrode,
In:Ga:Al=82:1:17 (R16),
In:Ga:Al=90:1:9 (R3),
In:Ga:Al=90:9:1 (R4), and
In:Ga:Al=82:17:1 (R17).

33. An electronic device comprising the thin-film transistor according to claim 25.
